(19) United States
(12) Patent Application Publication
(10) Pub. No.: US 2012/0190206 A1
(43) Pub. Date: Jul. 26, 2012

(54) SEMICONDUCTOR DEVICE MANUFACTURING METHOD

(75) Inventors: Koichi YATSUDA, Yamanashi (JP); Eiichi NISHIMURA, Yamanashi (JP)

(73) Assignee: Tokyo Electron Limited, Tokyo (JP)

(21) Appl. No.: 13/438,247

(22) Filed: Apr. 3, 2012

Related U.S. Application Data
(62) Division of application No. 12/997,584, filed on Dec. 17, 2010.

(30) Foreign Application Priority Data
Jun. 13, 2008 (JP) 2008-155844
Jun. 13, 2008 (JP) 2008-155845

(51) Int. Cl. H01L 21/302

(52) U.S. Cl. 438/703; 257/E21.214

(57) ABSTRACT

A semiconductor device manufacturing method includes forming a first organic film pattern on a to-be-etched layer on a substrate, forming a silicon oxide film coating the first organic film pattern-etching the silicon oxide film to form a first mask pattern to cause the width of the line part of the first organic film pattern to have a fixed proportion with respect forming a second organic film pattern coating the silicon oxide film, forming a second mask pattern including the silicon oxide film on a side face part in an area coated by the second organic film pattern, and forming, in an area other than the area coated by the second organic film pattern, a third mask pattern in which an even number of the silicon oxide films are arranged.

### CROSS-REFERENCE TO RELATED APPLICATIONS

This application is a divisional application of and is claiming benefit of priority under 35 U.S.C. 120 to the patent application Ser. No. 12/997,584 filed on Dec. 17, 2010, which has effectively entered under 35 U.S.C. 371 (c) the national stage from the PCT Application No. PCT/JP2009/053525, which claims the benefit of priorities of Japanese Patent Application No. 2008-155844 filed on Jun. 13, 2008 and Japanese Patent Application No. 2008-155845 filed on Jun. 13, 2008, where the entire contents of all applications which are incorporated herein by reference.

### TECHNICAL FIELD

The present invention relates to a semiconductor device manufacturing method, a program for performing the manufacturing method and a recording medium that records the program, and, in particular, to a semiconductor device manufacturing method in which a semiconductor device is manufactured by using a double patterning method including a SWT method, a program for performing the manufacturing method and a recording medium that records the program.

### BACKGROUND ART

In the prior art, in a semiconductor device manufacturing process, an etching process such as plasma etching is performed on a substrate such as a semiconductor wafer, and fine circuit patterns and so forth are formed. In the etching process, through a photolithography process using a photoresist, an etching mask is formed.

Resolution in the photolithography is expressed by k₁×λ/NA by using a constant k₁ depending on a process condition and an optical system, a wavelength λ of exposure light, and a numerical aperture of a lens NA. Further, the numerical aperture NA is in proportion to refractive index n. Therefore, by shortening the wavelength of light used in exposure and increasing the refractive index, the resolution is reduced. One example of realizing miniaturization according to this principle is ArF immersion lithography.

However, along with miniaturization processing so that a most advanced design rule becomes 45 nm and further becomes 32 nm, it becomes not possible to continue miniaturization of a semiconductor device only by photolithography in which a photoresist film is exposed by using an optical system and patterns are formed through development. Therefore, various new technologies not depending only on miniaturization in photolithography have been developed. As one example, a so-called double patterning method (double patterning process) exists. According to the double patterning method, by carrying out patterning in two stages, i.e., a first mask pattern forming step and a second mask pattern forming step carried out after the first mask pattern forming step, finer intervals than a case where an etching mask is formed through one time of patterning are formed (for example, see Patent Document 1).

Further, a method using a SWT (Side Wall Transfer) method is known. In the SWT method, for example, a SiO₂ film, a Si₃N₄ film and so forth are used as sacrificial films, masks are formed on side wall parts on both sides of one pattern, and used. Thus, patterning is carried out by a finer pitch than a pattern of a photoresist that is first obtained from a photoresist film being exposed and developed. In this method, first, a pattern of photoresist is used to etch a sacrificial film of a SiO₂ film, for example, patterning is carried out, and a Si₃N₄ film or such is formed on the SiO₂ pattern. After that, etching back is carried out in such a manner that the Si₃N₄ film remains only on side wall parts that coat side faces of the SiO₂ film acting as a core part. Then, wet etching is carried out so that the SiO₂ film of the core part is removed, and etching of a lower layer is carried out by using the Si₃N₄ film of the remaining side wall parts as a mask.

Further, for a film forming technology for a film that forms the side wall part, it is required to form a film at a lower temperature. As a technology of film forming at such a lower temperature, a method is known in which chemical vapor deposition is used in which a film forming gas is activated by means of a heated catalyst member (for example, see Patent Document 2).

Further, in a case where a semiconductor device is manufactured by using fine patterns formed by the SWT method as a memory array chip, it is necessary to form patterns of a logic device simultaneously in an area which becomes the logic device or such separated from an area that becomes the memory array chip. As a semiconductor device manufacturing method in which the fine patterns for the memory array chip and the patterns for the logic device are formed simultaneously, the following semiconductor device manufacturing method exists. That is, patterns of core parts for forming fine patterns throughout the area including the area becoming the memory array chip and the area becoming the logic device are formed. Then, the patterns of the core parts existing in the area becoming the logic device are coated by a photoresist film, and then, side faces of the patterns of the core parts existing in the area becoming the memory array chip are coated by films that become side wall parts. Then, etching back of the films that coat the patterns of the core parts is carried out, and subsequently, the core parts are removed to form the fine patterns becoming the side wall parts. Then, the photoresist film coating the patterns of the core parts existing in the area becoming logic device are removed. By the semiconductor device manufacturing method, it is possible to form the fine patterns for the memory array chip and the patterns for the logic device simultaneously (for example, see Patent Document 3). It is noted that, since the fine patterns are formed in the area becoming the memory array chip, the area may be defined as an area of a fine pattern density. The area becoming the logic device has a pattern density more coarse than the fine patterns, so the area may be defined as an area of a coarse pattern density.
Patent Document 1: Japanese Laid-Open Patent Application No. 2007-027742
Patent Document 2: Japanese Laid-Open Patent Application No. 2006-179819
Patent Document 3: U.S. Pat. No. 7,429,533

### DISCLOSURE OF THE INVENTION

### Problem to be Solved by the Invention

However, the following problem has existed in a case where a semiconductor device is manufactured by using the double patterning method including the above-mentioned SWT method.

In the prior art, since the two side wall parts are retained as the masks having fine line patterns which coat the side walls of both sides of the core part that is used to form a single pattern, it is easy to form an even number of fine line patterns (referred to as even number patterns, hereinafter). However, in a case where an odd number (including one, the same manner being applied hereinafter) of fine line patterns (referred to as odd number patterns, hereinafter) are required, it is not possible to form them in one lump by using photolithography using a metal mask for forming the even number patterns. It is necessary to newly produce another metal mask for forming the odd number patterns, and carry out an additional process of photolithography by using the metal mask.

Further, as in a case where a line pattern (referred to as an isolated pattern, hereinafter) at a position isolated from a position of the even number patterns is required, it is not possible to form these line patterns in one lump by using photolithography using the metal mask for forming the even number patterns. It is necessary to newly produce another metal mask for forming the isolated pattern, and carry out an additional process of photolithography by using the metal mask.

Therefore, in a case where a semiconductor device is manufactured by using the double patterning method and the SWT method, and patterns other than the even number patterns are to be formed at once, the man-hours increase, the manufacturing costs thus increase, the processes become complicated and also, productivity degrades.

Further, in a case where the films of the side wall parts of SWT are formed directly on the etching mask, it is not possible to increase a selection ratio in etching rates between a material of the side wall parts and a material of the etching mask below the side wall parts, and the material used for the etching mask is restricted. Therefore, it is difficult to reduce the manufacturing costs.

Further, according to the method disclosed by Patent Document 3, the fine patterns for the memory array chip which are the even number patterns can be formed in the area of fine pattern density, and simultaneously, the patterns for the logic device which are the odd number patterns or the isolated patterns can be formed in the area of coarse pattern density. However, in the method disclosed by Patent Document 3, patterns of core parts for forming the fine patterns are made of amorphous carbon films, and the side wall parts that coat the side walls of the patterns of the core parts are made of silicon oxide films. Therefore, materials of the patterns used as hard masks for etching the to-be-etched layer are different between the area of fine pattern density and the area of coarse pattern density. If the materials of the patterns are different, influences, such as etching resistance in a lateral direction, a ratio (selection ratio) in etching rates with respect to the lower layer and so forth for when the to-be-etched layer is etched, are different. Thus, it is not possible to make uniform the influences throughout the area of the masks. As a result, in the case where the area of fine pattern density and the area of coarse pattern density are mixed in the patterns used as the hard masks, it is not possible to maintain CD (Critical Dimension) of the patterns to be uniform at high accuracy.

The present invention has been devised in consideration of the above-mentioned points, and a semiconductor device manufacturing method, a control program and a program recording medium are provided by which in a case where a semiconductor device is manufactured by using the double patterning method including the SWT method, the even number patterns and the odd number patterns can be formed in a lump at low costs.

Further, an object of the present invention is to provide a semiconductor device manufacturing method, a control program and a program recording medium, by which when a semiconductor device is manufactured by using the double patterning method including the SWT method, even in a case where the area of fine pattern density and the area of coarse pattern density are mixed in the patterns used as the hard masks, the CD of the patterns can be maintained uniform at high accuracy.

### Means to Solve the Problems

The present invention for solving the above-mentioned problems is characterized in that the following respective parts are provided.

A semiconductor device manufacturing method according to the first invention has a first organic film pattern forming process of forming a first organic film on a to-be-etched layer on a substrate, and patterning the first organic film to form a first organic film pattern having a line part that has a fixed width; a silicon oxide film forming process of forming a silicon oxide film in such a manner to coat the first organic film pattern in an isotropic manner; a first mask pattern forming process of etching the silicon oxide film to form a first mask pattern in such a manner to cause the width of the line part of the first organic film pattern to have a fixed proportion with respect to a thickness of the silicon oxide film that coats a surface of the line part in the isotropic manner; a second organic film pattern forming process of forming a second organic film to coat the silicon oxide film, and patterning the second organic film to form a second organic film pattern in such a manner to cause the second organic film pattern to have a fixed proportion with respect to the width of the line part of the first organic film pattern; a second mask pattern forming process of forming a second mask pattern that includes the silicon oxide film at least on a side face part in an area that is coated by the second organic film pattern; a third mask pattern forming process of, in an area other than the area that is coated by the second organic film pattern, removing the first organic film pattern and forming a third mask pattern in which an even number of the silicon oxide films are arranged; and an etching process of etching the to-be-etched layer by using the second mask pattern and the third mask pattern.

The second invention is characterized to, in the semiconductor device manufacturing method according to the first invention, further have a first trimming process of, before the silicon oxide film forming process, trimming the first organic film pattern in such a manner to cause a dimension of the width of the first organic film pattern to be a first dimension, and, in the silicon oxide film forming process, the silicon oxide film is formed in such a manner to coat the trimmed first organic film pattern in an isotropic manner by a second dimension.

The third invention is characterized in that, in the semiconductor device manufacturing method according to the second invention, the second dimension is equal to the first dimension.

The fourth invention is characterized to, in the semiconductor device manufacturing method according to the second or third invention, have a second trimming process of trimming the second organic film pattern so that a dimension of a width becomes a third dimension.

The fifth invention is characterized in that in the semiconductor device manufacturing method according to the fourth invention, the third dimension is equal to the first dimension.

The sixth invention is characterized in that in the semiconductor device manufacturing method according to the first invention, in the first organic film pattern forming process, the first organic film is formed on a first protective film that is formed on the substrate through the to-be-etched layer and a third organic film, the second organic film pattern forming process is carried out before the first mask pattern forming process, on the occasion when the first mask pattern forming process is carried out, the second mask pattern forming process is carried out simultaneously, as a result of etching being carried out in such a manner that the silicon oxide film remains as a lower layer part of the second organic film pattern, and on the occasion when the third mask forming pattern is carried out, the second mask pattern forming process is carried out simultaneously, as a result of the second organic film pattern being removed.

The seventh invention is characterized in that in the semiconductor device manufacturing method according to the sixth invention, in the first organic film pattern forming process, the first organic film is formed on the first protective film, and, after the first organic film is exposed and developed, trimming is carried out and the first organic film pattern is formed.

The eighth invention is characterized in that in the semiconductor device manufacturing method according to the sixth invention, in the silicon oxide film forming process, a source gas containing silicon and a gas containing oxygen are supplied alternately, and the silicon oxide film is formed on the substrate.

The ninth invention is characterized in that in the semiconductor device manufacturing method according to the sixth invention, in the etching process, the first protective film and the third organic film are etched by using the second mask pattern and the third mask pattern, and a fourth mask pattern that includes the third organic film, the first protective film and the silicon oxide film are formed, and by using the fourth mask pattern, the to-be-etched layer that is a lower layer of the third organic film is etched.

The tenth invention is characterized in that in the semiconductor device manufacturing method according to the sixth invention, the to-be-etched layer is a silicon layer, a silicon oxide layer, a silicon nitride layer or a silicon oxynitride layer.

The eleventh invention is characterized in that in the semiconductor device manufacturing method according to the sixth invention, the first protective film is a SOG film, a SiON film or a composite film of a LTO film and a BARC film.

The twelfth invention is characterized in that in the semiconductor device manufacturing method according to the first invention, the first mask pattern forming process is carried out before the second organic film pattern forming process, the second organic film pattern is formed in such a manner to coat a predetermined pattern of the first mask pattern, in the second organic film pattern forming process, and on the occasion when the third mask pattern forming process is carried out, the second mask pattern forming process is carried out simultaneously, as a result of the second organic pattern being removed.

The thirteenth invention is characterized in that in the semiconductor device manufacturing method according to the twelfth invention, an upper layer part of the first organic film of the first organic film pattern is protected by a second protective film, and after the second organic film pattern forming process and before the third mask pattern forming process, a protective film removing process of removing the second protective film is carried out.

The fourteenth invention is characterized in that in the semiconductor device manufacturing method according to the thirteenth invention, the first organic pattern forming process includes a fourth organic film pattern forming process of forming a fourth organic film on the second protective film formed on the to-be-etched layer through the first organic film, and forming a fourth organic film pattern by patterning the fourth organic film; and a core part pattern forming process of forming a pattern of a core part protected by the second protective film, by etching the second protective film and the first organic film protected by the second protective film by using the fourth organic film pattern.

The fifteenth invention is characterized in that in the semiconductor device manufacturing method according to the fourteenth invention, in the core part pattern forming process, after the fourth organic film pattern is trimmed, the second protective film and the first organic film protected by the second protective film are etched.

The sixteenth invention is characterized in that in the semiconductor device manufacturing method according to the thirteenth invention, in the silicon oxide film forming process, a source gas containing silicon and a gas containing oxygen are supplied alternately, and the silicon oxide film is formed on the substrate.

The seventeenth invention is characterized in that in the semiconductor device manufacturing method according to the thirteenth invention, the to-be-etched layer is a silicon layer, a silicon oxide layer, a silicon nitride layer or a silicon oxynitride layer.

The eighteenth invention is characterized in that in the semiconductor device manufacturing method according to the thirteenth invention, as the to-be-etched layer, one obtained from laminating a first to-be-etched layer and a second to-be-etched layer in sequence from the side of the substrate is used.

The nineteenth invention is characterized in that in the semiconductor device manufacturing method according to the thirteenth invention, the second protective film is a SOG film, a SiON film or a composite film of a LTO film and a BARC film.

It is noted that, in the sixth invention, the first organic film may be a first photoresist film, the first organic film pattern may be a core part pattern, the first organic film pattern forming process may be a core part pattern forming process, the silicon oxide film forming process may be a film forming process, the first mask pattern may be a first pattern, the first mask pattern forming process may be a first pattern forming process, the second organic film may be a second photoresist film, the second organic film pattern may be a third pattern, the second organic film pattern forming process may be a third pattern forming process, the second mask pattern may be a fourth pattern, the third mask pattern may be a second pattern, and the third mask pattern forming process may be a second pattern forming process.

At this time, in the sixth invention, the semiconductor device manufacturing method may include a core part pattern forming process of forming a core part pattern made of a core part that includes a first photoresist film on a protective film formed on a substrate through a to-be-etched layer and an organic film; a film forming process of forming a silicon oxide film on the substrate on which the core part pattern has been formed; a first pattern forming process of etching so that the silicon oxide film remains as a side wall part that coats a side face of the core part, and forming a first pattern that includes the core part and the side wall part; and a second pattern forming process of forming a second pattern that includes the side wall part remaining as a result of the core part being removed. In the semiconductor device manufacturing method, a third pattern forming process of, before the first pattern forming process, forming a second photoresist film on the substrate, and forming a third pattern made of the second photoresist film by exposing and developing the second photoresist film may be provided. Further, in the first pattern forming process, etching may be carried out so that the silicon oxide film remains as the side wall part of the core part and a lower layer part of the third pattern. In the second pattern forming process, the second pattern and a fourth pattern that is made of the silicon oxide film and has the same shape as that of the third pattern may be formed simultaneously, as a result of the core part being removed, and the third pattern that is made of the second photoresist film being removed.

At this time, in the sixth invention, in the core part pattern forming process, after the first photoresist film is formed on the protective film, and the first photoresist film is exposed and developed, the core part pattern may be formed by trimming.

Further, at this time, in the sixth invention, in the film forming process, a source gas containing silicon and a gas containing oxygen are supplied alternately, and the silicon oxide film is formed on the substrate.

Further, at this time, in the sixth invention, a fifth pattern forming process of, after the second pattern forming process, etching the protective film and the organic film by using the second pattern and the fourth pattern as masks, and forming a fifth pattern that includes the organic film, the protective film and the silicon oxide film may be provided, and the to-be-etched layer as a lower layer may be etched by using the fifth pattern as a mask.

Further, at this time, in the sixth invention, the to-be-etched layer may be a silicon layer, a silicon oxide layer, a silicon nitride layer or a silicon oxynitride layer.

Further, at this time, in the sixth invention, the protective film may be a SOG film, a SiON film or a composite film of a LTO film and a BARC film.

Further, at this time, the present invention may be a program for carrying out the semiconductor device manufacturing method according to the sixth invention.

Further, at this time, the present invention may be a computer readable information recording medium that records a program for carrying out the semiconductor device manufacturing method according to the sixth invention.

Further, the patterns may mean, not only shapes formed as the masks, but also structures of respective layers formed in such a manner that the respective layers included in the semiconductor device are processed and the shapes of the masks are transferred to the respective layers. That is, according to the present invention, the patterns mean structures in which predetermined materials and predetermined shapes are combined.

Further, in the thirteenth invention, the first organic film may be an organic film, the first organic film pattern may be a core part pattern, the first organic film pattern forming process may be a core part pattern forming process, the silicon oxide film forming process may be a film forming process, the first mask pattern may be a first pattern, the first mask pattern forming process may be a first pattern forming process, the second organic film may be a second photoresist film, the second organic film pattern may be a third pattern, the second organic film pattern forming process may be the third pattern forming process, the second mask pattern may be a first pattern, the second mask pattern forming process may be a first pattern forming process, the third mask pattern may be a second pattern, and the third mask pattern forming process may be a second pattern forming process.

At this time, in the thirteenth invention, the semiconductor device manufacturing method may include a first pattern forming process of forming a first pattern that includes a core part made of an organic film, an upper layer of which is protected by a protective film, and a side wall part made of a silicon oxide film that coats a side face of the core part, on a to-be-etched layer on a substrate; a protective film removing process of removing the protective film of the core part; and a second pattern forming process of forming a second pattern made of the side wall part that remains as a result of removing the organic film of the core part. In the semiconductor device manufacturing method, before the protective film removing process, a photoresist coating process of coating a predetermined pattern of the first pattern by a first photoresist film may be provided. In the second pattern forming process, the second pattern made of the side wall part and the first pattern may be formed simultaneously as a result of the organic film being removed and the first photoresist film being removed.

Further, at this time, in the thirteenth invention, the first pattern forming process may include a third pattern forming process of forming a second photoresist film on the protective film that is formed on the to-be-etched layer through the organic film, and forming a third pattern of the second photoresist film by exposing and developing the second photoresist film; a core part pattern forming process of forming a pattern of the core part that is protected by the protective film, by etching the protective film and the organic film protected by the protective film, based on the third pattern of the second photoresist film; a film forming process of forming a silicon oxide film on the substrate on which the pattern of the core part has been formed; and an etching process of etching so that the silicon oxide film remains as the side wall part of the core part.

Further, at this time, in the thirteenth invention, in the core part pattern forming process, the protective film and the organic film protected by the protective film may be etched, after the third pattern of the second photoresist film is trimmed.

Further, at this time, in the thirteenth invention, in the film forming process, a source gas containing silicon and a gas containing oxygen are supplied alternately, and the silicon oxide film is formed on the substrate.

Further, at this time, in the thirteenth invention, after the second pattern forming process, the to-be-etched layer that is a lower layer of the organic film may be etched by using the second pattern and the first pattern as masks.

Further, at this time, in the thirteenth invention, the to-be-etched layer may be a silicon layer, a silicon oxide layer, a silicon nitride layer or a silicon oxynitride layer.

Further, at this time, in the thirteenth invention, as the to-be-etched layer, one obtained from laminating a first to-be-etched layer and a second to-be-etched layer in sequence from the side of the substrate is used.

Further, at this time, in the thirteenth invention, the protective film may be a SOG film, a SiON film or a composite film of a LTO film and a BARC film.

Further, at this time, the present invention may be a program for carrying out the semiconductor device manufacturing method according to the thirteenth invention.

Further, at this time, the present invention may be a computer readable information recording medium that records a program for carrying out the semiconductor device manufacturing method according to the thirteenth invention.

### Advantageous Effect of the Invention

According to the present invention, on the occasion when a semiconductor device is manufactured by using the double patterning method including the SWT method, even number patterns and odd number patterns can be formed in a lump at low costs, and, even in a case where an area of fine pattern density and an area of coarse pattern density are mixed in patterns used as hard masks, CD of the patterns can be maintained uniform at high accuracy.

### BRIEF DESCRIPTION OF THE DRAWINGS

FIG. 1 is a process diagram for illustrating procedures of respective processes of a semiconductor device manufacturing method according to a first embodiment of the present invention.

FIG. 2A is a figure for illustrating a process of the semiconductor device manufacturing method according to the first embodiment of the present invention, and a sectional view diagrammatically showing a structure of a semiconductor device in each process.

FIG. 2B is a figure for illustrating a process of the semiconductor device manufacturing method according to the first embodiment of the present invention, and a sectional view diagrammatically showing a structure of the semiconductor device in each process.

FIG. 2C is a figure for illustrating a process of the semiconductor device manufacturing method according to the first embodiment of the present invention, and a sectional view diagrammatically showing a structure of the semiconductor device in each process.

FIG. 2D is a figure for illustrating a process of the semiconductor device manufacturing method according to the first embodiment, and a sectional view diagrammatically showing a structure of the semiconductor device in each process.

FIG. 2E is a figure for illustrating a process of the semiconductor device manufacturing method according to the first embodiment of the present invention, and a sectional view diagrammatically showing a structure of the semiconductor device in each process.

FIG. 2F is a figure for illustrating a process of the semiconductor device manufacturing method according to the first embodiment of the present invention, and a sectional view diagrammatically showing a structure of the semiconductor device in each process.

FIG. 2G is a figure for illustrating a process of the semiconductor device manufacturing method according to the first embodiment of the present invention, and a sectional view diagrammatically showing a structure of the semiconductor device in each process.

FIG. 2H is a figure for illustrating a process of the semiconductor device manufacturing method according to the first embodiment of the present invention, and a sectional view diagrammatically showing a structure of the semiconductor device in each process.

FIG. 2I is a figure for illustrating a process of the semiconductor device manufacturing method according to the first embodiment of the present invention, and a sectional view diagrammatically showing a structure of the semiconductor device in each process.

FIG. 2J is a figure for illustrating a process of the semiconductor device manufacturing method according to the first embodiment of the present invention, and a sectional view diagrammatically showing a structure of the semiconductor device in each process.

FIG. 2K is a figure for illustrating a process of the semiconductor device manufacturing method according to the first embodiment of the present invention, and a sectional view diagrammatically showing a structure of the semiconductor device in each process.

FIG. 3 is a figure for illustrating processes of semiconductor device manufacturing methods in the first embodiment and a second embodiment of the present invention, and a circuit diagram showing an equivalent circuit of a NAND-type flash memory.

FIG. 4A is a figure for illustrating a process of a semiconductor device manufacturing method according to a first variant embodiment of the first embodiment of the present invention, and a sectional view diagrammatically showing a structure of a semiconductor device in each process.

FIG. 4B is a figure for illustrating a process of the semiconductor device manufacturing method according to the first variant embodiment of the first embodiment of the present invention, and a sectional view diagrammatically showing a structure of the semiconductor device in each process.

FIG. 4C is a figure for illustrating a process of the semiconductor device manufacturing method according to the first variant embodiment of the first embodiment of the present invention, and a sectional view diagrammatically showing a structure of the semiconductor device in each process.

FIG. 4D is a figure for illustrating a process of the semiconductor device manufacturing method according to the first variant embodiment of the first embodiment of the present invention, and a sectional view diagrammatically showing a structure of the semiconductor device in each process.

FIG. 4E is a figure for illustrating a process of the semiconductor device manufacturing method according to the first variant embodiment of the first embodiment of the present invention, and a sectional view diagrammatically showing a structure of the semiconductor device in each process.

FIG. 4F is a figure for illustrating a process of the semiconductor device manufacturing method according to the first variant embodiment of the first embodiment of the present invention, and a sectional view diagrammatically showing a structure of the semiconductor device in each process.

FIG. 4G is a figure for illustrating a process of the semiconductor device manufacturing method according to the first variant embodiment of the first embodiment of the present invention, and a sectional view diagrammatically showing a structure of the semiconductor device in each process.

FIG. 4H is a figure for illustrating a process of the semiconductor device manufacturing method according to the first variant embodiment of the first embodiment of the present invention, and a sectional view diagrammatically showing a structure of the semiconductor device in each process.

FIG. 4I is a figure for illustrating a process of the semiconductor device manufacturing method according to the first variant embodiment of the first embodiment of the present invention, and a sectional view diagrammatically showing a structure of the semiconductor device in each process.

FIG. 4J is a figure for illustrating a process of the semiconductor device manufacturing method according to the first variant embodiment of the first embodiment of the present invention, and a sectional view diagrammatically showing a structure of the semiconductor device in each process.

FIG. 4K is a figure for illustrating a process of the semiconductor device manufacturing method according to the first variant embodiment of the first embodiment of the present invention, and a sectional view diagrammatically showing a structure of the semiconductor device in each process.

FIG. 5A is a figure for illustrating a process of a semiconductor device manufacturing method according to a second variant embodiment of the first embodiment of the present invention, and a sectional view diagrammatically showing a structure of a semiconductor device in each process.

FIG. 5B is a figure for illustrating a process of the semiconductor device manufacturing method according to the second variant embodiment of the first embodiment of the present invention, and a sectional view diagrammatically showing a structure of the semiconductor device in each process.

FIG. 5C is a figure for illustrating a process of the semiconductor device manufacturing method according to the second variant embodiment of the first embodiment of the present invention, and a sectional view diagrammatically showing a structure of the semiconductor device in each process.

FIG. 5D is a figure for illustrating a process of the semiconductor device manufacturing method according to the second variant embodiment of the first embodiment of the present invention, and a sectional view diagrammatically showing a structure of the semiconductor device in each process.

FIG. 5E is a figure for illustrating a process of the semiconductor device manufacturing method according to the second variant embodiment of the first embodiment of the present invention, and a sectional view diagrammatically showing a structure of the semiconductor device in each process.

FIG. 5F is a figure for illustrating a process of the semiconductor device manufacturing method according to the second variant embodiment of the first embodiment of the present invention, and a sectional view diagrammatically showing a structure of the semiconductor device in each process.

FIG. 5G is a figure for illustrating a process of the semiconductor device manufacturing method according to the second variant embodiment of the first embodiment of the present invention, and a sectional view diagrammatically showing a structure of the semiconductor device in each process.

FIG. 5H is a figure for illustrating a process of the semiconductor device manufacturing method according to the second variant embodiment of the first embodiment of the present invention, and a sectional view diagrammatically showing a structure of the semiconductor device in each process.

FIG. 5I is a figure for illustrating a process of the semiconductor device manufacturing method according to the second variant embodiment of the first embodiment of the present invention, and a sectional view diagrammatically showing a structure of the semiconductor device in each process.

FIG. 5J is a figure for illustrating a process of the semiconductor device manufacturing method according to the second variant embodiment of the first embodiment of the present invention, and a sectional view diagrammatically showing a structure of the semiconductor device in each process.

FIG. 5K is a figure for illustrating a process of the semiconductor device manufacturing method according to the second variant embodiment of the first embodiment of the present invention, and a sectional view diagrammatically showing a structure of the semiconductor device in each process.

FIG. 6A is a figure for illustrating a process of a semiconductor device manufacturing method according to a third variant embodiment of the first embodiment of the present invention, and a sectional view diagrammatically showing a structure of a semiconductor device in each process.

FIG. 6B is a figure for illustrating a process of the semiconductor device manufacturing method according to the third variant embodiment of the first embodiment of the present invention, and a sectional view diagrammatically showing a structure of the semiconductor device in each process.

FIG. 6C is a figure for illustrating a process of the semiconductor device manufacturing method according to the third variant embodiment of the first embodiment of the present invention, and a sectional view diagrammatically showing a structure of the semiconductor device in each process.

FIG. 6D is a figure for illustrating a process of the semiconductor device manufacturing method according to the third variant embodiment of the first embodiment of the present invention, and a sectional view diagrammatically showing a structure of the semiconductor device in each process.

FIG. 6E is a figure for illustrating a process of the semiconductor device manufacturing method according to the third variant embodiment of the first embodiment of the present invention, and a sectional view diagrammatically showing a structure of the semiconductor device in each process.

FIG. 6F is a figure for illustrating a process of the semiconductor device manufacturing method according to the third variant embodiment of the first embodiment of the present invention, and a sectional view diagrammatically showing a structure of the semiconductor device in each process.

FIG. 6G is a figure for illustrating a process of the semiconductor device manufacturing method according to the third variant embodiment of the first embodiment of the present invention, and a sectional view diagrammatically showing a structure of the semiconductor device in each process.

FIG. 6H is a figure for illustrating a process of the semiconductor device manufacturing method according to the third variant embodiment of the first embodiment of the present invention, and a sectional view diagrammatically showing a structure of the semiconductor device in each process.

FIG. 6I is a figure for illustrating a process of the semiconductor device manufacturing method according to the third variant embodiment of the first embodiment of the present invention, and a sectional view diagrammatically showing a structure of the semiconductor device in each process.

FIG. 6J is a figure for illustrating a process of the semiconductor device manufacturing method according to the third variant embodiment of the first embodiment of the present invention, and a sectional view diagrammatically showing a structure of the semiconductor device in each process.

FIG. 6K is a figure for illustrating a process of the semiconductor device manufacturing method according to the third variant embodiment of the first embodiment of the present invention, and a sectional view diagrammatically showing a structure of the semiconductor device in each process.

FIG. 7A is a figure for illustrating a process of a semiconductor device manufacturing method according to a fourth variant embodiment of the first embodiment of the present invention, and a sectional view diagrammatically showing a structure of a semiconductor device in each process.

FIG. 7B is a figure for illustrating a process of the semiconductor device manufacturing method according to the fourth variant embodiment of the first embodiment of the present invention, and a sectional view diagrammatically showing a structure of the semiconductor device in each process.

FIG. 7C is a figure for illustrating a process of the semiconductor device manufacturing method according to the fourth variant embodiment of the first embodiment of the present invention, and a sectional view diagrammatically showing a structure of the semiconductor device in each process.

FIG. 7D is a figure for illustrating a process of the semiconductor device manufacturing method according to the fourth variant embodiment of the first embodiment of the present invention, and a sectional view diagrammatically showing a structure of the semiconductor device in each process.

FIG. 7E is a figure for illustrating a process of the semiconductor device manufacturing method according to the fourth variant embodiment of the first embodiment of the present invention, and a sectional view diagrammatically showing a structure of the semiconductor device in each process.

FIG. 7F is a figure for illustrating a process of the semiconductor device manufacturing method according to the fourth variant embodiment of the first embodiment of the present invention, and a sectional view diagrammatically showing a structure of the semiconductor device in each process.

FIG. 7G is a figure for illustrating a process of the semiconductor device manufacturing method according to the fourth variant embodiment of the first embodiment of the present invention, and a sectional view diagrammatically showing a structure of the semiconductor device in each process.

FIG. 7H is a figure for illustrating a process of the semiconductor device manufacturing method according to the fourth variant embodiment of the first embodiment of the present invention, and a sectional view diagrammatically showing a structure of the semiconductor device in each process.

FIG. 7I is a figure for illustrating a process of the semiconductor device manufacturing method according to the fourth variant embodiment of the first embodiment of the present invention, and a sectional view diagrammatically showing a structure of the semiconductor device in each process.

FIG. 7J is a figure for illustrating a process of the semiconductor device manufacturing method according to the fourth variant embodiment of the first embodiment of the present invention, and a sectional view diagrammatically showing a structure of the semiconductor device in each process.

FIG. 7K is a figure for illustrating a process of the semiconductor device manufacturing method according to the fourth variant embodiment of the first embodiment of the present invention, and a sectional view diagrammatically showing a structure of the semiconductor device in each process.

FIG. 8A is a figure for illustrating a process of a semiconductor device manufacturing method according to a fifth variant embodiment of the first embodiment of the present invention, and a sectional view diagrammatically showing a structure of a semiconductor device in each process.

FIG. 8B is a figure for illustrating a process of the semiconductor device manufacturing method according to the fifth variant embodiment of the first embodiment of the present invention, and a sectional view diagrammatically showing a structure of the semiconductor device in each process.

FIG. 8C is a figure for illustrating a process of the semiconductor device manufacturing method according to the fifth variant embodiment of the first embodiment of the present invention, and a sectional view diagrammatically showing a structure of the semiconductor device in each process.

FIG. 8D is a figure for illustrating a process of the semiconductor device manufacturing method according to the fifth variant embodiment of the first embodiment of the present invention, and a sectional view diagrammatically showing a structure of the semiconductor device in each process.

FIG. 8E is a figure for illustrating a process of the semiconductor device manufacturing method according to the fifth variant embodiment of the first embodiment of the present invention, and a sectional view diagrammatically showing a structure of the semiconductor device in each process.

FIG. 8F is a figure for illustrating a process of the semiconductor device manufacturing method according to the fifth variant embodiment of the first embodiment of the present invention, and a sectional view diagrammatically showing a structure of the semiconductor device in each process.

FIG. 8G is a figure for illustrating a process of the semiconductor device manufacturing method according to the fifth variant embodiment of the first embodiment of the present invention, and a sectional view diagrammatically showing a structure of the semiconductor device in each process.

FIG. 8H is a figure for illustrating a process of the semiconductor device manufacturing method according to the fifth variant embodiment of the first embodiment of the present invention, and a sectional view diagrammatically showing a structure of the semiconductor device in each process.

FIG. 8I is a figure for illustrating a process of the semiconductor device manufacturing method according to the fifth variant embodiment of the first embodiment of the present invention, and a sectional view diagrammatically showing a structure of the semiconductor device in each process.

FIG. 8J is a figure for illustrating a process of the semiconductor device manufacturing method according to the fifth variant embodiment of the first embodiment of the present invention, and a sectional view diagrammatically showing a structure of the semiconductor device in each process.

FIG. 8K is a figure for illustrating a process of the semiconductor device manufacturing method according to the fifth variant embodiment of the first embodiment of the present invention, and a sectional view diagrammatically showing a structure of the semiconductor device in each process.

FIG. 9 is a process diagram for illustrating procedures of respective processes of a semiconductor device manufacturing method according to a second embodiment of the present invention.

FIG. 10A is a figure for illustrating a process of the semiconductor device manufacturing method according to the second embodiment of the present invention, and a sectional view diagrammatically showing a structure of a semiconductor device in each process.

FIG. 10B is a figure for illustrating a process of the semiconductor device manufacturing method according to the second embodiment of the present invention, and a sectional view diagrammatically showing a structure of the semiconductor device in each process.

FIG. 10C is a figure for illustrating a process of the semiconductor device manufacturing method according to the second embodiment of the present invention, and a sectional view diagrammatically showing a structure of the semiconductor device in each process.

FIG. 10D is a figure for illustrating a process of the semiconductor device manufacturing method according to the second embodiment of the present invention, and a sectional view diagrammatically showing a structure of the semiconductor device in each process.

FIG. 10E is a figure for illustrating a process of the semiconductor device manufacturing method according to the second embodiment of the present invention, and a sectional view diagrammatically showing a structure of the semiconductor device in each process.

FIG. 10F is a figure for illustrating a process of the semiconductor device manufacturing method according to the second embodiment of the present invention, and a sectional view diagrammatically showing a structure of the semiconductor device in each process.

FIG. 10G is a figure for illustrating a process of the semiconductor device manufacturing method according to the second embodiment of the present invention, and a sectional view diagrammatically showing a structure of the semiconductor device in each process.

FIG. 10H is a figure for illustrating a process of the semiconductor device manufacturing method according to the second embodiment of the present invention, and a sectional view diagrammatically showing a structure of the semiconductor device in each process.

FIG. 10I is a figure for illustrating a process of the semiconductor device manufacturing method according to the second embodiment of the present invention, and a sectional view diagrammatically showing a structure of the semiconductor device in each process.

FIG. 10J is a figure for illustrating a process of the semiconductor device manufacturing method according to the second embodiment of the present invention, and a sectional view diagrammatically showing a structure of the semiconductor device in each process.

FIG. 10K is a figure for illustrating a process of the semiconductor device manufacturing method according to the second embodiment of the present invention, and a sectional view diagrammatically showing a structure of the semiconductor device in each process.

FIG. 10L is a figure for illustrating a process of the semiconductor device manufacturing method according to the second embodiment of the present invention, and a sectional view diagrammatically showing a structure of the semiconductor device in each process.

FIG. 11A is a figure for illustrating a process of a semiconductor device manufacturing method according to a first variant embodiment of the second embodiment of the present invention, and a sectional view diagrammatically showing a structure of a semiconductor device in each process.

FIG. 11B is a figure for illustrating a process of the semiconductor device manufacturing method according to the first variant embodiment of the second embodiment of the present invention, and a sectional view diagrammatically showing a structure of the semiconductor device in each process.

FIG. 11C is a figure for illustrating a process of the semiconductor device manufacturing method according to the first variant embodiment of the second embodiment of the present invention, and a sectional view diagrammatically showing a structure of the semiconductor device in each process.

FIG. 11D is a figure for illustrating a process of the semiconductor device manufacturing method according to the first variant embodiment of the second embodiment of the present invention, and a sectional view diagrammatically showing a structure of the semiconductor device in each process.

FIG. 11E is a figure for illustrating a process of the semiconductor device manufacturing method according to the first variant embodiment of the second embodiment of the present invention, and a sectional view diagrammatically showing a structure of the semiconductor device in each process.

FIG. 11F is a figure for illustrating a process of the semiconductor device manufacturing method according to the first variant embodiment of the second embodiment of the present invention, and a sectional view diagrammatically showing a structure of the semiconductor device in each process.

FIG. 11G is a figure for illustrating a process of the semiconductor device manufacturing method according to the first variant embodiment of the second embodiment of the present invention, and a sectional view diagrammatically showing a structure of the semiconductor device in each process.

FIG. 11H is a figure for illustrating a process of the semiconductor device manufacturing method according to the first variant embodiment of the second embodiment of the present invention, and a sectional view diagrammatically showing a structure of the semiconductor device in each process.

FIG. 11I is a figure for illustrating a process of the semiconductor device manufacturing method according to the first variant embodiment of the second embodiment of the present invention, and a sectional view diagrammatically showing a structure of the semiconductor device in each process.

FIG. 11J is a figure for illustrating a process of the semiconductor device manufacturing method according to the first variant embodiment of the second embodiment of the present invention, and a sectional view diagrammatically showing a structure of the semiconductor device in each process.

FIG. 11K is a figure for illustrating a process of the semiconductor device manufacturing method according to the first variant embodiment of the second embodiment of the present invention, and a sectional view diagrammatically showing a structure of the semiconductor device in each process.

FIG. 11L is a figure for illustrating a process of the semiconductor device manufacturing method according to the first variant embodiment of the second embodiment of the present invention, and a sectional view diagrammatically showing a structure of the semiconductor device in each process.

FIG. 12A is a figure for illustrating a process of a semiconductor device manufacturing method according to a second variant embodiment of the second embodiment of the present invention, and a sectional view diagrammatically showing a structure of a semiconductor device in each process.

FIG. 12B is a figure for illustrating a process of the semiconductor device manufacturing method according to the second variant embodiment of the second embodiment of the present invention, and a sectional view diagrammatically showing a structure of the semiconductor device in each process.

FIG. 12C is a figure for illustrating a process of the semiconductor device manufacturing method according to the second variant embodiment of the second embodiment of the present invention, and a sectional view diagrammatically showing a structure of the semiconductor device in each process.

FIG. 12D is a figure for illustrating a process of the semiconductor device manufacturing method according to the second variant embodiment of the second embodiment of the present invention, and a sectional view diagrammatically showing a structure of the semiconductor device in each process.

FIG. 12E is a figure for illustrating a process of the semiconductor device manufacturing method according to the second variant embodiment of the second embodiment of the present invention, and a sectional view diagrammatically showing a structure of the semiconductor device in each process.

FIG. 12F is a figure for illustrating a process of the semiconductor device manufacturing method according to the second variant embodiment of the second embodiment of the present invention, and a sectional view diagrammatically showing a structure of the semiconductor device in each process.

FIG. 12G is a figure for illustrating a process of the semiconductor device manufacturing method according to the second variant embodiment of the second embodiment of the present invention, and a sectional view diagrammatically showing a structure of the semiconductor device in each process.

FIG. 12H is a figure for illustrating a process of the semiconductor device manufacturing method according to the second variant embodiment of the second embodiment of the present invention, and a sectional view diagrammatically showing a structure of the semiconductor device in each process.

FIG. 12I is a figure for illustrating a process of the semiconductor device manufacturing method according to the second variant embodiment of the second embodiment of the present invention, and a sectional view diagrammatically showing a structure of the semiconductor device in each process.

FIG. 12J is a figure for illustrating a process of the semiconductor device manufacturing method according to the second variant embodiment of the second embodiment of the present invention, and a sectional view diagrammatically showing a structure of the semiconductor device in each process.

FIG. 12K is a figure for illustrating a process of the semiconductor device manufacturing method according to the second variant embodiment of the second embodiment of the present invention, and a sectional view diagrammatically showing a structure of the semiconductor device in each process.

FIG. 12L is a figure for illustrating a process of the semiconductor device manufacturing method according to the second variant embodiment of the second embodiment of the present invention, and a sectional view diagrammatically showing a structure of the semiconductor device in each process.

FIG. 13A is a figure for illustrating a process of a semiconductor device manufacturing method according to a third variant embodiment of the second embodiment of the present invention, and a sectional view diagrammatically showing a structure of a semiconductor device in each process.

FIG. 13B is a figure for illustrating a process of the semiconductor device manufacturing method according to the third variant embodiment of the second embodiment of the present invention, and a sectional view diagrammatically showing a structure of the semiconductor device in each process.

FIG. 13C is a figure for illustrating a process of the semiconductor device manufacturing method according to the third variant embodiment of the second embodiment of the present invention, and a sectional view diagrammatically showing a structure of the semiconductor device in each process.

FIG. 13D is a figure for illustrating a process of the semiconductor device manufacturing method according to the third variant embodiment of the second embodiment of the present invention, and a sectional view diagrammatically showing a structure of the semiconductor device in each process.

FIG. 13E is a figure for illustrating a process of the semiconductor device manufacturing method according to the third variant embodiment of the second embodiment of the present invention, and a sectional view diagrammatically showing a structure of the semiconductor device in each process.

FIG. 13F is a figure for illustrating a process of the semiconductor device manufacturing method according to the third variant embodiment of the second embodiment of the present invention, and a sectional view diagrammatically showing a structure of the semiconductor device in each process.

FIG. 13G is a figure for illustrating a process of the semiconductor device manufacturing method according to the third variant embodiment of the second embodiment of the present invention, and a sectional view diagrammatically showing a structure of the semiconductor device in each process.

FIG. 13H is a figure for illustrating a process of the semiconductor device manufacturing method according to the third variant embodiment of the second embodiment of the present invention, and a sectional view diagrammatically showing a structure of the semiconductor device in each process.

FIG. 13I is a figure for illustrating a process of the semiconductor device manufacturing method according to the third variant embodiment of the second embodiment of the present invention, and a sectional view diagrammatically showing a structure of the semiconductor device in each process.

FIG. 13J is a figure for illustrating a process of the semiconductor device manufacturing method according to the third variant embodiment of the second embodiment of the present invention, and a sectional view diagrammatically showing a structure of the semiconductor device in each process.

FIG. 13K is a figure for illustrating a process of the semiconductor device manufacturing method according to the third variant embodiment of the second embodiment of the present invention, and a sectional view diagrammatically showing a structure of the semiconductor device in each process.

FIG. 13L is a figure for illustrating a process of the semiconductor device manufacturing method according to the third variant embodiment of the second embodiment of the present invention, and a sectional view diagrammatically showing a structure of the semiconductor device in each process.

FIG. 14A is a figure for illustrating a process of a semiconductor device manufacturing method according to a fourth variant embodiment of the second embodiment of the present invention, and a sectional view diagrammatically showing a structure of a semiconductor device in each process.

FIG. 14B is a figure for illustrating a process of the semiconductor device manufacturing method according to the fourth variant embodiment of the second embodiment of the present invention, and a sectional view diagrammatically showing a structure of the semiconductor device in each process.

FIG. 14C is a figure for illustrating a process of the semiconductor device manufacturing method according to the fourth variant embodiment of the second embodiment of the present invention, and a sectional view diagrammatically showing a structure of the semiconductor device in each process.

FIG. 14D is a figure for illustrating a process of the semiconductor device manufacturing method according to the fourth variant embodiment of the second embodiment of the present invention, and a sectional view diagrammatically showing a structure of the semiconductor device in each process.

FIG. 14E is a figure for illustrating a process of the semiconductor device manufacturing method according to the fourth variant embodiment of the second embodiment of the present invention, and a sectional view diagrammatically showing a structure of the semiconductor device in each process.

FIG. 14F is a figure for illustrating a process of the semiconductor device manufacturing method according to the fourth variant embodiment of the second embodiment of the present invention, and a sectional view diagrammatically showing a structure of the semiconductor device in each process.

FIG. 14G is a figure for illustrating a process of the semiconductor device manufacturing method according to the fourth variant embodiment of the second embodiment of the present invention, and a sectional view diagrammatically showing a structure of the semiconductor device in each process.

FIG. 14H is a figure for illustrating a process of the semiconductor device manufacturing method according to the fourth variant embodiment of the second embodiment of the present invention, and a sectional view diagrammatically showing a structure of the semiconductor device in each process.

FIG. 14I is a figure for illustrating a process of the semiconductor device manufacturing method according to the fourth variant embodiment of the second embodiment of the present invention, and a sectional view diagrammatically showing a structure of the semiconductor device in each process.

FIG. 14J is a figure for illustrating a process of the semiconductor device manufacturing method according to the fourth variant embodiment of the second embodiment of the present invention, and a sectional view diagrammatically showing a structure of the semiconductor device in each process.

FIG. 14K is a figure for illustrating a process of the semiconductor device manufacturing method according to the fourth variant embodiment of the second embodiment of the present invention, and a sectional view diagrammatically showing a structure of the semiconductor device in each process.

FIG. 14L is a figure for illustrating a process of the semiconductor device manufacturing method according to the fourth variant embodiment of the second embodiment of the present invention, and a sectional view diagrammatically showing a structure of the semiconductor device in each process.

FIG. 15A is a figure for illustrating a process of a semiconductor device manufacturing method according to a fifth variant embodiment of the second embodiment of the present invention, and a sectional view diagrammatically showing a structure of a semiconductor device in each process.

FIG. 15B is a figure for illustrating a process of the semiconductor device manufacturing method according to the fifth variant embodiment of the second embodiment of the present invention, and a sectional view diagrammatically showing a structure of the semiconductor device in each process.

FIG. 15C is a figure for illustrating a process of the semiconductor device manufacturing method according to the fifth variant embodiment of the second embodiment of the present invention, and a sectional view diagrammatically showing a structure of the semiconductor device in each process.

FIG. 15D is a figure for illustrating a process of the semiconductor device manufacturing method according to the fifth variant embodiment of the second embodiment of the present invention, and a sectional view diagrammatically showing a structure of the semiconductor device in each process.

FIG. 15E is a figure for illustrating a process of the semiconductor device manufacturing method according to the fifth variant embodiment of the second embodiment of the present invention, and a sectional view diagrammatically showing a structure of the semiconductor device in each process.

FIG. 15F is a figure for illustrating a process of the semiconductor device manufacturing method according to the fifth variant embodiment of the second embodiment of the present invention, and a sectional view diagrammatically showing a structure of the semiconductor device in each process.

FIG. 15G is a figure for illustrating a process of the semiconductor device manufacturing method according to the fifth variant embodiment of the second embodiment of the present invention, and a sectional view diagrammatically showing a structure of the semiconductor device in each process.

FIG. 15H is a figure for illustrating a process of the semiconductor device manufacturing method according to the fifth variant embodiment of the second embodiment of the present invention, and a sectional view diagrammatically showing a structure of the semiconductor device in each process.

FIG. 15I is a figure for illustrating a process of the semiconductor device manufacturing method according to the fifth variant embodiment of the second embodiment of the present invention, and a sectional view diagrammatically showing a structure of the semiconductor device in each process.

FIG. 15J is a figure for illustrating a process of the semiconductor device manufacturing method according to the fifth variant embodiment of the second embodiment of the present invention, and a sectional view diagrammatically showing a structure of the semiconductor device in each process.

FIG. 15K is a figure for illustrating a process of the semiconductor device manufacturing method according to the fifth variant embodiment of the second embodiment of the present invention, and a sectional view diagrammatically showing a structure of the semiconductor device in each process.

FIG. 15L is a figure for illustrating a process of the semiconductor device manufacturing method according to the fifth variant embodiment of the second embodiment of the present invention, and a sectional view diagrammatically showing a structure of the semiconductor device in each process.

FIG. 16 is a process diagram for illustrating procedures of respective processes of a semiconductor device manufacturing method according to a sixth variant embodiment of the second embodiment of the present invention.

FIG. 17A is a figure for illustrating a process of the semiconductor device manufacturing method according to the sixth variant embodiment of the second embodiment of the present invention, and a sectional view diagrammatically showing a structure of a semiconductor device in each process.

FIG. 17B is a figure for illustrating a process of the semiconductor device manufacturing method according to the sixth variant embodiment of the second embodiment of the present invention, and a sectional view diagrammatically showing a structure of the semiconductor device in each process.

FIG. 17C is a figure for illustrating a process of the semiconductor device manufacturing method according to the sixth variant embodiment of the second embodiment of the present invention, and a sectional view diagrammatically showing a structure of the semiconductor device in each process.

FIG. 17D is a figure for illustrating a process of the semiconductor device manufacturing method according to the sixth variant embodiment of the second embodiment of the present invention, and a sectional view diagrammatically showing a structure of the semiconductor device in each process.

FIG. 17E is a figure for illustrating a process of the semiconductor device manufacturing method according to the sixth variant embodiment of the second embodiment of the present invention, and a sectional view diagrammatically showing a structure of the semiconductor device in each process.

FIG. 17F is a figure for illustrating a process of the semiconductor device manufacturing method according to the sixth variant embodiment of the second embodiment of the present invention, and a sectional view diagrammatically showing a structure of the semiconductor device in each process.

FIG. 17G is a figure for illustrating a process of the semiconductor device manufacturing method according to the sixth variant embodiment of the second embodiment of the present invention, and a sectional view diagrammatically showing a structure of the semiconductor device in each process.

FIG. 17H is a figure for illustrating a process of the semiconductor device manufacturing method according to the sixth variant embodiment of the second embodiment of the present invention, and a sectional view diagrammatically showing a structure of the semiconductor device in each process.

FIG. 17I is a figure for illustrating a process of the semiconductor device manufacturing method according to the sixth variant embodiment of the second embodiment of the present invention, and a sectional view diagrammatically showing a structure of the semiconductor device in each process.

FIG. 17J is a figure for illustrating a process of the semiconductor device manufacturing method according to the sixth variant embodiment of the second embodiment of the present invention, and a sectional view diagrammatically showing a structure of the semiconductor device in each process.

FIG. 17K is a figure for illustrating a process of the semiconductor device manufacturing method according to the sixth variant embodiment of the second embodiment of the present invention, and a sectional view diagrammatically showing a structure of the semiconductor device in each process.

FIG. 17L is a figure for illustrating a process of the semiconductor device manufacturing method according to the sixth variant embodiment of the second embodiment of the present invention, and a sectional view diagrammatically showing a structure of the semiconductor device in each process.

FIG. 18 is a plan view diagrammatically showing one example of a configuration of a semiconductor device manufacturing apparatus for carrying out a semiconductor device manufacturing method according to a third embodiment of the present invention.

### DESCRIPTION OF REFERENCE NUMERALS

W wafer
L1, L2, L3, L4, L11, L12, L31, L41 line width
S1, S11, S12, S2 space width
D thickness
L101, L102, L103, L104, L111, L131, L141 line width
S101, S102, S103, S104 space width
D101 thickness
10 substrate
11, 11a to-be-etched layer
13 organic film
14, 14b protective film
15 first photoresist film
15a, 15b core part
16 SiO₂ film
16a side wall part
17 second photoresist film
21 first pattern
22 second pattern
23, 23a third pattern
24, 24a fourth pattern
25 fifth pattern
110 substrate
111, 111b first to-be-etched layer
112, 112a second to-be-etched layer
113 organic film
114 protective film
115 second photoresist film
116 SiO₂ film
117 first photoresist film
121, 121a first pattern
122 second pattern
123 third pattern
124 fourth pattern
125 core part
126 side wall part
128 fifth pattern
129 sixth pattern

### BEST MODE FOR CARRYING OUT THE INVENTION

Next, a best mode for carrying out the present invention will be described with reference to figures.

### First Embodiment

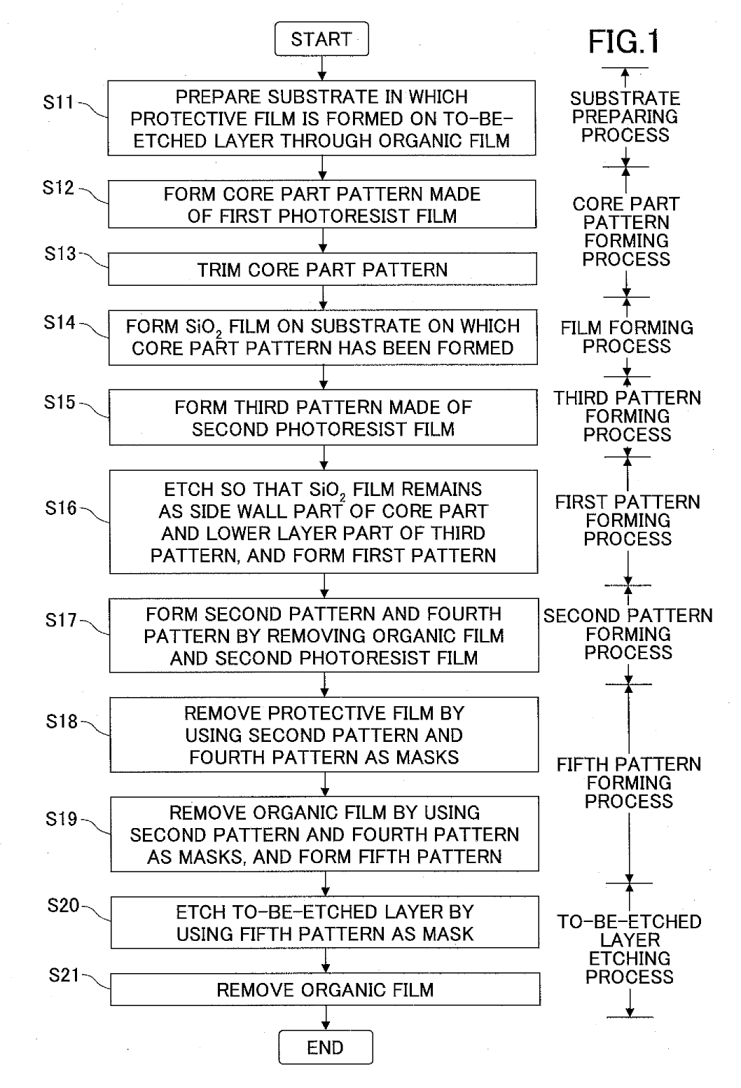

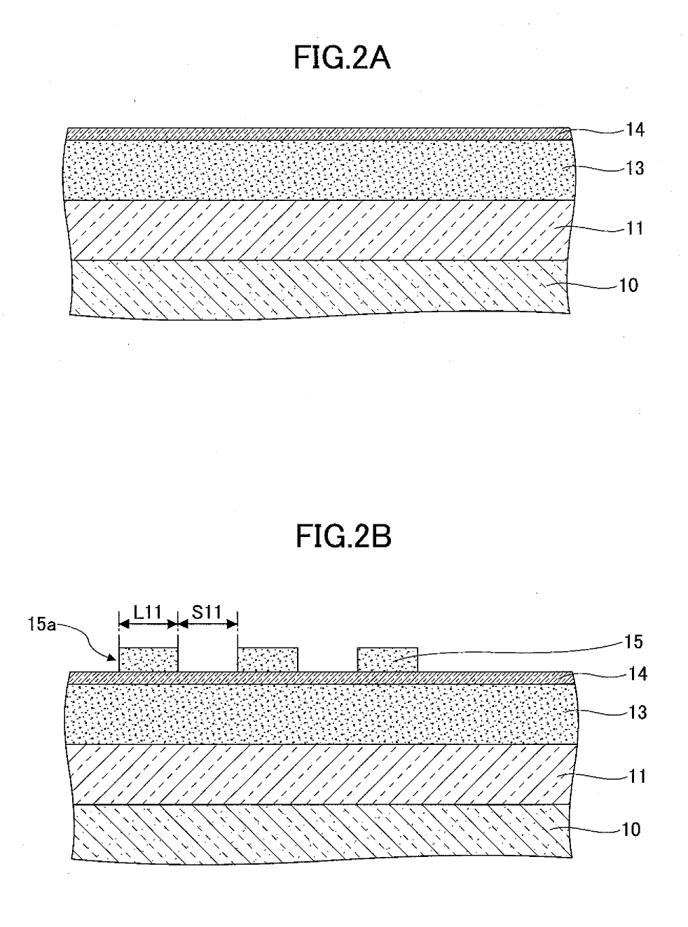

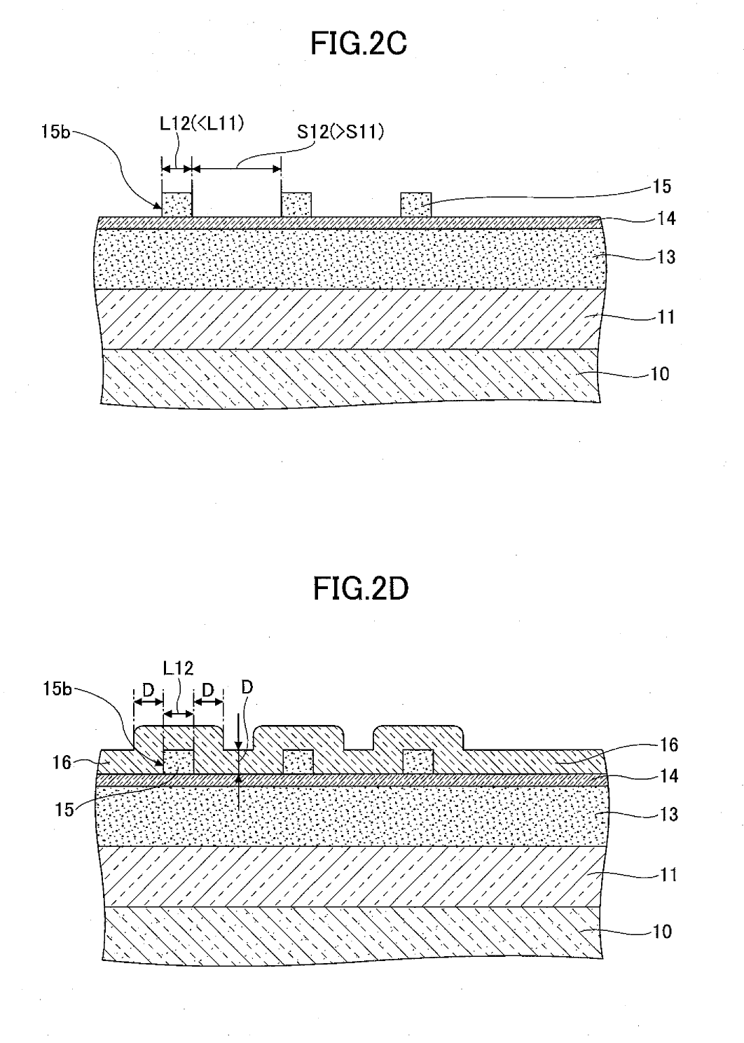

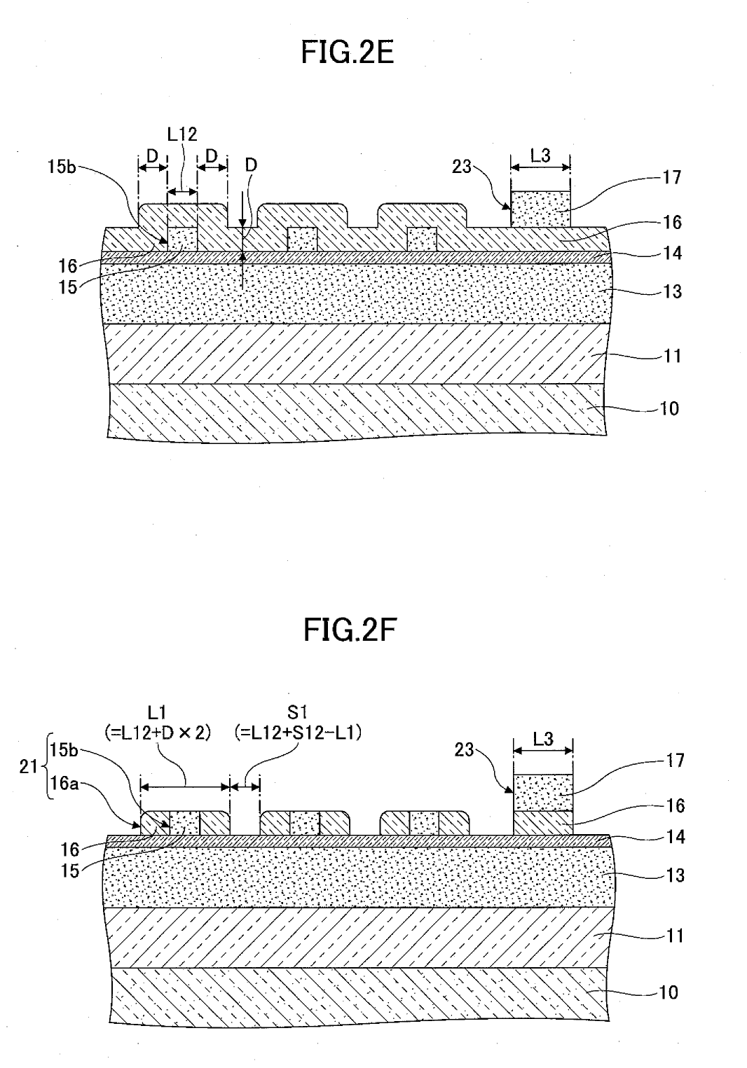

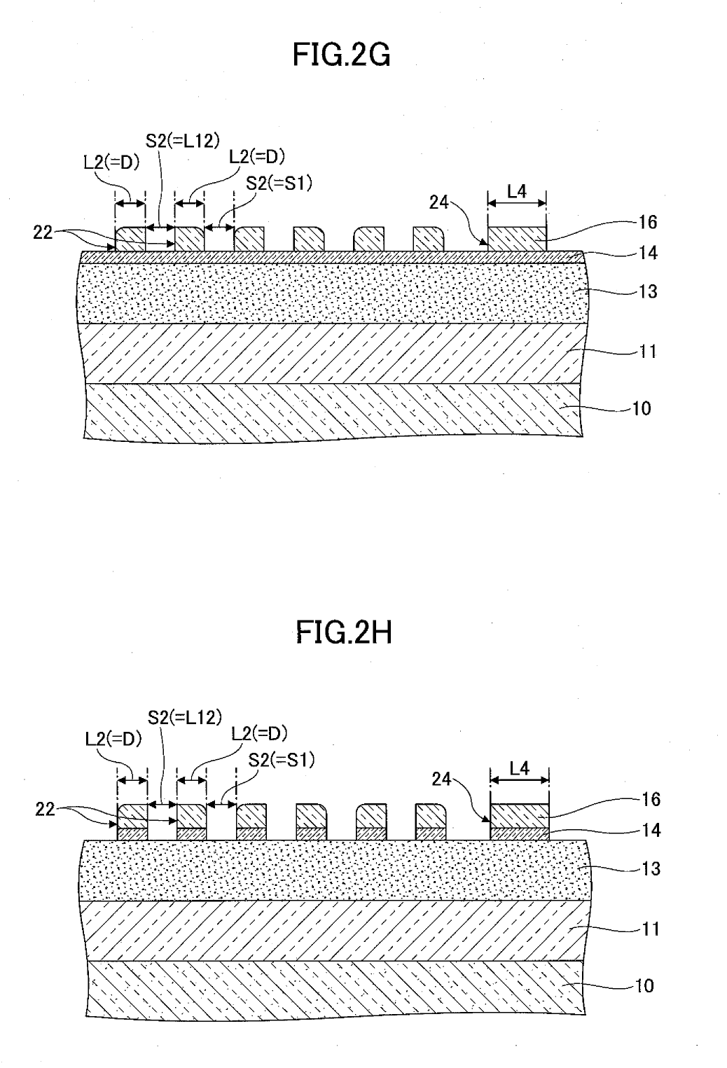

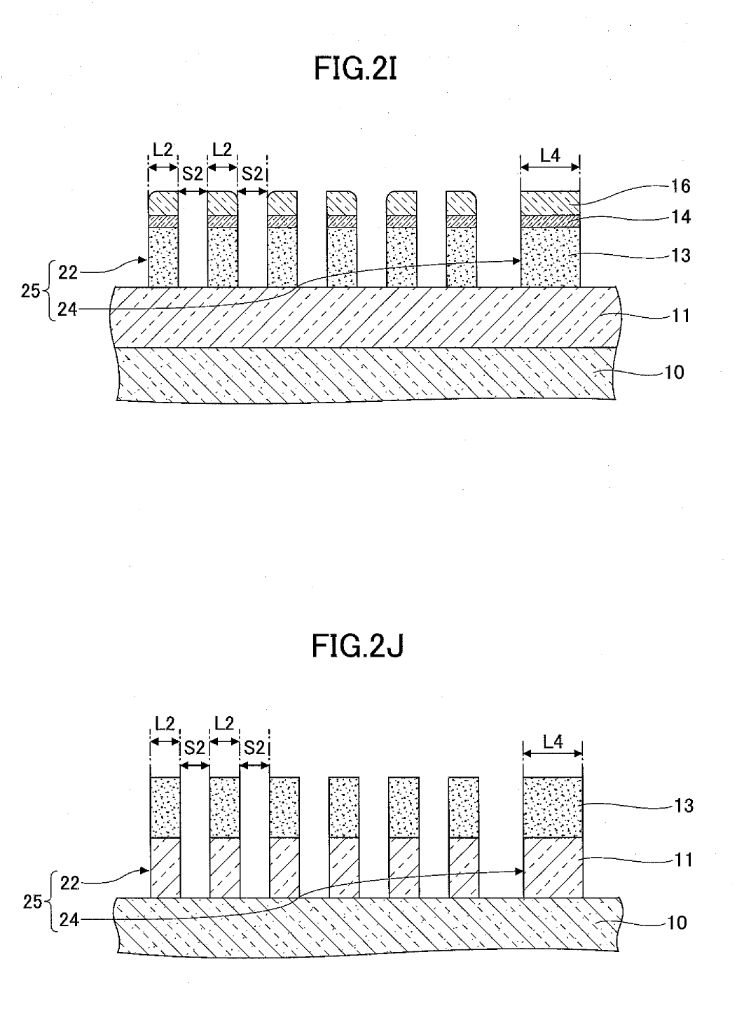

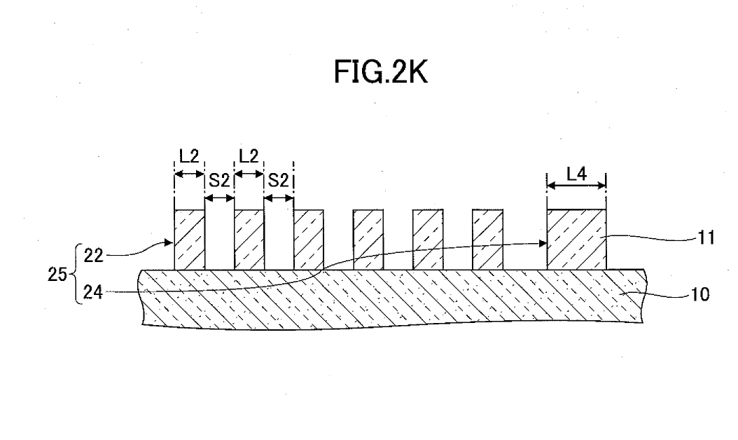

With reference to FIGS. 1 through 2K, a semiconductor device manufacturing method according to a first embodiment of the present invention will be described.

Below, a first photoresist film, a core part pattern, a core part pattern forming process, a film forming process, a first pattern, a first pattern forming process, a second photoresist film, a third pattern, a third pattern forming process, a fourth pattern, a second pattern, and a second pattern forming process in the present embodiment and respective variant embodiments of the present embodiment correspond to a first organic film, a first organic film pattern, a first organic film pattern forming process, a silicon oxide film forming process, a first mask pattern, a first mask pattern forming process, a second organic film, a second organic film pattern, a second organic film pattern forming process, a second mask pattern, a third mask pattern, and a third mask pattern forming process according to the present invention, respectively.

Further, a line width L12 and a thickness D of the present embodiment and the respective variant embodiments of the present embodiment correspond to a first dimension and a second dimension according to the present invention, respectively.

FIG. 1 is a process diagram for illustrating respective processes of the semiconductor device manufacturing method according to the present embodiment. Further, FIGS. 2A through 2K are figures for illustrating processes of the semiconductor device manufacturing method according to the present embodiment, and sectional views diagrammatically showing structures of a semiconductor device in the respective processes. Further, the structures of the semiconductor device after the respective processes of steps S11 through S21 of FIG. 1 are carried out correspond to the structures shown in the respective sectional views of FIGS. 2A through 2K.

The semiconductor device manufacturing method according to the present embodiment includes, as shown in FIG. 1, a substrate preparing process, a core part pattern forming process, a film forming process, a third pattern forming process, a first pattern forming process, a second pattern forming process, a fifth pattern forming process, and a to-be-etched layer etching process. The substrate preparing process includes a process of step S11, the core part pattern forming process includes processes of steps S12 and S13, the film forming process includes a process of step S14, the third pattern forming process includes a process of step S15, the first pattern forming process includes a process of step S16, the second pattern forming process includes a process of step S17, the fifth pattern forming process includes processes of steps S18 and S19, and the to-be-etched layer etching process includes processes of steps S20 and S21.

First, the preparing process including step S11 is carried out. Step S11 is a process of preparing a substrate in which on a to-be-etched layer, a protective film is formed through an organic film. FIG. 2A is a sectional view showing a structure of a semiconductor device after the process of step S11 is carried out.

In step S11, as shown in FIG. 2A, the substrate is prepared in which on the substrate 10, the to-be-etched layer 11, the organic film 13 and the protective film 14 are formed in the stated order from the bottom. The to-be-etched layer 11 functions as a mask to be used for carrying out subsequent various processing processes as a result of patterns being formed. Patterns are formed in the organic film 13 and the organic film 13 functions as a mask for forming the patterns in the to-be-etched layer 11. As will be described later, the protective film 14 has a function to protect a surface of the organic film 13 when patterns of core parts 15b made of first photoresist films 15 are formed. Further, there is a case where the protective film 14 has a function as a reflection preventing film (BARC: Bottom Anti-Reflecting Coating) when photolithography of the first photoresist film 15 formed on the protective layer 14 is carried out.

A material of the to-be-etched layer 11 is not particularly limited, and, for example, TEOS may be used. Further, a thickness of the first to-be-etched layer 11 is not particularly limited, and, for example, may be 50 through 500 nm.

A material of the organic film 13 is not particularly limited, and, for example, a broad range of organic materials may be used, which includes amorphous carbon formed by a chemical vapor deposition (CVD) method, polyphenol, a film of which is formed by spin on, and photoresist such as i-ray resist. Further, a thickness of the organic film 13 is not particularly limited, and, for example, may be 100 through 400 nm.

A material of the protective film 14 is not particularly limited, and, for example, a SOG (Spin On Glass) film, a SiON film, or a composite film of a LTO (Low Temperature Oxide) film and BARC, may be used. Further, a thickness of the protective film 14 is not particularly limited, and, for example, may be 40 through 120 nm.

Next, the core part pattern forming process including steps S12 and S13 is carried out.

Step S12 is a core part pattern forming process of forming a first photoresist film 15, exposing and developing the formed first photoresist film 15, and forming patterns of core parts 15a made of the first photoresist film 15. As a result, as shown in FIG. 2B, the patterns of the core parts 15a made of the first photoresist film 15 are formed. The patterns of the core parts 15a function as cores for forming side wall parts that coat both side faces of the patterns of the core parts 15a.

As a material of the first photoresist film 15, ArF resist may be used for example. Further, a thickness of the first photoresist film 15 is not particularly limited, and, for example, may be 50 through 200 nm. A line width L11 and a space width S11 of the patterns of the core parts 15a are not particularly limited, and, for example, both may be 60 nm.

Step S13 is a process of trimming the first photoresist films 15 that form the patterns of the core parts 15a, and forming patterns of core parts 15b having a line width thinner than the line width of the patterns of the core parts 15a. Further, FIG. 2C is a sectional view showing a structure of the semiconductor device after the process of step S13 is carried out.

A method of the trimming is not particularly limited, and, for example, plasma of oxygen, nitrogen, hydrogen, ammonia or such is used. As shown in FIGS. 2B and 2C, the line width L12 of the patterns of the core parts 15b obtained from the trimming is thinner than the line width L11 of the patterns of the core parts 15a before the trimming is carried out. Therefore, size relations between the line width L11 and the space width S11 of the patterns of the core parts 15a and the line width L12 and the space width S12 of the patterns of the core parts 15b are, L12<L11, L12>S11. Values of L12 and S12 are not particularly limited, and, for example, L12 may be 30 nm, and S12 may be 90 nm.

Step S14 is the film forming process of forming a SiO₂ film 16 on the substrate on which the patterns of the core parts 15b have been formed. Further, FIG. 2D is a sectional view showing a structure of the semiconductor device after step S14 is carried out.

It is noted that the SiO₂ film corresponds to a silicon oxide film according to the present invention. Further, hereinafter, instead of the SiO₂ film, a film of another composition that predominantly contains silicon and oxygen, such as a SiOₓ film, may be used.

The film forming process for the SiO₂ film 16 is carried out in a condition in which the first photoresist film 15 remains as the core parts 15b. Since photoresist is weak against a high temperature generally speaking, the film forming process may be preferably carried out at a low temperature (for example, on the order of equal to or less than 300° C.). A film forming method is not particular limited as long as film forming can be carried out at a low temperature as mentioned above, and, in the present embodiment, the film forming may be carried out by molecular layer deposition (hereafter referred to as MLD) at a low temperature, i.e., low-temperature MLD. As a result, as shown in FIG. 2D, the SiO₂ film 16 is formed throughout the surface of the substrate including places at which the core parts 15b are formed and places at which the core parts 15b are not formed, and further, the SiO₂ film 16 is formed also on side faces of the core parts 15b to coat the side faces of the core parts 15b. Assuming that a thickness of the SiO₂ film 16 is D, a width of the SiO₂ film 16 coating the side faces of the core parts 15b is also D. The thickness D of the SiO₂ film 16 is not particularly limited, and, for example, may be 30 nm.

Here, the film forming process according to the low-temperature MLD will be described.

In the low-temperature MLD, a process of supplying a source gas including silicon to a processing chamber and adsorption of the silicon raw material on a substrate and a process of supplying a gas containing oxygen to the processing chamber and oxidizing the silicon raw material are repeated alternately.

Specifically, in the process of adsorption of the silicon raw material on the substrate, as the source gas containing silicon, a silane gas of a network having two amino groups in one molecule, for example, bis-tertiary-butylamino silane (referred to as BTBAS, hereinafter), is supplied to the processing chamber through a supply nozzle of the silicon source gas for a predetermined time period (T1). Thus, adsorption of BTBAS is carried out on the substrate. The time period of T1 may be, for example, 1 through 60 seconds. A flow rate of the source gas containing silicon may be 10 through 500 mL/min (sccm). Further, a pressure in the inside of the processing chamber may be 13.3 through 665 Pa.

Next, in the process of supplying the gas containing oxygen to the processing chamber and oxidizing the silicon raw material, as the gas containing oxygen, for example, plasma of O₂ gas obtained by using a plasma generating mechanism that includes a high-frequency power source is supplied to the processing chamber for a predetermined time period (T2) through a gas supply nozzle. Thereby, BTBAS, adsorption of which on the substrate has been carried out, is oxidized, and the SiO₂ film 16 is formed. The time period T2 may be, for example, 5 through 300 seconds. Further, a flow rate of the gas containing oxygen may be 100 through 20000 mL/min (sccm). Further, a frequency of the high-frequency power source may be 13.56 MHz. Electric power of the high-frequency power source may be 5 through 1000 W. A pressure in the inside of the processing chamber may be 13.3 through 665 Pa.

Further, on the occasion of switching between the process of adsorption of the source gas containing silicon on the substrate and the process of supplying the gas containing oxygen and oxidizing the silicon material, a process of supplying a purge gas made of an inactive gas such as a N₂ gas, for example, to the processing chamber while carrying out vacuum evacuation of the processing chamber may be carried out for a predetermined time period (T3) between the respective processes for the purpose of removing the residual gas in the immediately preceding process. The time period of T3 may be, for example, 1 through 60 seconds. A flow rate of the purge gas may be 50 through 5000 mL/min (sccm). It is noted that this process is carried out for the purpose of removing the gas remaining in the processing chamber. Therefore, in this process, vacuum evacuation may be proceeded to continuously in a condition in which all the supply of the gas has been stopped without supplying the purge gas.

BTBAS is amino silane gas having two amino groups in one molecule used as the source gas containing silicon. As such an amino silane gas, other than the above-mentioned BTBAS, bis-diethylamino silane (BDEAS), bis-dimethylamino silane (BDMAS), diisopropyl amino silane (DIPAS), or bis-ethylmethylamino silane (BDEAS) may be used. Further, as the silicon source gas, an amino silane gas having three or more amino groups in one molecule may be used, or, further, an amino silane gas having one amino group in one molecule may also be used.

On the other hand, as the gas containing oxygen, a NO gas, a N₂O gas, H₂O gas or O₃ gas may be used, other than the O₂ gas. Plasma may be obtained therefrom by using a high-frequency electric field and may be used as an oxidizing agent. By using such plasma of the gas containing oxygen, it is possible to form the SiO₂ film at a temperature equal to or less than 300° C. Further, by adjusting the gas flow rate of the gas containing oxygen, the electrical power of the high-frequency power source and the pressure in the inside of the processing chamber, it is possible to form the SiO₂ film at a temperature equal to or less than 100° C., or at room temperature.

Next, the third pattern forming process including step S15 is carried out. Step S15 is a process of forming a third pattern 23 made of a second photoresist film 17 at a place at which the patterns of the core parts 15b are not formed. Further, FIG. 2E is a sectional view showing a structure of the semiconductor device after the process of step S15 is carried out.

As shown in FIG. 2E, at a position adjacent to the patterns of the core parts 15b, the third pattern 23 is formed. The position of forming the third pattern 23 is not particularly limited as long as the position does not overlap with the patterns of the core parts 15b. In the present embodiment, the third pattern 23 is positioned adjacent to the patterns of the core parts 15b. The second photoresist film 17 functions as a mask for forming a fourth pattern 24 having the same shape as that of the third pattern 23, without removing the patterns of the core parts 15b from the first patterns 21 including the core parts 15b and the side wall parts 16a and forming second patterns 22 made of the side wall parts 16a. Assuming that a line width of the third pattern 23 is L3, a value of L3 is not particularly limited, and, for example, may be 60 nm.

As a material of the second photoresist film 17, for example, KrF resist or ArF resist may be used. Further, a thickness of the second photoresist 17 is not particularly limited, and, for example, may be 50 through 300 nm.

Here, because the line width L3 of the third pattern 23 is fine, a metal mask having high accuracy is like a metal mask used for carrying out lithography for forming the patterns of the core parts 15a, and the costs for manufacturing the metal mask are required. However, as will be described later in a description of step S20, according to the present invention, although odd number patterns are added to even number patterns, a process of etching the to-be-etched layer 11 can be carried out in a lump by using the organic film 13 as a mask for when the to-be-etched layer 11 is etched. Therefore, a selection range for the material of the to-be-etched layer 11 increases, and it is possible to reduce the total manufacturing costs.

It is noted that it is possible to carry out a trimming process like step S13 after step S15 is carried out, and, in step S15, it is possible to cause a line width of the pattern 23 made of the second photoresist film 17 to be L3 (60 nm) shown in FIG. 2E, by previously forming the pattern 23 to have L3′ (for example, 120 nm) larger than the line width L3 shown in FIG. 2E, and carrying out the trimming. In this case, in step S15, it is not necessary to manufacture a high-accuracy metal mask as a metal mask for forming the third pattern 23 of the second photoresist film 17, and it is possible to further reduce the total manufacturing costs.

Next, step S16 is carried out. Step S16 is an etching process of carrying out etching so that the SiO₂ film 16 remains as the side wall parts 16a of the core parts 15b and a lower layer part of the third pattern 23 made of the second photoresist film 17. Further, FIG. 2F is a sectional view showing a structure of the semiconductor device after the process S16 is carried out.

As shown in FIG. 2F, a state results such that the SiO₂ film 16 has been etched, and the SiO₂ film 16 remains only as the side wall parts 16a coating the side faces of the core parts 15b and the lower layer part of the third pattern 23 made of the second photoresist film 17. The etching of the SiO₂ film 16 is not particularly limited, and, for example, may be carried out by using a mixed gas of a gas of a CF family, such as CF₄, C₄F₈, CHF₃. CH₃F or CH₂F₂, and an Ar gas or such, or, a gas obtained from adding oxygen as is necessary to the mixed gas, or such. At a place at which the etching is carried out so that the side wall parts 16a of the core parts 15b of the SiO₂ film 16 remain, the first patterns 21 made of the core parts 15b and the side wall parts 16a are formed. Assuming that a line width of the first patterns 21 is L1 and a space width thereof is S1, L1 may be 90 nm and S1 may be 30 nm because of L1=L12+D×2 and S1=L12+S12−L1, in a case where the line width L12 of the core parts 15b is 30 nm and the thickness D of the side wall parts 16a is 30 nm. Further, a line width L4 of a part of the SiO₂ film remaining as a part of the lower layer part of the third pattern 23 made of the second photoresist film 17 is equal to L3 and is 60 nm.

Next, the second pattern forming process including step S17 is carried out. Step S17 is the second pattern forming process of forming the second patterns 22 made of the side wall parts 16a remaining as a result of the core parts 15b being removed. It is noted that by carrying out the second pattern forming process, the fourth pattern 24 having the same shape as that of the third pattern 23 is formed simultaneously together with the second patterns 22. Further, FIG. 2G is a sectional view showing a structure of the semiconductor device after the process of step S17 is carried out.

By carrying out etching by using plasma of oxygen, nitrogen, hydrogen, ammonia or such, the first photoresist films 15 of the core parts 15b are removed. As a result, as shown in FIG. 2G, in the first patterns 21, the first photoresist films 15 of the core parts 15b are removed, only the side wall parts 16a remain, and the second patterns 22 are formed which are patterns such that the line width is D and the space widths L12 and S1 alternately occur. In the present embodiment, as a result of the line width L12 of the core parts 15b and the space width S1 of the first patterns 21 being made equal to one another, the space width is S2 that is equal to L12 and S1. Further, the line width equal to D is referred to as L2. As described above, as a result of L12 being 30 nm, S1 being 30 nm, and the thickness of the SiO₂ film 16 (the width D of the side wall parts 16a) being 30 nm, it is possible to form the second patterns in which L2 is 30 nm and S2 is 30 nm.

Further, the first photoresist film 15 is removed, the second photoresist film 17 forming the third pattern 23 is also removed, and the fourth pattern 24 that is the lower layer part of the third pattern 23 and having the shape the same as that of the third pattern 23 is formed. Assuming that the line width of the fourth pattern 24 is L4, L4 is equal to L3, and, for example, L4 is 60 nm when L3 is 60 nm, since the fourth pattern 24 has the same shape as that of the third pattern 23.

Next, the fifth pattern forming process including steps S18 and S19 is carried out.

Step S18 is a process of etching the protective film 14 by using the second pattern 22 and the fourth pattern 24 made of the SiO₂ film 16 as masks. Further, FIG. 2H is a sectional view showing a structure of the semiconductor device after the process of step S18 is carried out.

The second patterns 22 having the line width L2 and the space width S2 and made of the SiO₂ films 16 and the fourth pattern 24 having the line width L4 and made of the SiO₂ film 16 are used as masks, and the protective film 14 is etched. Thus are formed the second patterns 22 having the line width L2 and the space width S2 and the fourth pattern 24 having the line width L4 in which the SiO₂ films 16 and the protective films 14 are laminated. Etching of the protective film 14 may use, for example, a mixed gas of a gas of a CF family, such as CF₄, C₄F₈, CHF₃, CH₃F or CH₂F₂, and an Ar gas or such, or, a gas obtained from adding oxygen as is necessary to the mixed gas, in a case where the protective film 14 is, for example, a SOG film (or SiON film, or a composite film of a LTO film and BARC).

Step S19 is a fifth pattern forming process of, by etching the organic film 13 by using the second patterns 22 and the fourth pattern 24 as masks, forming the fifth patterns 25 including the second patterns 22 and the fourth pattern 24 in which the SiO₂ films 16, the protective films 14 and the organic films 13 are laminated. Further, FIG. 2I is a sectional view showing a structure of the semiconductor device after the process of step S19 is carried out.

Etching of the organic film 13 is not particularly limited, and, for example, plasma of oxygen, nitrogen, hydrogen, ammonia or such may be used. As a result, as shown in FIG. 2I, the organic film 23 is etched by using the second patterns 22 in which the SiO₂ films 16 and the protective films 14 are laminated and the fourth pattern 24 in which the SiO₂ film 16 and the protective film 14 are laminated as masks, and the fifth patterns 25 including the second patterns 22 having the line width L2 and the space width S2 in which the SiO₂ films, the protective films 14 and the organic films 13 are laminated and the fourth pattern 24 having the line width L4 are formed.

Next, the to-be-etched layer etching process including steps S20 and S21 is carried out.

Step S20 is a process of etching the to-be-etched layer 11 that is a lower layer of the organic film 13 by using the fifth patterns 25 including the second patterns 22 and the fourth pattern 24 as masks, and forms the fifth patterns 25 in which the organic films 13 and the to-be-etched layers 11 are laminated and including the second patterns 22 and the fourth pattern 24. Further, FIG. 2J is a sectional view showing a structure of the semiconductor device after the process of step S20 is carried out.

The fifth patterns 25 made of the organic films 13 are used as masks, and the to-be-protective layer 11 is etched by using the substrate 10 as an etching stopper layer. Etching of the to-be-etched layer 11 that is made of, for example, TEOS, may be carried out by using a mixed gas of a gas of a CF family, such as CF₄, C₄F₈, CHF₃, CH₃F or CH₂F₂, and an Ar gas or such, or, a gas obtained from adding oxygen as is necessary to the mixed gas, or such, for example. As a result, as shown in FIG. 2J, it is possible to form, simultaneously, the second patterns 22 that are even number patterns having the line width L2 and the space width S2 and the fourth pattern 24 that is an odd number pattern having the line width L4. It is noted that, the organic films 13 remain without being removed at upper layers parts of the second patterns 22 and the fourth pattern 24.

Step S21 is a process of removing the organic films 13. FIG. 2K is a sectional view showing a structure of the semiconductor device after the process of step S21 is carried out.

Removing the organic films 13 is carried out by etching using plasma of oxygen, nitrogen, hydrogen, ammonia or such, for example. As a result, as shown in FIG. 2K, the organic films 13 remaining on the to-be-etched layers 11 that form the second patterns 22 and the fourth pattern 24 are removed, and it is possible to form, simultaneously, the second patterns 22 and the fourth pattern 24 made of the to-be-etched layers 11.

Thus, according to the present embodiment, only by carrying out fine photolithography by using the masks of, for example, the line width 60 nm, it is possible to form the fine even number patterns of, for example, the line width 30 nm and the space width 30 nm, and simultaneously, only by carrying out the fine photolithography again by using the mask of, for example, the line width 60 nm, before the etching process of SiO₂ film in such a manner to retain the side wall parts made of the SiO₂ films, it is possible to form the odd number pattern having, for example, the line width 60 nm, while the etching process for the to-be-etched layer is carried out in a lump.

For example, also by the method disclosed by Patent Document 3, it is possible to form even number patterns in an area of fine pattern density, and simultaneously, odd number patterns or an isolated pattern in an area of coarse pattern density. However, in the method disclosed by Patent Document 3, core part patterns for forming fine patterns are made of amorphous carbon films, and side wall parts that coat the side walls of the core part patterns are made of silicon oxide films. Thus, materials of the patterns that are used as hard masks used for etching a to-be-etched layer are different between the area of fine pattern density and the area of coarse pattern density. If the materials of the patterns are different, influences, such as etching resistance in a lateral direction, a ratio (selection ratio) in etching rates with respect to the lower layer and so forth for when the to-be-etched layer is etched, are different. Thus, it is not possible to make uniform the influences throughout the area of the masks. As a result, in the case where the area of fine pattern density and the area of coarse pattern density are mixed in the patterns used as the hard masks, it is not possible to maintain CD (Critical Dimension) of the patterns to be uniform at high accuracy.

On the other hand, in the present embodiment, both the patterns of the core parts used for forming the fine patterns and the side wall parts that coat the side walls of the patterns of the core parts are made of the silicon oxide films. Therefore, the materials of the patterns that are used as the hard masks used for etching the to-be-etched layer are identical between the area of fine pattern density and the area of coarse pattern density. As the materials of the patterns are thus identical, influences, such as etching resistance in a lateral direction, a ratio (selection ratio) in etching rates with respect to the lower layer and so forth for when the to-be-etched layer is etched, are identical. Thus, it is possible to make uniform the influences throughout the area of the masks. As a result, in the case where the area of fine pattern density and the area of coarse pattern density are mixed in the patterns used as the hard masks, it is possible to maintain CD (Critical Dimension) of the patterns to be uniform at high accuracy.

Further, by changing the material and thickness of the organic film 13, it is possible to cause the organic films 13 to function as the masks for the to-be-etched layer 11 even in a case where various materials are used as the to-be-etched layer 11. Especially, in the removing of the organic films 13 in step S21, etching using plasma of oxygen, nitrogen, hydrogen, ammonia or such is carried out. Therefore, it is possible to easily remove the organic films 13 even in a case where the organic films 13 are thick. Therefore, it is possible to use various materials as the to-be-etched layer 11, and, by using a material of low costs or a film forming method of low costs, it is possible to reduce the costs of the semiconductor device manufacturing method according to the present embodiment.

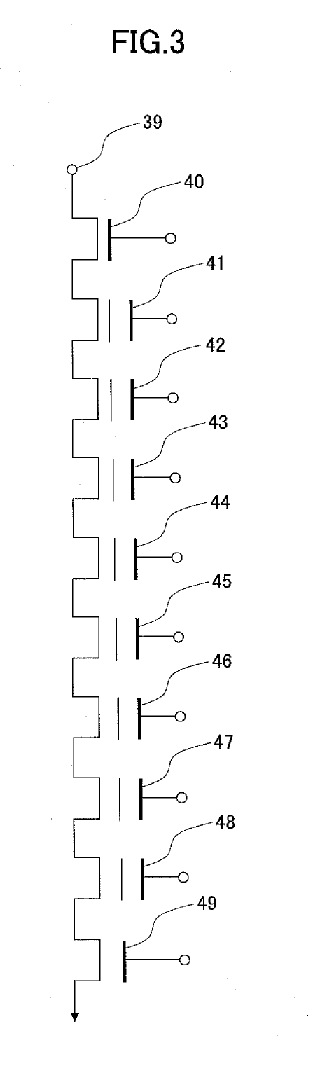

As an example of such an electronic device having an odd number pattern having a different line width adjacent to even number patterns, a NAND-type flash memory may be cited. FIG. 3 shows an equivalent circuit of a NAND-type flash memory. As shown in FIG. 3, the NAND-type flash memory has a circuit such that memory cells of 8 bits are disposed in such a manner that bit lines thereof are connected in series, and field effect transistors (FETs) each having one selection gate for inputting and outputting data are connected in series on both sides of the memory cells. That is, the first selection gate 40, eight floating gates 41 through 48 corresponding to the 8 bits, and the second selection gate 49 are connected in series with a bit line 39. In such a structure of the NAND-type flash memory, in a case where a gate length of the FETs corresponding to the selection gates 40 and 49 of both sides is made longer than a gate length of the memory cells, it is not necessary to newly manufacture masks for the FETs, and thus, it is possible to reduce the manufacturing costs.

Further, in the present embodiment, it is possible to carry out all of the processes of steps S16 through S21 by dry processes. Therefore, it is possible to use a manufacturing method in which the processes are carried out in a lump in such a manner that only the gas type is changed in the same chamber. By carrying out the processes of steps S16 through S21 in a lump, it is possible to simplify the processes and reduce the manufacturing costs in comparison to the prior art, and it is possible to improve the productivity.

It is noted that in the present embodiment, the film forming process of step S14 for the SiO₂ film 14 is carried out by the low-temperature MLD. However, as long as it is possible to form the SiO₂ film 14 without damaging the core parts 15b made of the organic films 13, the upper layer parts of which are protected by the protective films 14, the above-mentioned method should not be limited to, and a well-known film forming method such as CVD, a RF (Radio Frequency) magnetron sputter, or electron beam evaporation may be used.

Further, in the present embodiment, in the core part pattern forming process, trimming of the third pattern 23 made of the second photoresist film 17 need not be carried out, and the first patterns 21 may be formed by using the core parts 15a having a line width approximately equal to the line width L3 of the third pattern 23.

Further, in the present embodiment, a width dimension of L3 that is the line width of the third pattern 23 can be freely controlled as a result of the third pattern 23 being formed previously to have a line width L3′ (for example, 120 nm) that is larger than the line width L3 shown in FIG. 2E, and trimming being carried out. Therefore, the line width L3 may be larger than, equal to or smaller than L12 that is the line width of the patterns of the core parts 15b obtained from trimming.

### First Variant Embodiment of First Embodiment

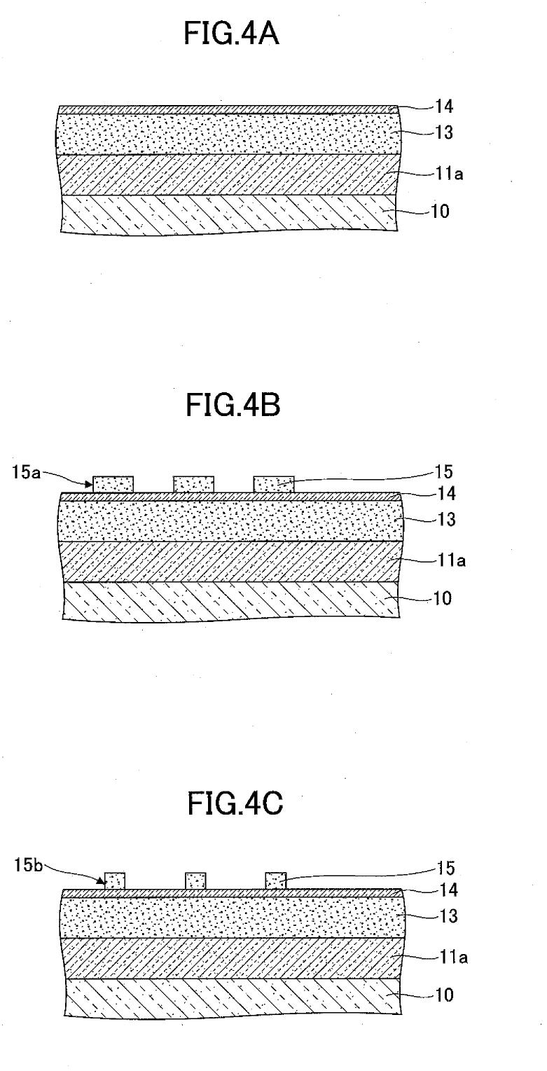

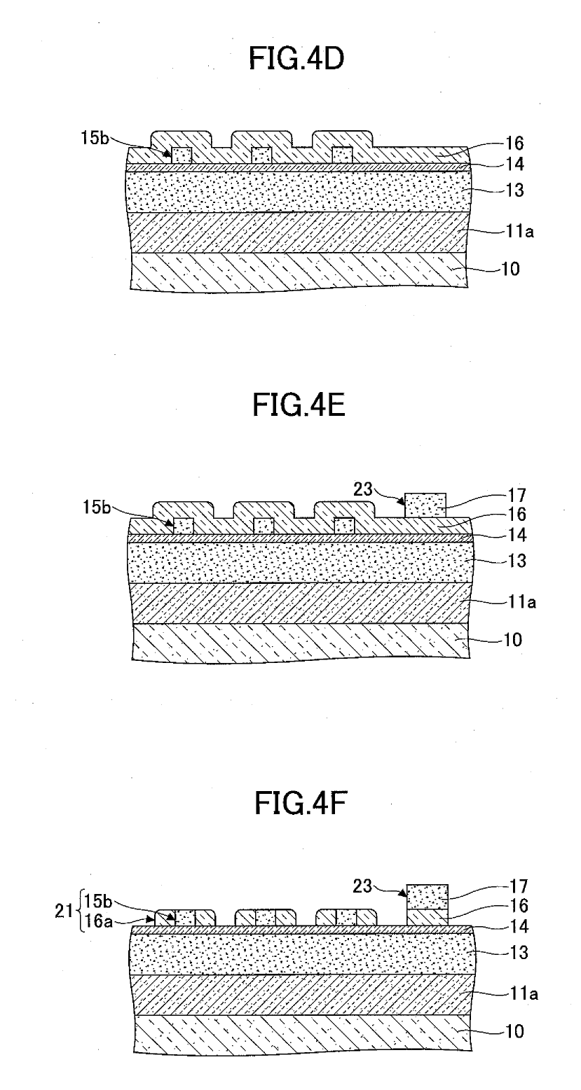

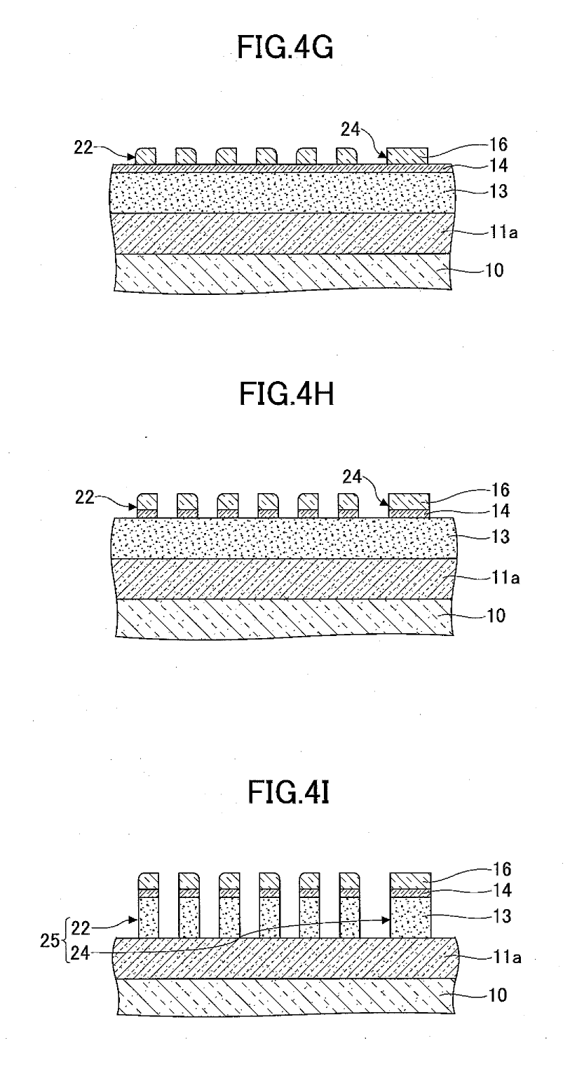

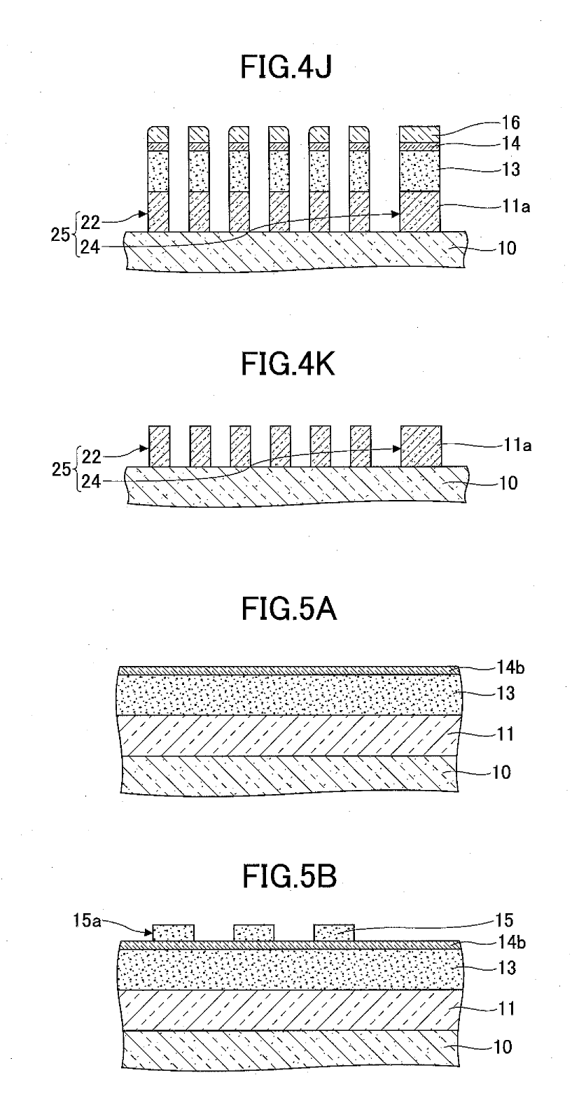

Next, with reference to FIGS. 4A through 4K, a semiconductor device manufacturing method in a first variant embodiment of the first embodiment according to the present invention will be described.

FIGS. 4A through 4K illustrate processes of the semiconductor device manufacturing method in the present variant embodiment, and are sectional views diagrammatically showing structures of the semiconductor device in the respective processes. It is noted that in the description below, the same reference numerals are given to the parts already described above, and description may be omitted (also the same in variant embodiments and embodiments below).

The semiconductor device manufacturing method according to the present variant embodiment is different from the semiconductor device manufacturing method according to the first embodiment in that the to-be-etched layer is a silicon nitride layer.

With reference to FIGS. 4A through 4K, different from the to-be-etched layer 11 made of TEOS being used in the first embodiment, the to-be-etched layer 11a made of a silicon nitride layer (referred to as SiN, hereinafter) is used in the present variant embodiment.

The semiconductor device manufacturing method according to the present variant embodiment includes processes of steps S11 through S21, as shown in FIG. 1, like the first embodiment.

First, a preparing process including step S11 is carried out. As shown in FIG. 4A, also in the present variant embodiment, like the first embodiment, a substrate in which a to-be-etched layer 11a, an organic film 13 and a protective film 14 are formed in the stated order from the bottom on the substrate 10 is used. However, the to-be-etched layer 11a is SiN, different from TEOS in the first embodiment. Like the first embodiment, a thickness of the to-be-etched layer 11a may be, for example, 50 through 500 nm.

Like the first embodiment, the to-be-etched layer 11a functions as a mask in subsequent various processing processes as a result of patterns being formed therein. SiN can improve a selection ratio of etching of SiN and the adjacent organic film 13 in comparison to amorphous silicon or polysilicon used in the first embodiment.

A core part pattern forming process, a film forming process, a third pattern forming process, a first pattern forming process and a second pattern forming process including steps S12 through S17 are like the first embodiment, and parts of structures of the semiconductor device after the respective processes are carried out are shown in FIGS. 4B through 4G, respectively.

Next, a fifth pattern forming process including steps S18 and S19 are carried out.

Step S18, i.e., a process of removing the protective film 14 by using a second pattern 22 and a fourth pattern 24 as masks, is like the first embodiment, and a part of a structure of the semiconductor device when the process of step S18 is finished is shown in FIG. 4H.

Step S19, i.e., a process of etching the organic film 13 by using the second pattern 22 and the fourth pattern 24 as masks, as shown in FIG. 4I, can increase a ratio of an etching rate of the organic film 13 with respect to an etching rate of the to-be-etched layer 11a made of SiN, in comparison to a ratio of an etching rate of the organic film 13 with respect to an etching rate of the to-be-etched layer made of TEOS in the first embodiment. Therefore, etching can be positively stopped at a time when a progress of etching has reached a surface of the to-be-etched layer 11a. Specifically, etching of the organic film 13 is carried out by using, for example, plasma of oxygen, nitrogen, hydrogen, ammonia or such, and, it is possible to improve a selection ratio of etching of SiN and the organic film by controlling a type, a flow rate ratio, a gas pressure of a mixed gas and a substrate temperature. As a result, it is possible to carry out the manufacturing method that is superior in repeatability.

Next, step S20, i.e., a process of removing the to-be-etched layer 11a by using the second pattern 22 and the fourth pattern 24 as masks, and forming a fifth pattern 25, is carried out. FIG. 4J is a sectional view showing a structure of the semiconductor device after the process of step S20 is carried out.

In the present variant embodiment, a selection ratio in etching of the to-be-etched layer 11a made of SiN with respect to the organic film 13 can be improved as a result of the conditions of the etching being controlled, and it is possible to precisely transfer the shapes of the masks to the to-be-etched layer 11a without etching the patterns made of the organic films 13 during the etching of the to-be-etched layer 11a. Specifically, for example, a mixed gas of a gas of a CF family, such as CF₄, C₄Fₛ, CHF₃, CH₃F or CH₂F₂, and an Ar gas or such, or, a gas obtained from adding oxygen to the mixed gas as is necessary, or such, is used for the etching of the first to-be-etched layer 11a, and it is possible to improve the selection ratio of SiN with respect to the organic film by controlling a type of the CF family gas, a type, a flow rate ratio and a gas pressure of the mixed gas, and a substrate temperature. As a result, it is possible to carry out the manufacturing method that is superior in repeatability.

Further, in the present variant embodiment, by controlling the conditions of the etching described above, it is possible to improve a selection ratio in the etching of the to-be-etched layer 11a made of SiN with respect to the substrate 10, and cause the etching to be positively stopped when the etching has reached a surface of the substrate 10.

A process of step S21, i.e., a process of removing the organic films is like the first embodiment. Further, a structure of the semiconductor device after the process of step S21 is finished is shown in FIG. 4K.

Thus, according to the semiconductor device manufacturing method in the present variant embodiment, by changing the to-be-etched layer 11a from TEOS to SiN, it is possible to improve the selection ratio with respect to the adjacent organic film 13, and manufacture the semiconductor device that is superior in repeatability at low costs.

It is noted that a composition ratio of Si and N of SiN is not particularly limited, and, for example, Si₃N₄ may be used. Further, instead of SiN, SiON (silicon oxynitride) may be used.

Further, instead of SiN, a composite film in which amorphous silicon or polysilicon is inserted may be used. Especially, in a case where a large selection ratio in etching rate in the etching process with respect to the substrate can be ensured, it is possible to use the to-be-etched layer of any material.

### Second Variant Embodiment of First Embodiment

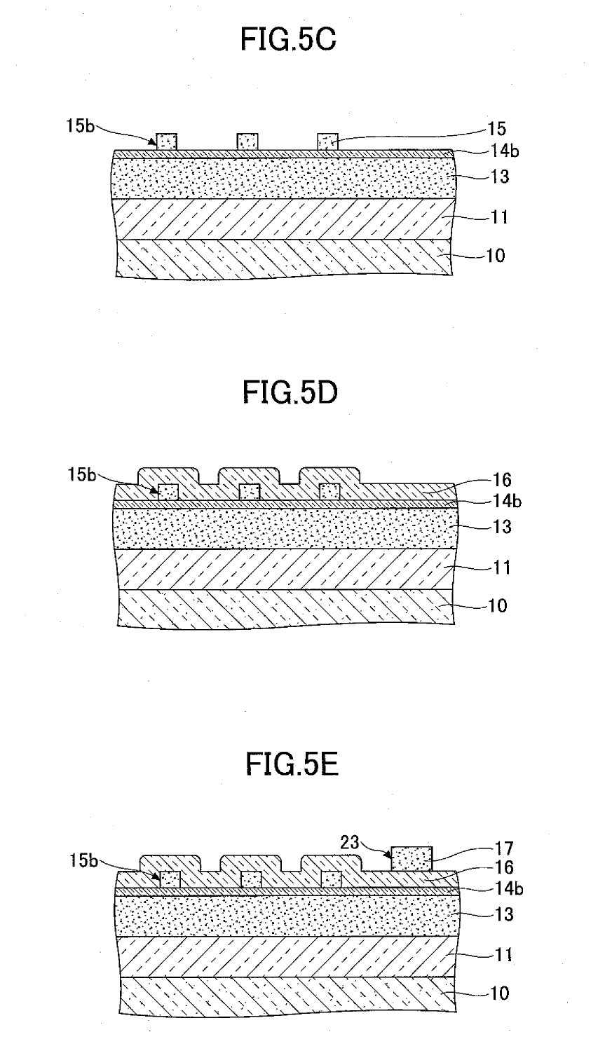

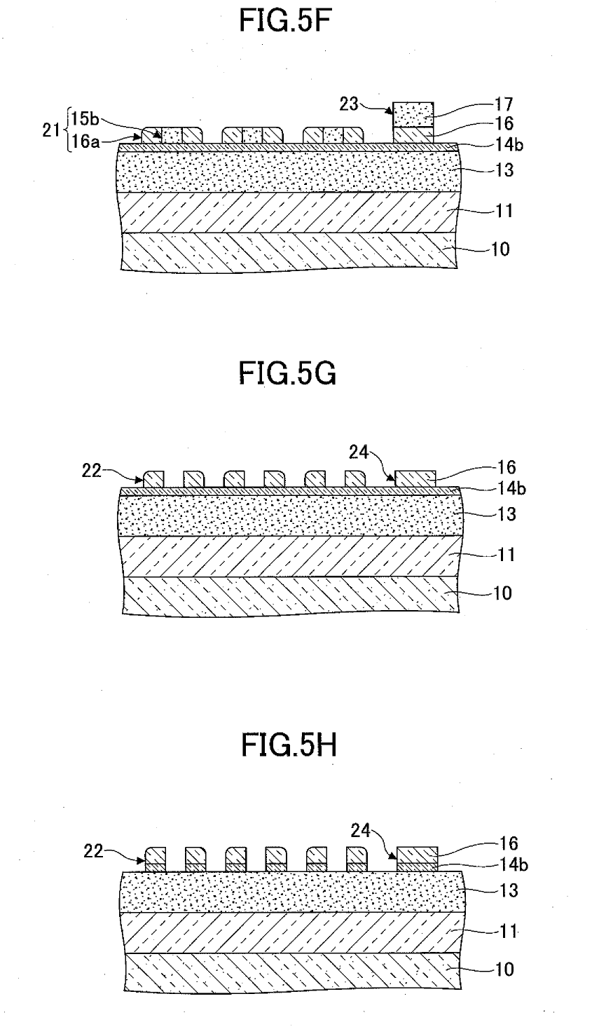

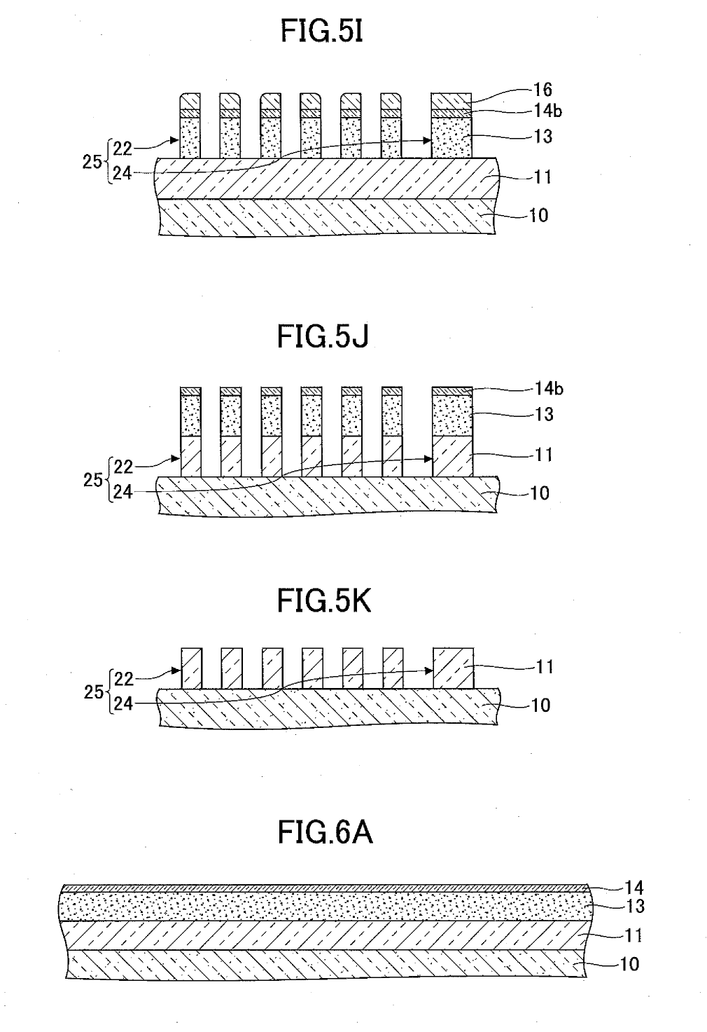

Next, with reference to FIGS. 5A through 5K, a semiconductor device manufacturing method in a second variant embodiment of the first embodiment according to the present invention will be described.

FIGS. 5A through 5K illustrate processes of the semiconductor device manufacturing method in the present variant embodiment, and are sectional views diagrammatically showing structures of the semiconductor device in the respective processes.

The semiconductor device manufacturing method according to the present variant embodiment is different from the semiconductor device manufacturing method according to the first embodiment in that the protective layer is silicon oxynitride SiON.

With reference to FIGS. 5A through 5K, different from the protective film made of SOG used in the first embodiment, the protective film 14b made of SiON is used in the present variant embodiment.

The semiconductor device manufacturing method according to the present variant embodiment includes processes of steps S11 through S22, as shown in FIG. 1, like the first embodiment.

First, a preparing process including step S11 is carried out. As shown in FIG. 5A, also in the present variant embodiment, like the first embodiment, a substrate in which a to-be-etched layer 11, an organic film 13 and a protective film 14b are formed in the stated order from the bottom on the substrate 10 is used. However, the protective film 14b is SiON, different from SOG in the first embodiment. Like the first embodiment, a thickness of the protective film 14b may be, for example, 40 through 120 nm.

Like the first embodiment, the to-be-etched layer 11 functions as a mask in subsequent various processing processes as a result of patterns being formed therein.

A core part pattern forming process, a film forming process, a third pattern forming process and a first pattern forming process including steps S12 through S15 are like the first embodiment, and parts of structures of the semiconductor device after the respective processes are finished are shown in FIGS. 5B through 5E, respectively.

Next, a first pattern forming process including step S16 is carried out. A partial structure of the semiconductor device after the first pattern forming process is carried out is shown in FIG. 5F.

In the present variant embodiment, a selection ratio of an etching rate of the SiO₂ film 16 and an etching rate of the protective film 14b made of SiON can be improved as a result of the conditions of the etching being controlled, and it is possible to cause the etching to be positively stopped when the etching has reached a surface of the protective film 14b. Specifically, for example, a mixed gas of a gas of a CF family, such as CF₄, C₄F₈, CHF₃, CH₃F or CH₂F₂, and an Ar gas or such, or, a gas obtained from adding oxygen to the mixed gas as is necessary, or such, is used for the etching of the SiO₂ film 16, and it is possible to improve the selection ratio of etching between the SiO₂ film and SiON by controlling types, flow rates and gas pressures of the gases, and a substrate temperature. As a result, it is possible to carry out the manufacturing method that is superior in repeatability.

A second pattern forming process and a fifth pattern forming process including steps S17 through S19 are like the first embodiment. Partial structures of the semiconductor device after the respective processes are finished are shown in FIGS. 5G through 51.

Next, a to-be-etched layer etching process including steps S20 and S21 is carried out. Partial structures of the semiconductor device after steps S20 and S21 of the to-be-etched layer etching process are carried out are shown in FIGS. 5J through 5K.

In the present variant embodiment, a selection ratio of an etching rate of the to-be-etched layer 11 made of TEOS and an etching rate of the protective film 14b made of SiON can be improved as a result of the conditions of the etching being controlled, and it is possible to precisely transfer shapes of the masks to the to-be-etched layer 11 without etching the second patterns 22 and the fourth pattern 24 made of the protective films 14b during the etching of the to-be-etched layer 11. Specifically, for example, a mixed gas of a gas of a CF family, such as CF₄, C₄F₈, CHF₃, CH₃F or CH₂F₂, and an Ar gas or such, or, a gas obtained from adding oxygen to the mixed gas as is necessary, or such, is used for the etching of the to-be-etched layer 11, and it is possible to improve the selection ratio of etching between TEOS and SiON by controlling types, flow rates and gas pressures of the gases, and a substrate temperature. As a result, it is possible to carry out the manufacturing method that is superior in repeatability.

A process of step S21 is like the first embodiment, and a structure of the semiconductor device after the process is finished is shown in FIG. 5K.

Thus, according to the semiconductor device manufacturing method in the present variant embodiment, by changing the protective film 14b from SOG to SiON, it is possible to improve the selection ratio in the etching of the SiO₂ layer 16 and the to-be-etched layer 11, and manufacture the semiconductor device that is superior in repeatability at low costs.

It is noted that, also in the case where a composite film of a LTO film and a BARC film is used instead of SiON, it is possible to improve a selection ratio of the SiO₂ film 16 and the to-be-etched layer 11, and manufacture the semiconductor device that is superior in repeatability at low costs.

### Third Variant Embodiment of First Embodiment

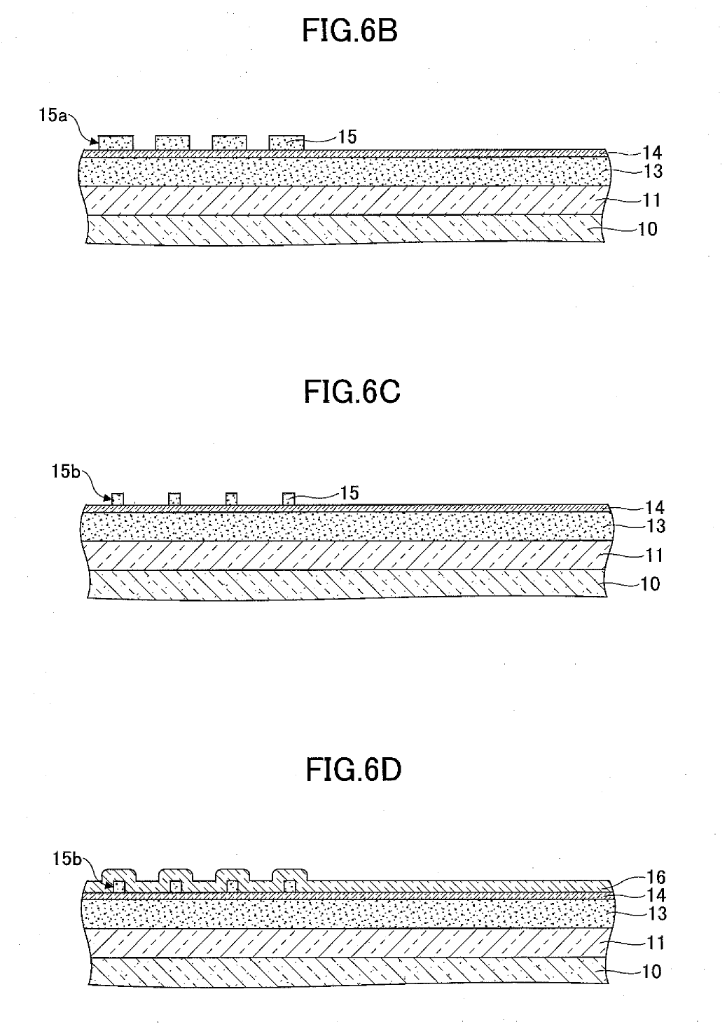

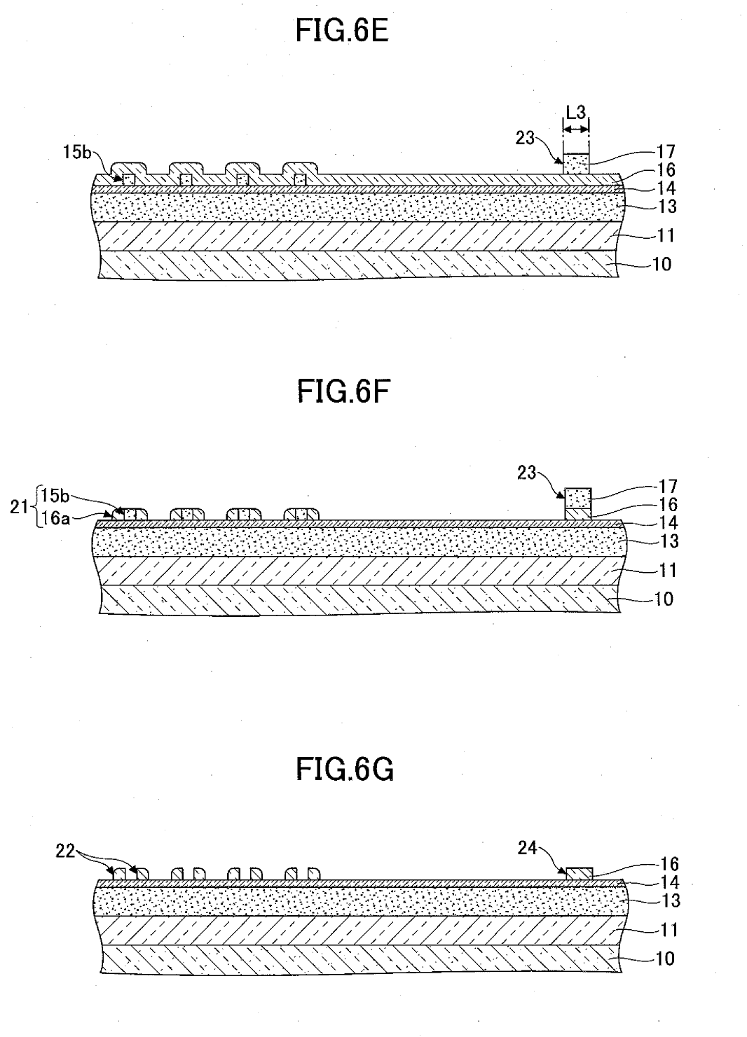

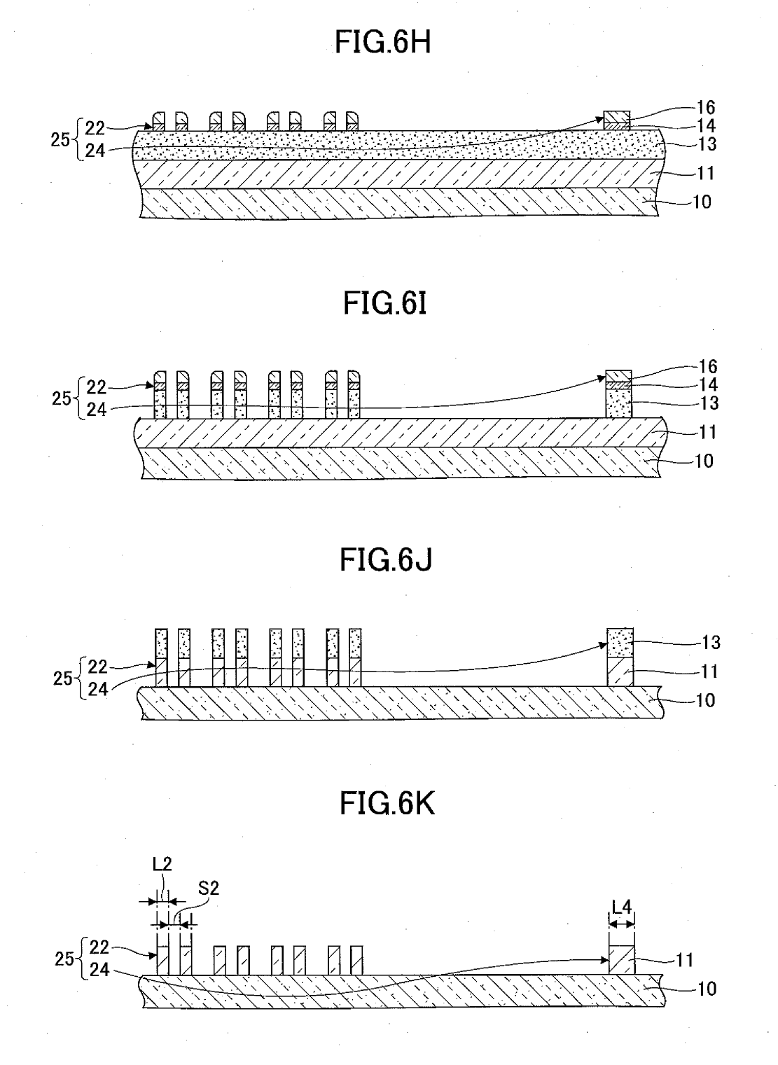

Next, with reference to FIGS. 6A through 6K, a semiconductor device manufacturing method according to a third variant embodiment of the first embodiment of the present invention will be described.

FIGS. 6A through 6K illustrate processes of the semiconductor device manufacturing method according to the present variant embodiment, and are sectional views diagrammatically showing structures of a semiconductor device in respective processes.

The semiconductor device manufacturing method according to the present variant embodiment is different from the semiconductor device manufacturing method according to the first embodiment in that an isolated pattern is formed simultaneously at a position away from even number patterns.

With reference to FIGS. 6A through 6K, different from the first embodiment in which the odd number pattern is simultaneously formed adjacent to the even number patterns, the isolated pattern is formed at a position away from the even number patterns in the present variant embodiment.

The semiconductor device manufacturing method according to the present variant embodiment includes steps S11 through S21 as shown in FIG. 1, like the first embodiment.

First, a preparing process including step S11 is carried out. As shown in FIG. 6A, also in the present variant embodiment, like the first embodiment, a substrate is used in which, on the substrate 10, a to-be-etched layer 11, an organic film 13 and a protective film 14 are formed in the stated order from the bottom.

Next, a core part pattern forming process including steps S12 and S13 is carried out.

Step S12 is a core part forming process of exposing and developing a first photoresist film 15 and forming patterns of core parts 15a made of the first photoresist films 15. In the present variant embodiment, the first photoresist film 15 is formed on the protective film 14, photolithography is carried out by using a metal mask having a place in which even number patterns for the patterns of the core parts 15a are disposed and a place in which none of patterns for the core parts 15a is disposed, exposing and developing are carried out, and patterns of the core parts 15a are formed. A structure of the semiconductor device after the process of step S12 is carried out is shown in FIG. 6B.

Step S13 to be carried out next is like the first embodiment, and a structure of the semiconductor device after the process of step S13 is carried out is shown in FIG. 6C.

A film forming process including step S14 is like the first embodiment, and a structure of the semiconductor device after the process of step S14 is carried out is shown in FIG. 6D.

Next, a third pattern forming process of step S15 is carried out. As shown in FIG. 6E, at a place at which none of the patterns of the core parts 15b is formed, a third pattern 23 is formed. A second photoresist film 17 for forming the third pattern 23 is formed throughout the surface of the substrate, exposing and developing are carried out, and the third pattern 23 made of the second photoresist film 17 is formed. It is noted that material and a thickness of the second photoresist film 17 may be the same as the first embodiment. However, a metal mask used when the second photoresist film 17 is exposed in the present variant embodiment is different from the first embodiment, and, has such a pattern that the third pattern 23 corresponding to the isolated pattern is disposed at a position away from the patterns of the core parts 15b. Assuming that a line width of the third pattern 23 is L3, a value of L3 is not particularly limited, and may be, for example, 60 nm, like the first embodiment.

It is noted that, since the third pattern 23 has the fine line width L3, a highly accurate metal mask, like the metal mask for forming the patterns of the core parts 15a, is required, and mask manufacturing costs are required. However, it is possible to carry out etching in a lump by using the organic film 13 as a mask used for the etching of the to-be-etched layer 11, it is possible to select material from a wide variety of materials as the to-be-etched layer 11, and, by using the material of low costs and a film forming method of low costs, it is possible to reduce the total manufacturing costs, like the first embodiment.

After that, a first pattern forming process, a second pattern forming process, a fifth pattern forming process and a to-be-etched layer etching process, including steps S16 through S21, are like the first embodiment. Partial structures of the semiconductor device after the respective processes are finished are shown in FIGS. 6F through 6K. As a result, it is possible to form, in a lump, the patterns having the isolated pattern made of the to-be-etched layer 11 and having the line width L4 at the position away from the even number patterns having the line width L2 and the space width S2.

### Fourth Variant Embodiment of First Embodiment

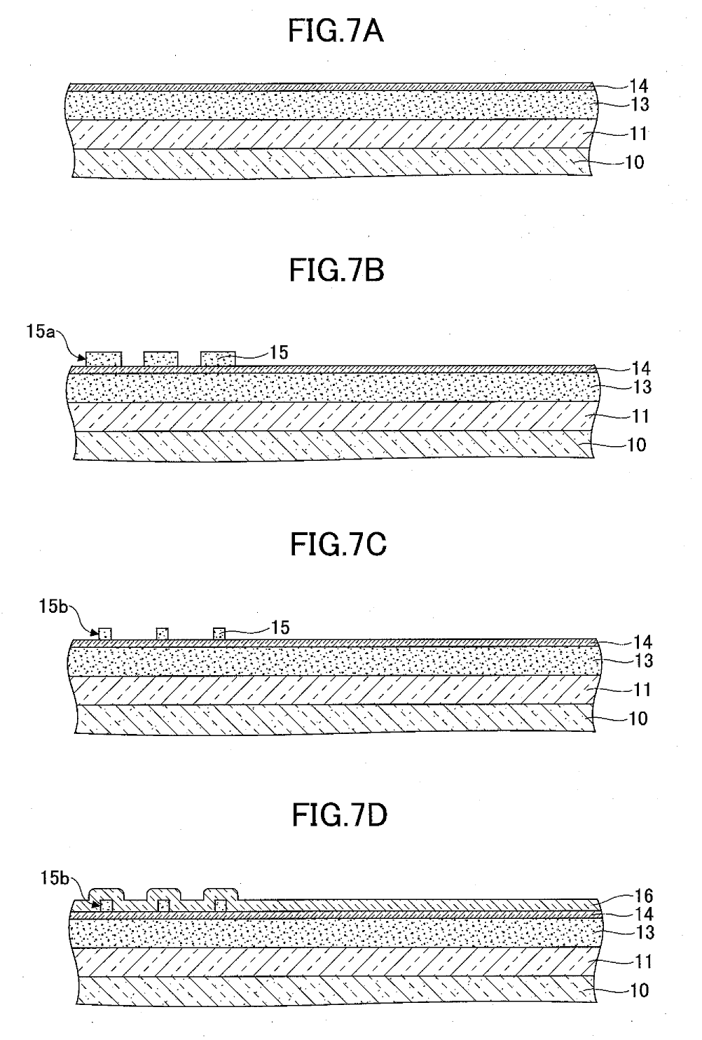

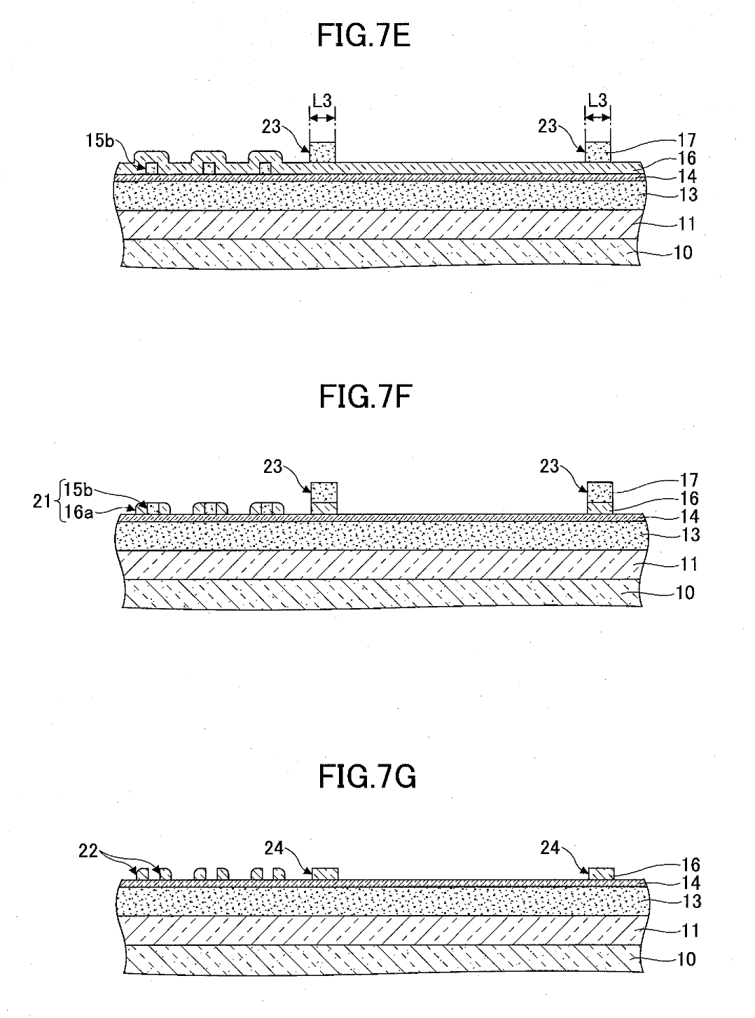

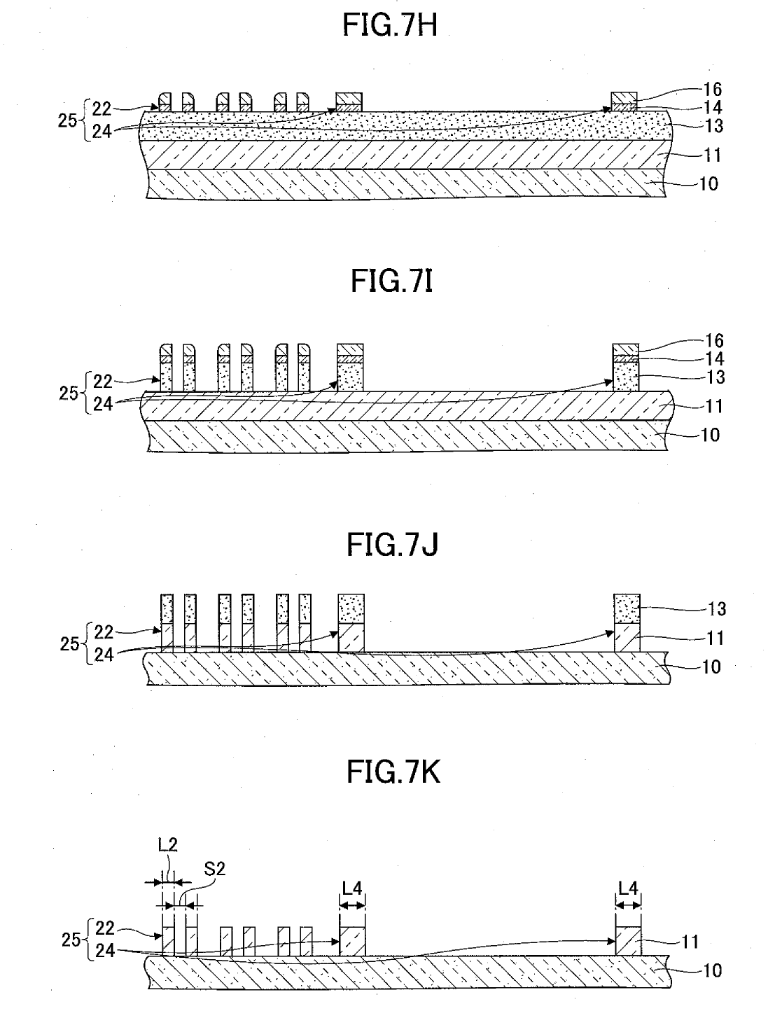

Next, with reference to FIGS. 7A through 7K, a semiconductor device manufacturing method according to a fourth variant embodiment of the first embodiment of the present invention will be described.

FIGS. 7A through 7K illustrate processes of the semiconductor device manufacturing method according to the present variant embodiment, and are sectional views diagrammatically showing structures of a semiconductor device in the respective processes.

The semiconductor device manufacturing method according to the present variant embodiment is different from the semiconductor device manufacturing method according to the first embodiment in that an odd number pattern is formed at a position adjacent to even number patterns simultaneously, and also, an isolated pattern is formed also at a position away from the even number patterns simultaneously.

With reference to FIGS. 7A through 7K, different from the odd number pattern being formed adjacent to the even number patterns simultaneously in the first embodiment, the odd number pattern is formed adjacent to the even number patterns simultaneously, and also, the isolated pattern is formed at the position away from the even number patterns, in the present variant embodiment.

The semiconductor device manufacturing method according to the present variant embodiment includes steps S11 through S21 as shown in FIG. 1, like the first embodiment.

First, a preparing process including step S11 is carried out. As shown in FIG. 7A, also in the present variant embodiment, a substrate is used in which, on the substrate 10, a to-be-etched layer 11, an organic film 13 and a protective film 14 are formed in the stated order from the bottom, like the first embodiment.

Next, a core part pattern forming process and a film forming process including steps S12 through S14 are carried out. The core part pattern forming process and the film forming process are like the first embodiment. Structures of the semiconductor device after the respective processes are carried out are shown in FIGS. 7B through 7D.

Next, a third pattern forming process including step S15 is carried out. As shown in FIG. 7E, a third pattern 23 is formed at a position at which none of the core part patterns 15b are formed, like the first embodiment. However, the present variant embodiment is characterized by having such a pattern that a third pattern 23 corresponding to the odd number pattern and having a line width L3 is provided adjacent to patterns of the core parts 15b, and also, a third pattern 23 corresponding to the isolated pattern and having the line width L3 is also provided at a position away from the patterns of the core parts 15b. A value of L3 is not particularly limited, and may be, for example, 60 nm, like the first embodiment.

After that, a first pattern forming process, a second pattern forming process, a fifth pattern forming process and a to-be-etched layer etching process, including steps S16 through S21, are like the first embodiment. Partial structures of the semiconductor device when the respective processes are finished are shown in FIGS. 7F through 7K. As a result, it is possible to form, in a lump, the odd number pattern having a line width L4 at a position adjacent to the even number patterns having a line width L2 and a space width S2 and made of the to-be-etched layers 11, and also, form, in a lump, the isolated pattern having the line width L4 at a position away from the even number patterns having the line width L2 and the space width S2.

### Fifth Variant Embodiment of First Embodiment

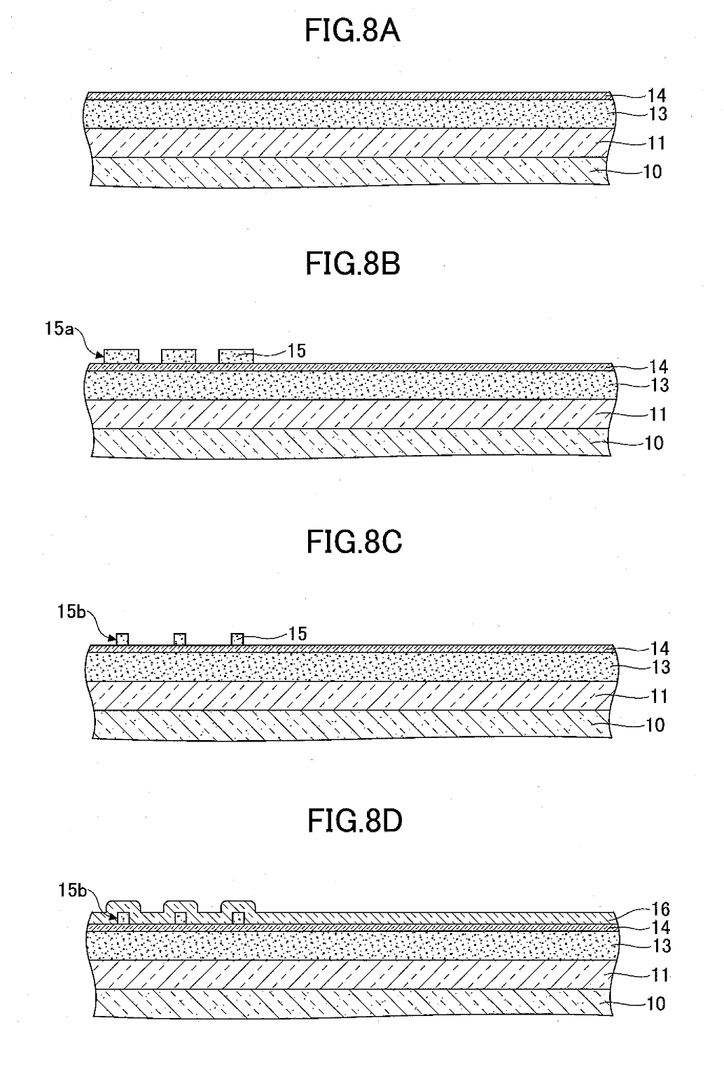

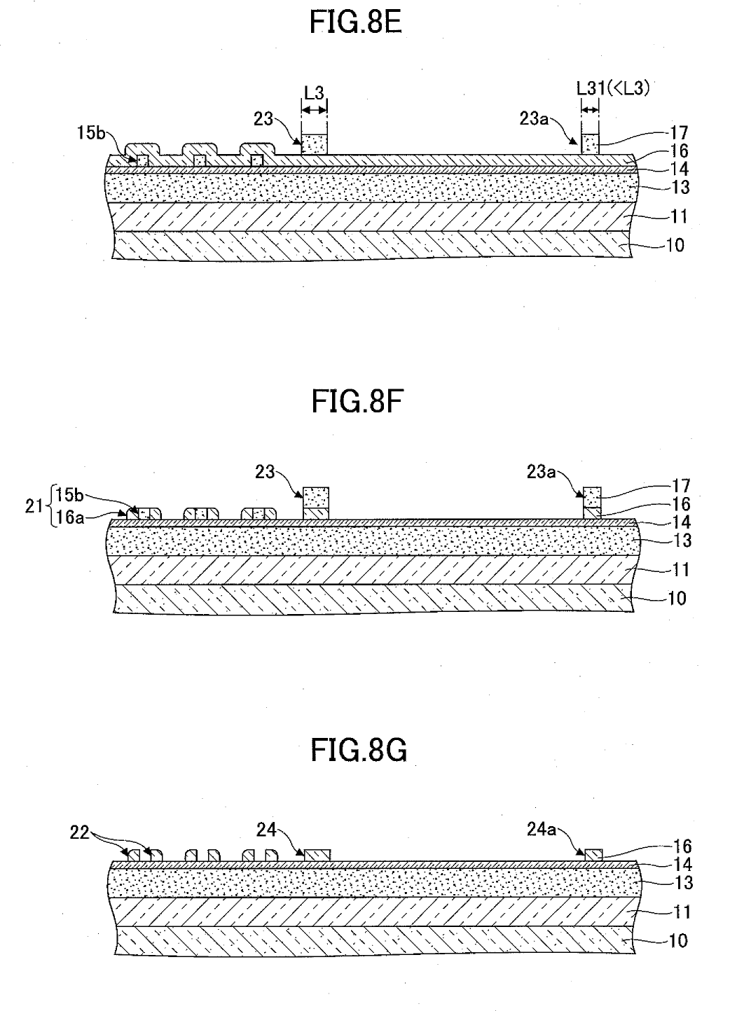

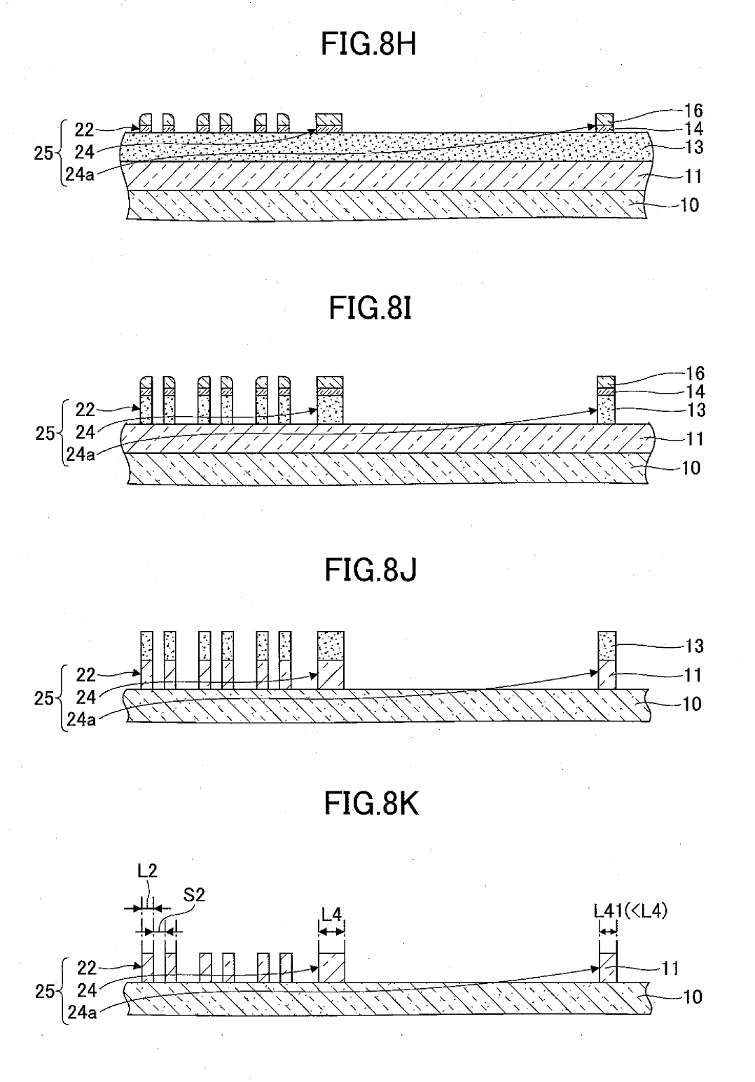

Next, with reference to FIGS. 8A through 8K, a semiconductor device manufacturing method according to a fifth variant embodiment of the first embodiment of the present invention will be described.

It is noted that, a line width L31 in the present variant embodiment corresponds to a third dimension of the present invention.

FIGS. 8A through 8K illustrate the semiconductor device manufacturing method according to the present variant embodiment, and are sectional views diagrammatically showing structures of a semiconductor device in the respective processes.

The semiconductor device manufacturing method according to the present variant embodiment is different from the semiconductor device manufacturing method according to the fourth variant embodiment of the first embodiment in that, when first patterns including core parts and side wall parts are formed, a line width of a third pattern of third patterns, coated with a second photoresist film after that, disposed at a position away from even number patterns including second patterns is thinner than a line width of a third pattern of the third patterns disposed at a position adjacent to the even number patterns including the second patterns.

With reference to FIGS. 8A through 8K, different from the line width of the isolated pattern at the position away from the second patterns being the same as the line width of the odd number pattern at the position adjacent to the second patterns in the fourth variant embodiment of the first embodiment, the line width L31 of the isolated pattern 23a at the position away from the second patterns 22 is thinner than the line width L3 of the odd number pattern 23 at the position adjacent to the second patterns 22 in the present variant embodiment.

The semiconductor device manufacturing method according to the present variant embodiment includes steps S11 through S21 as shown in FIG. 1, like the fourth variant embodiment of the first embodiment.

First, a preparing process including step S11 is carried out. As shown in FIG. 8A, a substrate is used in which, on the substrate 10, a to-be-etched layer 11, an organic layer 13 and a protective layer 14 are formed in the stated order from the bottom, like the first embodiment, also in the present variant embodiment.

Next, a core part pattern forming process and a film forming process including steps S12 through S14 are carried out. The core part pattern forming process and the film forming process are like the first embodiment. Structures of the semiconductor device after the respective processes are carried out are shown in FIGS. 8B through 8D.

Next, a third pattern forming process including step S15 is carried out. As shown in FIG. 8E, the third pattern 23 is formed at the position at which none of the core part patterns 15b are formed, like the first embodiment. However, the present variant embodiment is characterized by having such a pattern that the third pattern 23 corresponding to the odd number pattern and having the line width L3 is provided adjacent to the patterns of the core parts 15b, also, the third pattern 23a corresponding to the isolated pattern and having the line width L31 is also provided at the position away from the patterns of the core parts 15b, and L31 is smaller than L3. Values of L3 and L31, the line widths of the third pattern 23 and the third pattern 23a, respectively, are not particularly limited, and the value of L3 may be, for example, 60 nm, like the first embodiment, and the value of L31 may be, for example, 40 nm.

After that, a first pattern forming process, a second pattern forting process, a fifth pattern forming process and a to-be-etched layer etching process, including steps S16 through S21, are like the first embodiment. Partial structures of the semiconductor device when the respective processes are finished are shown in FIGS. 8F through 8K. As a result, it is possible to form, in a lump, the pattern, made of the to-be-etched layer 11, having the odd number pattern having a line width L4 at the position adjacent to the even number patterns having a line width L2 and a space width S2, and also, the isolated pattern having the line width L41 at the position away from the even number patterns having the line width L2 and the space width S2. It is noted that because a value of L4 is equal to L3, the value of L4 may be, for example, 60 nm, and because a value of L41 is equal to L31, the value of L41 may be, for example, 40 nm.

### Second Embodiment

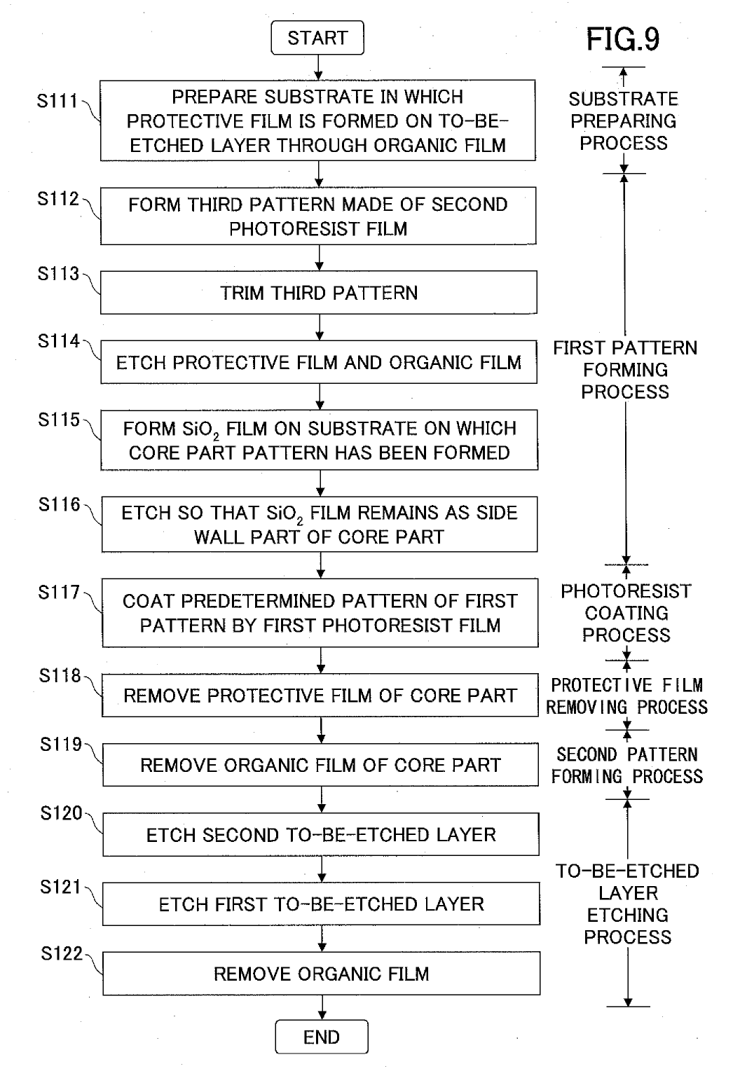

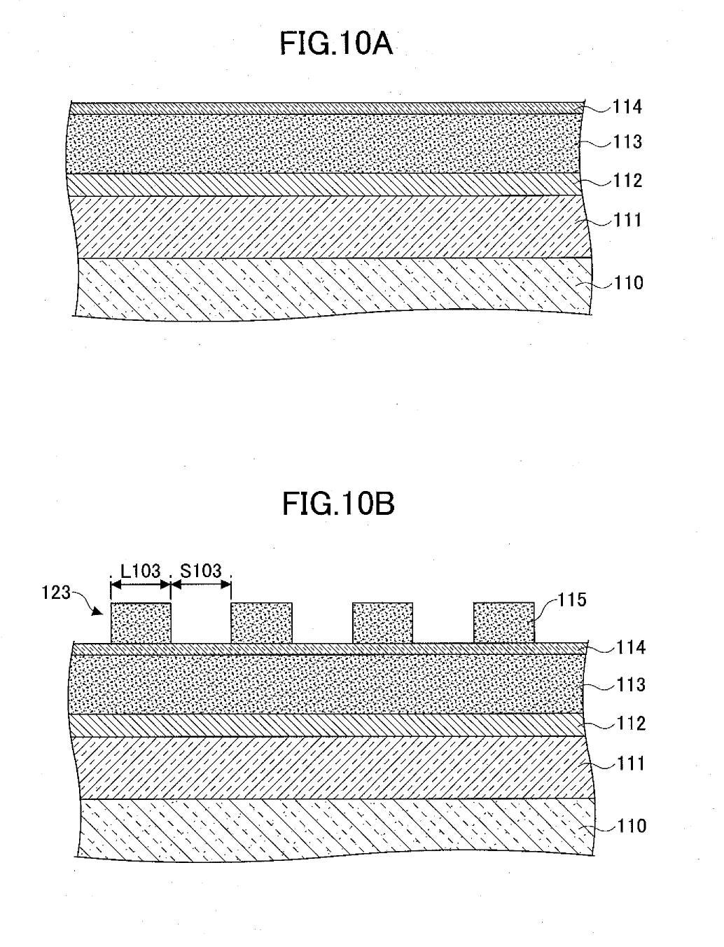

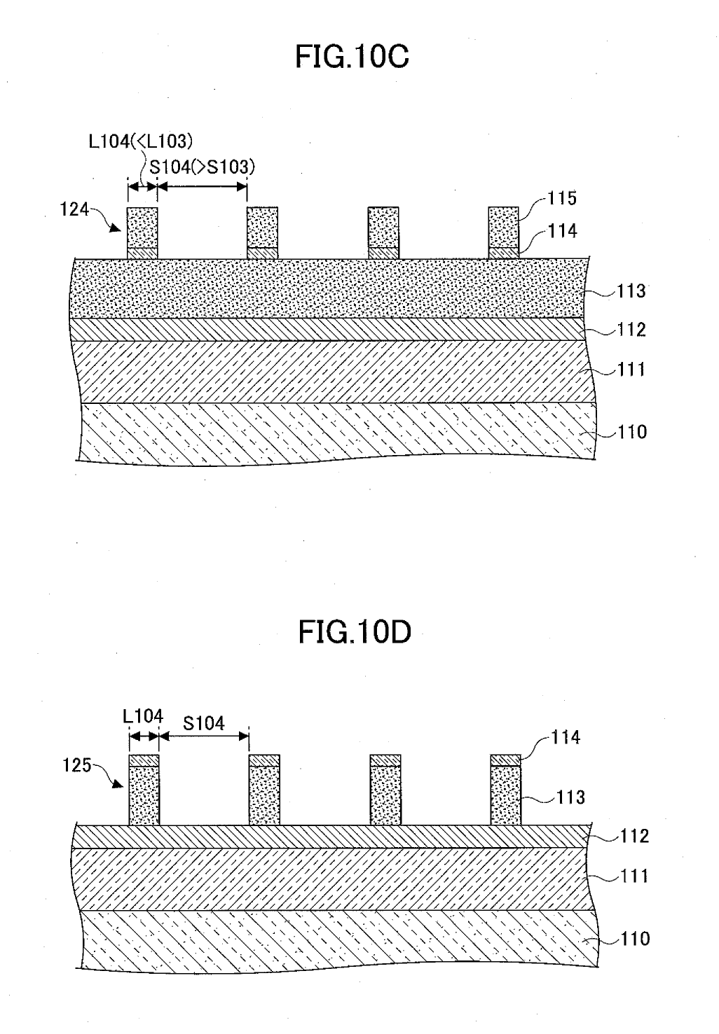

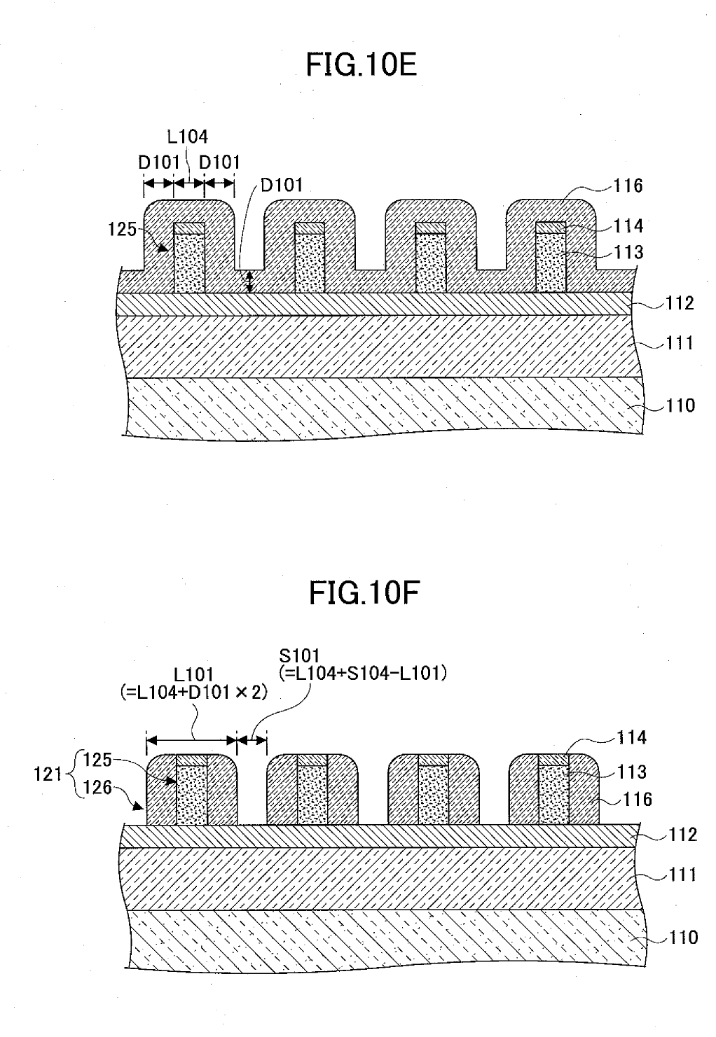

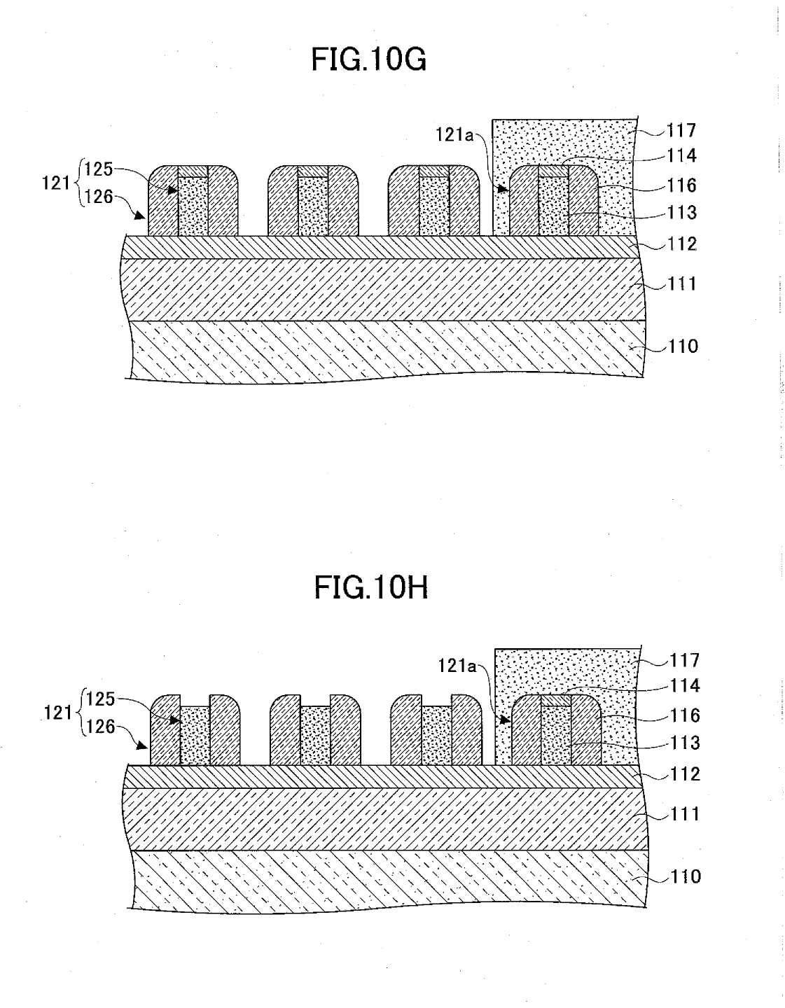

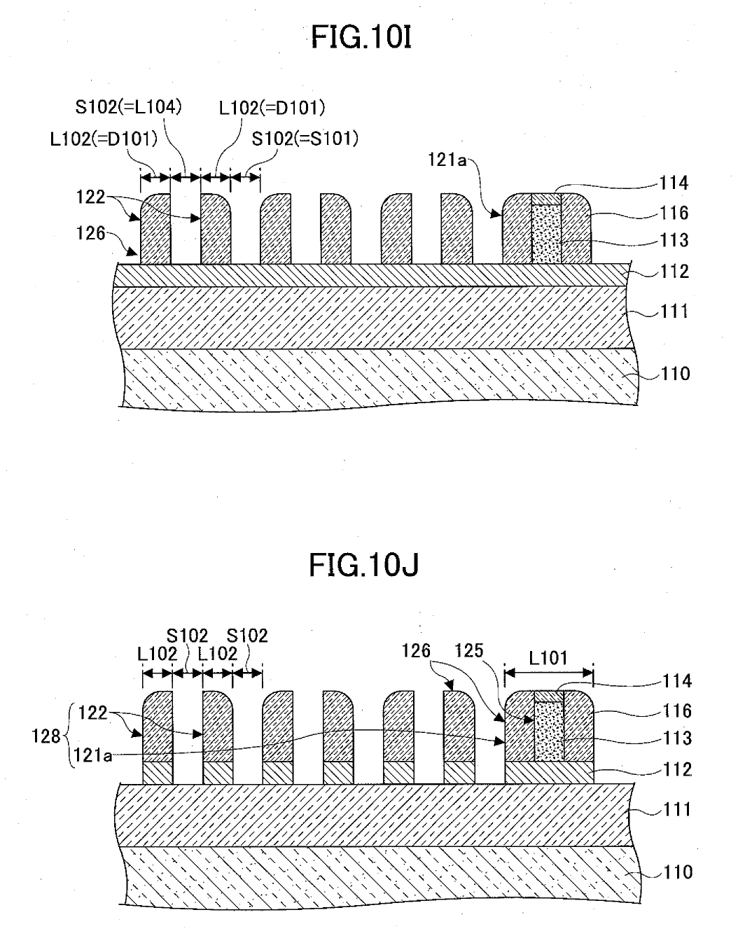

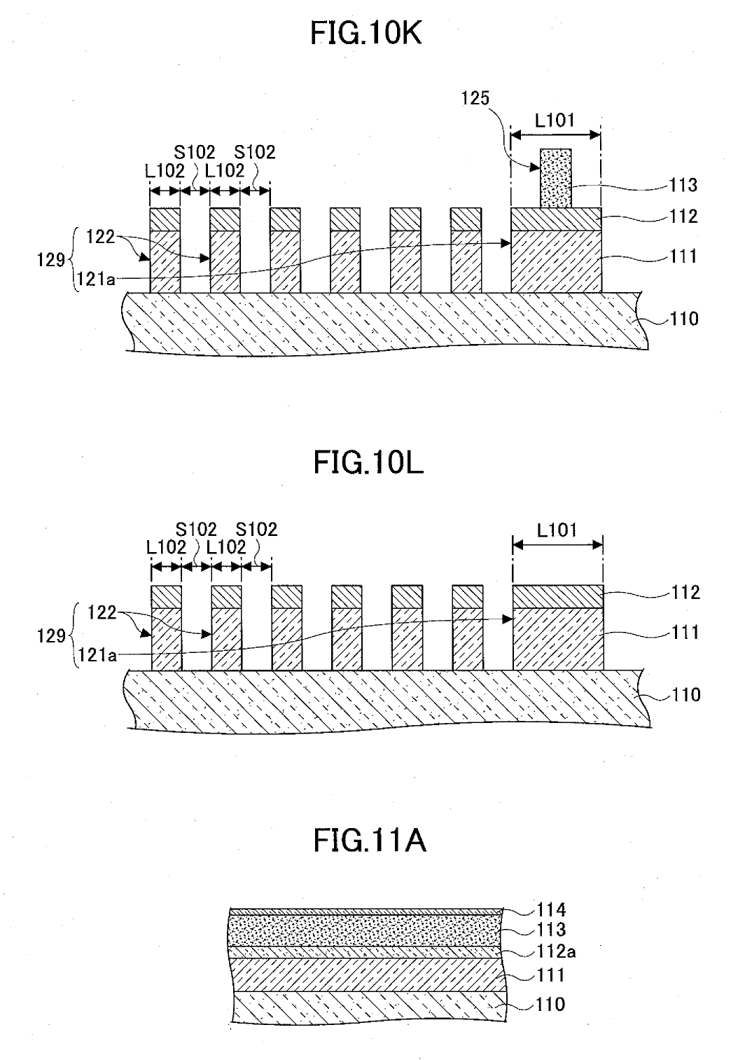

With reference to FIGS. 9 through 10L, a semiconductor device manufacturing method according to a second embodiment of the present invention will be described.

Below, an organic film, a core part pattern, a core part pattern forming process, a film forming process, a first pattern, a first pattern forming process, a second photoresist film, a third pattern, a third pattern forming process, a predetermined pattern of the first pattern, a first pattern forming process, a second pattern, a second pattern forming process, in the present embodiment and respective variant embodiments of the present embodiment correspond to a first organic film, a first organic film pattern, a first organic film pattern forming process, a silicon oxide film forming process, a first mask pattern, a first mask pattern forming process, a second organic film, a second organic film pattern, a second organic film pattern forming process, a second mask pattern, a second mask pattern forming process, a third mask pattern, and a third mask pattern forming process according to the present invention, respectively.

Further, a line width L104 and a thickness D101 of the present embodiment and the respective variant embodiments of the present embodiment correspond to a first dimension and a second dimension according to the present invention, respectively.

FIG. 9 is a process diagram for illustrating respective processes of the semiconductor device manufacturing method according to the present embodiment. Further, FIGS. 10A through 10L are figures for illustrating processes of the semiconductor device manufacturing method according to the present embodiment, and sectional views diagrammatically showing structures of a semiconductor device in the respective processes. Further, the structures of the semiconductor device after the respective processes of steps S111 through S122 of FIG. 9 are carried out correspond to the structures shown in the respective sectional views of FIGS. 10A through 10L.

The semiconductor device manufacturing method according to the present embodiment includes, as shown in FIG. 9, a substrate preparing process, a first pattern forming process, a photoresist coating process, a protective film removing process, a second pattern farming process and a to-be-etched layer etching process. The substrate preparing process includes a process of step S111, the first pattern forming process includes processes of steps S112 through S116, the photoresist coating process includes a process of step 117, the protective film removing process includes a process of step S118, the second pattern forming process includes a process of step S119, and the to-be-etched layer etching process includes processes of steps S120 through S122.

First, the preparing process including step S111 is carried out. Step S111 is a process of preparing a substrate in which on to-be-etched layers, a protective film is formed through an organic film. FIG. 10A is a sectional view showing a structure of a semiconductor device after the process of step S111 is carried out.

In step S111, as shown in FIG. 10A, the substrate is prepared in which on the substrate 10, a first to-be-etched layer 111, a second to-be-etched layer 112, the organic film 113 and the protective film 114 are formed in the stated order from the bottom. The first to-be-etched layer 111 and the second to-be-etched layer 112 function as a mask to be used for carrying out subsequent various processing processes as a result of patterns being formed. Patterns are formed in the organic film 113 and the organic film 113 functions as a mask for forming patterns in the first to-be-etched layer 111 and the second to-be-etched layer 112. As will be described later with reference to FIG. 10D, the protective film 114 has a function to protect a surface of the organic films 113 when patterns of core parts 125 made of the organic films 113 are formed, and also, as will be described later with reference to FIG. 10G, protect the organic films 113 to prevent the organic film 113 of the core part 125 from being removed in a predetermined pattern of first patterns 121. Further, there is a case where the protective film 114 has a function as a reflection preventing film (BARC: Bottom Anti-Reflecting Coating) when photolithography of the second photoresist film 115 formed on the protective layer 114 is carried out.

A material of the first to-be-etched layer 111 is not particularly limited, and, for example, TEOS (Tetraethoxysilane) may be used. Further, a thickness of the first to-be-etched layer 111 is not particularly limited, and, for example, may be 50 through 500 nm.

A material of the second to-be-etched layer 112 is not particularly limited, and, for example, amorphous silicon or polysilicon may be used. Further, a thickness of the second to-be-etched layer 112 is not particularly limited, and, for example, may be 20 through 200 nm.

A material of the organic film 113 is not particularly limited, and, for example, a broad range of organic materials may be used, which include amorphous carbon formed by a chemical vapor deposition (CVD) method, polyphenol, a film of which is formed by spin on, and photoresist such as i-ray resist. Further, a thickness of the organic film 113 is not particularly limited, and, for example, may be 150 through 300 nm.

A material of the protective film 114 is not particularly limited, and, for example, a SOG (Spin On Glass) film, a SiON film, or a composite film of a LTO (Low Temperature Oxide) film and BARC, may be used. Further, a thickness of the protective film 114 is not particularly limited, and, for example, may be 40 through 120 nm.

Next, the first pattern forming process including steps S112 through S116 is carried out.

Step S112 is a third pattern forming process of forming a second photoresist film 115, exposing and developing the formed second photoresist film 115, and forming third patterns 123 made of the second photoresist films 115. As a result, as shown in FIG. 10B, the third patterns 123 made of the second photoresist films 115 are formed. The third patterns 123 function as a mask in a process of etching the protective film 114 and the organic film 115.

As a material of the second photoresist film 115, ArF resist may be used for example. Further, a thickness of the second photoresist film 115 is not particularly limited, and, for example, may be 50 through 200 nm. A line width L103 and a space width S103 of the third patterns 123 are not particularly limited, and, for example, both may be 60 nm.

Step S113 is a process of trimming the second photoresist films 115 that form the third patterns 123, and etching the protective film 114 by using fourth patterns made of the second photoresist films 115 obtained from the trimming. Further, FIG. 10C is a sectional view showing a structure of the semiconductor device after the process of step S113 is carried out.

A method of the trimming is not particularly limited, and, for example, plasma of oxygen, nitrogen, hydrogen, ammonia or such is used. Further, as shown in FIGS. 10B and 10C, the line width L104 of the fourth patterns 124 obtained from the trimming becomes thinner than the line width L103 of the third patterns 123 before the trimming. Therefore, size relations between the line width L104 and the space width S104 of the fourth patterns 124 and the line width L103 and the space width S103 of the third patterns 123 are, L104<L103, S104>S103. Values of L104 and S104 are not particularly limited, and, for example, L104 may be 30 nm, and S104 may be 90 nm.

After the trimming, the protective film 114 is etched with the use of the patterns 124 made of the second photoresist films 115 having the line width of L104 as masks, and patterns are formed having the line width of L104 in which the second photoresist films 115 and the protective films 114 are laminated. The etching of the protective film 114 may employ, for example, a mixed gas of a gas of a CF family, such as CF₄, C₄F₈, CHF₃, CH₃F or CH₂F₂, and an Ar gas or such, or, a gas obtained from adding oxygen, as is necessary, to the mixed gas, or such, may be used in a case where the protective film 114 is, for example, a SOG film (or a SiON film, or a composite film of a LTO film and BARC).

Step S114 is a core part pattern forming process of forming patterns of core parts 125 made of the organic films 113, upper layers of which are protected by the protective films 114, by etching the organic film 113, an upper layer of which is protected by the protective films 114. FIG. 10D is a sectional view showing a structure of the semiconductor device after the process of step S114 is carried out.

The etching of the organic film 113 is not particularly limited, and, for example, may be carried out by using plasma of oxygen, nitrogen, hydrogen, ammonia or such. As a result, as shown in FIG. 10D, the organic film 113 is etched by the use of the protective films 114 having the line width of L104 as masks, and the patterns of the core parts 25 made of the organic films 113 protected by the protective films 114 and having the line width of L104 are formed.

Step S115 is a film forming process of forming a SiO₂ film 116 on the substrate on which the patterns of the core parts 125 have been formed. Further, FIG. 10E is a sectional view showing a structure of the semiconductor device after step S115 is carried out.

It is noted that the SiO₂ film corresponds to a silicon oxide film according to the present invention. Further, hereinafter, instead of the SiO₂ film, a film of another composition that predominantly contains silicon and oxygen, such as a SiOₓ film, may be used.

The film forming process of SiO₂ is carried out in a condition in which the organic films 113 remain as the core parts 125. Since the organic films 113 are weak against a high temperature generally speaking, the film forming process may be carried out preferably at a low temperature (for example, on the order of equal to or less than 300° C.). A film forming method is not particularly limited as long as film forming can be carried out at a low temperature as mentioned above, and, in the present embodiment, the film forming may be carried out by molecular layer deposition (hereafter referred to as MLD) at a low temperature, i.e., low-temperature MLD. As a result, as shown in FIG. 10E, the SiO₂ film 116 is formed throughout the surface of the substrate including places at which the core parts 125 are formed and places at which the core parts 125 are not formed, and further, the SiO₂ films 116 are formed also on side faces of the core parts 125 to coat the side faces of the core parts 125. Assuming that a thickness of the SiO₂ film 116 is D101, a width of the SiO₂ films 116 coating the side faces of the core parts 125 is also D101. The thickness D101 of the SiO₂ film 116 is not particularly limited, and, for example, may be 30 nm.

Here, the film forming process according to the low-temperature MLD will be described.

In the low-temperature MLD, a process of supplying a source gas including silicon to a processing chamber and adsorption of the silicon raw material on a substrate and a process of supplying a gas containing oxygen to the processing chamber and oxidizing the silicon raw material are repeated alternately.

Specifically, in the process of adsorption of the silicon raw material on the substrate, as the source gas containing silicon, a silane gas of a network having two amino groups in one molecule, for example, bis-tertiary-butylamino silane (referred to as BTBAS, hereinafter), is supplied to the processing chamber through a supply nozzle for the silicon source gas for a predetermined time period (T1). Thus, adsorption of BTBAS is carried out on the substrate. The time period of T1 may be, for example, 1 through 60 seconds. A flow rate of the source gas containing silicon may be 10 through 500 mL/min (sccm). Further, a pressure in the inside of the processing chamber may be 13.3 through 665 Pa.

Next, in the process of supplying the gas containing oxygen to the processing chamber and oxidizing the silicon material, as the gas containing oxygen, for example, plasma of O₂ gas obtained by using a plasma generating mechanism that includes a high-frequency power source is supplied to the processing chamber for a predetermined time period (T2) through a gas supply nozzle. Thereby, BTBAS, adsorption of which on the substrate has been carried out, is oxidized, and the SiO₂ film 16 is formed. The time period T2 may be, for example, 5 through 300 seconds. Further, a flow rate of the gas containing oxygen may be 100 through 20000 mL/min (sccm). Further, a frequency of the high-frequency power source may be 13.56 MHz. Electric power of the high-frequency power source may be 5 through 1000 W. A pressure in the inside of the processing chamber may be 13.3 through 665 Pa.

Further, on the occasion of switching between the process of adsorption of the source gas containing silicon on the substrate and the process of supplying the gas containing oxygen and oxidizing the silicon material, a process of supplying a purge gas made of an inactive gas such as a N₂ gas, for example, to the processing chamber while carrying out vacuum evacuation of the processing chamber may be carried out for a predetermined time period (T3) between the respective processes for the purpose of removing the residual gas in the immediately preceding process. The time period of T3 may be, for example, 1 through 60 seconds. A flow rate of the purge gas may be 50 through 5000 mL/min (sccm). It is noted that this process is carried out for the purpose of removing the gas remaining in the processing chamber. Therefore, in this process, vacuum evacuation may be performed continuously in a condition in which all the supply of the gas has been stopped without supplying the purge gas.

BTBAS is amino silane gas having two amino groups in one molecule used as the source gas containing silicon. As such an amino silane gas, other than the above-mentioned BTBAS, bis-diethylamino silane (BDEAS), bis-dimethylamino silane (BDMAS), diisopropyl amino silane (DIPAS), or bis-ethylmethylamino silane (BEMAS) may be used. Further, as the silicon source gas, an amino silane gas having three or more amino groups in one molecule may be used, or, further, an amino silane gas having one amino group in one molecule may also be used.

On the other hand, as the gas containing oxygen, a NO gas, a N₂O gas, a H₂O gas or a O₃ gas may be used, other than the O₂ gas. Plasma may be obtained therefrom by using a high-frequency electric field and may be used as an oxidizing agent. By using such plasma of the gas containing oxygen, it is possible to form the SiO₂ film at a temperature equal to or less than 300° C. Further, by adjusting the gas flow rate of the gas containing oxygen, the electrical power of the high-frequency power source and the pressure in the inside of the processing chamber, it is possible to form the SiO₂ film at a temperature equal to or less than 100° C. or at room temperature.

Next, step S116 is carried out. Step S116 is an etching process of carrying out etching so that the SiO₂ film 116 remains only as the side wall parts 126 of the core parts 125. Further, FIG. 10F is a sectional view showing a structure of the semiconductor device after the process S116 is carried out.

As shown in FIG. 10F, a state results such that the SiO₂ film 116 has been etched, and the SiO₂ films 116 remain only as the side wall parts 126 coating the side faces of the core parts 125. The etching of the SiO₂ film 116 is not particularly limited, and, for example, may be carried out by using a mixed gas of a gas of a CF family, such as CF₄, C₄F₈, CHF₃, CH₃F or CH₂F₂, and an Ar gas or such, or, a gas obtained from adding oxygen, as is necessary, to the mixed gas, or such. In order to carry out the etching such that only the side wall parts 126 of the core parts 125 of the SiO² films 116 remain, first patterns 121 made of the core parts 125 and the side wall parts 126 are formed. Assuming that a line width of the first patterns 121 is L101 and a space width thereof is S101, L101 may be 90 nm and S101 may be 30 nm because L101=L104+D101×2 and S101=L104+S104−L101, in a case where the line width L104 of the core parts 125 is 30 nm and the thickness D101 of the side wall parts 126 is 30 nm.

Next, a photoresist coating process including step S117 is carried out. Step S117 is the photoresist coating process of coating a predetermined pattern 121a of the first patterns 121 with a first photoresist film 117. FIG. 10G is a sectional view showing a structure of the semiconductor device after the process of step S117 is carried out.

As shown in FIG. 10G, the predetermined pattern 121a that is part of the first patterns 121 is coated with the first photoresist film 117. The first photoresist film 117 functions as a mask for protecting the first pattern 121a from among the first patterns 121 including the core parts 125 and the side wall parts 126, which is retained as the first pattern 121 without having the core parts 125 removed to form second patterns 122 made of the side wall parts 126 in steps S118 and S119.

It is noted that the line width L101 and the space width S101 of the first patterns 121 are both fine. However, accuracy of a metal mask used for carrying out photolithography to form the first photoresist film 117 that coats the pattern 121a that is part of the first patterns 121 requires not so high accuracy in comparison to a metal mask used for forming the first patterns 121. Therefore, it is possible to reduce the costs for manufacturing the metal masks.

As a material of the first photoresist film 117, for example, KrF resist or ArF resist may be used. Further, a thickness of the first photoresist 117 is not particularly limited, and, for example, may be 200 through 500 nm.

Next, a protective film removing process including step S118 is carried out. Step S118 is the protective film removing process of removing the protective films 114 of the core parts 125. FIG. 10H is a sectional view showing a structure of the semiconductor device after the process of step S118 is carried out.

The protective films 114 of the core parts 125 are etched in a state in which the predetermined first pattern 121a is coated with the first photoresist film 117. The etching may use, for example, a mixed gas of a gas of CF family, such as CF₄, C₄F₈, CHF₃, CH₃F or CH₂F₂, and an Ar gas or such, or, a gas obtained from adding oxygen, as is necessary, to the mixed gas. As a result, as shown in FIG. 10H, in the first patterns 121 that are not coated with the first photoresist film 117, the protective films 114 of the core parts 125 are removed and the organic films 113 of the core parts 125 are exposed.

Next, the second pattern forming process including step S119 is carried out. Step S119 is the second pattern forming process of forming second patterns 122 made of the side wall parts 126 remaining as a result of the organic films 113 of the core parts 125 being removed. FIG. 10I is a sectional view showing a structure of the semiconductor device after the process of step S119 is carried out.

By carrying out etching by using plasma of oxygen, nitrogen, hydrogen, ammonia or such, the organic films 113 of the core parts 125 are removed. As a result, as shown in FIG. 10I, in the first patterns 121 that are not coated with the first photoresist film 117, the organic films 113 of the core parts 125 are removed, only the side wall parts 126 remain, and the second patterns 122 are formed which are patterns such that the line width is D101 and the space widths L104 and S101 alternately occur. In the present embodiment, as a result of the line width L104 of the core parts 125 and the space width S101 of the first patterns 121 being made equal to one another, the space width S102 is equal to L104 and S101. Further, the line width equal to D101 is referred to as L102. As described above, as a result of L104 being 30 nm, S101 being 30 nm, and the thickness of the SiO₂ film 116 (the width D101 of the side wall parts 126) being 30 nm, it is possible to form the second patterns in which L102 is 30 nm and S102 is 30 nm.

Next, the to-be-etched layer etching process including steps S120 through S122 is carried out.

Step S120 is a process of etching the second to-be-etched layer 112 that is a lower layer of the organic film 113 by using the second patterns 122 and the first pattern 121a as masks, and forming fifth patterns 128 including the second to-be-etched layers 112, having the side wall parts 126 as upper layer parts, and having the same shapes as those of the second patterns 122 and the first pattern 121a. Further, FIG. 10J is a sectional view showing a structure of the semiconductor device after the process of step S120 is carried out.

The second to-be-etched layer 112 is etched by the use of the second patterns 122 made of the side wall parts 126 and the first pattern 121a made of the core part 125 and the side wall parts 126 as masks and the first to-be-etched layer 111 as an etching stopper layer. The etching of the second to-be-etched layer 112 made of, for example, amorphous silicon or polysilicon may be carried out by using plasma of a gas or such of Cl₂, Cl₂+HBr, Cl₂+O₂, CF₄+O₂, SF₆, Cl₂+N₂, Cl₂+HCl, HBr+Cl₂+SF₆ or such. As a result, as shown in FIG. 10J, the fifth patterns 128 are formed in which the second patterns 122 and the first pattern 121a are formed.

Step S121 is a process of etching the first to-be-etched layer 111 by using the fifth patterns 128 as masks, and forming sixth patterns 129 including the first to-be-etched layers 111 and the second to-be-etched layers 112. FIG. 10K is a sectional view showing a structure of the semiconductor device after the process of step S121 is carried out.

The etching of the first to-be-etched layer 111 may be carried out by using, for example, a mixed gas of a CF family, such as CF₄, C₄F₈, CHF₃, CH₃F or CH₂F₂, and an Ar gas or such, or, a gas obtained from adding oxygen, as is necessary, to the mixed gas, or such. At this time, the SiO₂ films 116 included in the side wall parts 126 in the first pattern 121 and the second patterns 122, and the protective films 114 included in the core parts 125 in the first pattern 121a, are etched and removed. As a result, as shown in FIG. 10K, it is possible to simultaneously form the second patterns 122 that are even number patterns having the line width L102 and the space width S102 and the first pattern 121a that is an odd number pattern having the line width L101. However, the organic film 113 of the core part 125 is not removed and remains at the top of the second to-be-etched layer 112 included in the first pattern 121a.

Step S122 is a process of removing the organic films 113 not removed in step S121. FIG. 10L is a sectional view showing a structure of the semiconductor device after the process of step S122 is carried out.

Removing the organic film 113 is carried out by etching using plasma of oxygen, nitrogen, hydrogen, ammonia or such, for example. As a result, as shown in FIG. 10L, the organic film 113 remaining on the second to-be-etched layers 112 included in the first pattern 121a is removed, and thus, it is possible to form, simultaneously, the first pattern 121a and the second patterns 122, including the first to-be-etched layers 111 and the second to-be-etched layers 112.

Thus, according to the present embodiment, only by carrying out fine photolithography by using the masks of, for example, the line width 60 nm, it is possible to form the fine even number patterns of, for example, the line width 30 nm and the space width 30 nm, and simultaneously, it is possible to form the odd number pattern having, for example, the line width 90 nm without newly carrying out a fine photolithography process.

For example, also by the method disclosed by Patent Document 3, it is possible to form even number patterns in an area of fine pattern density, and simultaneously, odd number patterns or an isolated pattern in an area of coarse pattern density. However, in the method disclosed by Patent Document 3, core part patterns for forming fine patterns are made of amorphous carbon films, and side wall parts that coat the side walls of the core part patterns are made of silicon oxide films. Thus, materials of the patterns that are used as hard masks used for etching a to-be-etched layer are different between the area of fine pattern density and the area of coarse pattern density. If the materials of the patterns are different, influences, such as etching resistance in a lateral direction, a ratio (selection ratio) in etching rates with respect to the lower layer and so forth for when the to-be-etched layer is etched, are different. Thus, it is not possible to make uniform the influences throughout the area of the masks. As a result, in the case where the area of fine pattern density and the area of coarse pattern density are mixed in the patterns used as the hard masks, it is not possible to maintain CD (Critical Dimension) of the patterns to be uniform at high accuracy.

On the other hand, in the present embodiment, both the patterns of the core parts used for forming the fine patterns and the side wall parts that coat the side walls of the patterns of the core parts are made of the silicon oxide films. Therefore, the materials of the patterns that are used as the hard masks used for etching the to-be-etched layer are identical between the area of fine pattern density and the area of coarse pattern density. As the materials of the patterns are thus identical, influences, such as etching resistance in a lateral direction, a ratio (selection ratio) in etching rates with respect to the lower layer and so forth for when the to-be-etched layer is etched, are identical. Thus, it is possible to make uniform the influences throughout the area of the masks. As a result, in the case where the area of fine pattern density and the area of coarse pattern density are mixed in the patterns used as the hard masks, it is possible to maintain CD (Critical Dimension) of the patterns to be uniform at high accuracy.

Also in the second embodiment, like the first embodiment, as an example of such an electronic device having an odd number pattern having a different line width adjacent to even number patterns, a NAND-type flash memory may be cited. FIG. 3 shows an equivalent circuit of a NAND-type flash memory. As shown in FIG. 3, the NAND-type flash memory has a circuit such that memory cells of 8 bits are disposed in such a manner that bit lines thereof are connected in series, and field effect transistors (FETs) each having one selection gate for inputting and outputting data are connected in series on both sides of the memory cells. That is, the first selection gate 40, eight floating gates 41 through 48 corresponding to the 8 bits, and the second selection gate 49 are connected in series with a bit line 39. In such a structure of the NAND-type flash memory, in a case where a gate length of the FETs corresponding to the selection gates 40 and 49 of both sides is made longer than a gate length of the memory cells, it is not necessary to newly manufacture masks for the FETs, and thus, it is possible to reduce the manufacturing costs.

Further, in the present embodiment, it is possible to carry out all of the processes of steps S118 through S122 by dry process. Therefore, it is possible to use a manufacturing method in which the processes are carried out in a lump in such a manner that only the gas type is changed in the same chamber. By carrying out the processes of steps S118 through S122 in a lump, it is possible to simplify the processes and reduce the manufacturing costs in comparison to the prior art, and it is possible to improve the productivity.

It is noted that in the present embodiment, the film forming process of step S115 for the SiO₂ film is carried out by the low-temperature MLD. However, as long as it is possible to form the SiO₂ film 116 without damaging the core parts 125 made of the organic films 113, the upper layer parts of which are protected by the protective films 114, the above-mentioned method should not be limited to, and a well-known film forming method such as CVD, RF (Radio Frequency) magnetron sputtering, or electron beam evaporation may be used.

Further, in the present embodiment, the first pattern forming process includes the third pattern forming process of forming the third patterns made of the second photoresist films, the core part pattern forming process of forming the core part patterns based on the third patterns, and the film forming process of forming the SiO₂ film. However, as long as the upper layer parts of the core parts included in the first patterns function as protective films to protect the organic films of the core parts, the mode of the present embodiment is not so limited, and various variations may be made.

Further, in the present embodiment, in the core part pattern forming process, trimming of the third patterns made of the second photoresist films need not be carried out, and the first patterns may be formed by using the core parts having a line width approximately equal to the line width of the third patterns.

Further, in the present embodiment, the protective film 114 having the function of protecting the surface of the organic film 113 is used when the patterns of the core parts 125 including the organic films 113 are formed. However, the protective film 114 need not be used if, in the photoresist coating process including step S117, material of the organic film 113 is selected such that the organic film 113 is neither degraded nor deteriorated during resist coating, exposing, developing and so forth carried out when the predetermined pattern 121a of the first patterns 121 is coated with the first photoresist film 117.

### First Variant Embodiment of Second Embodiment

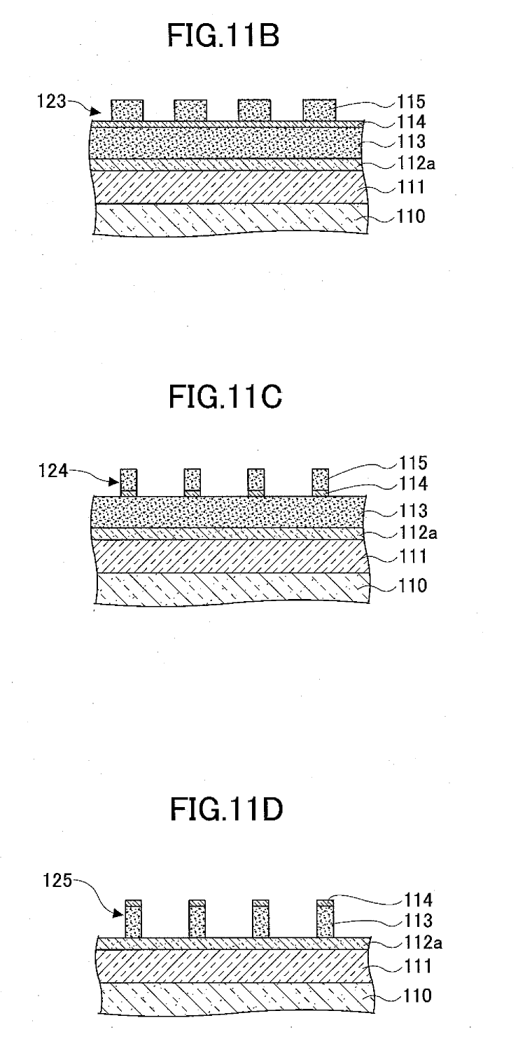

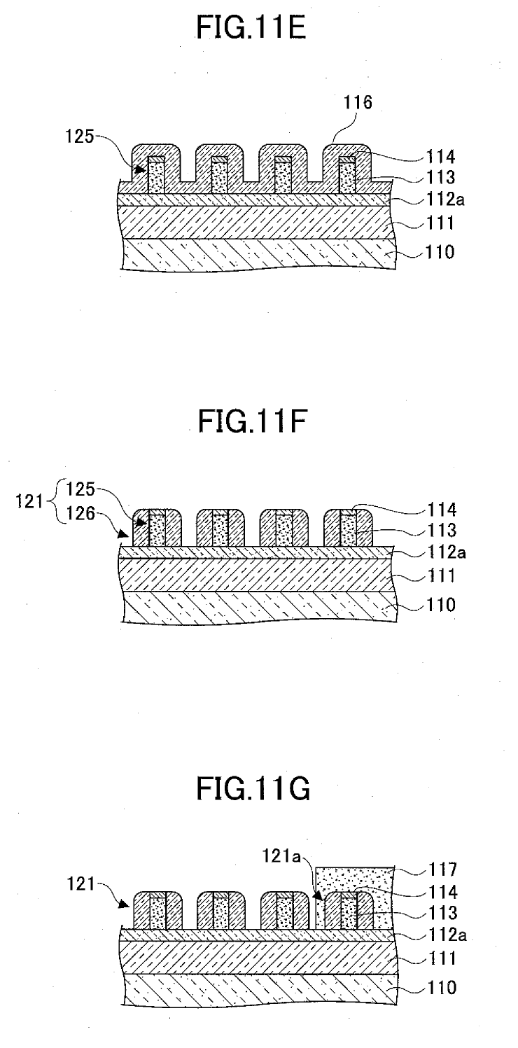

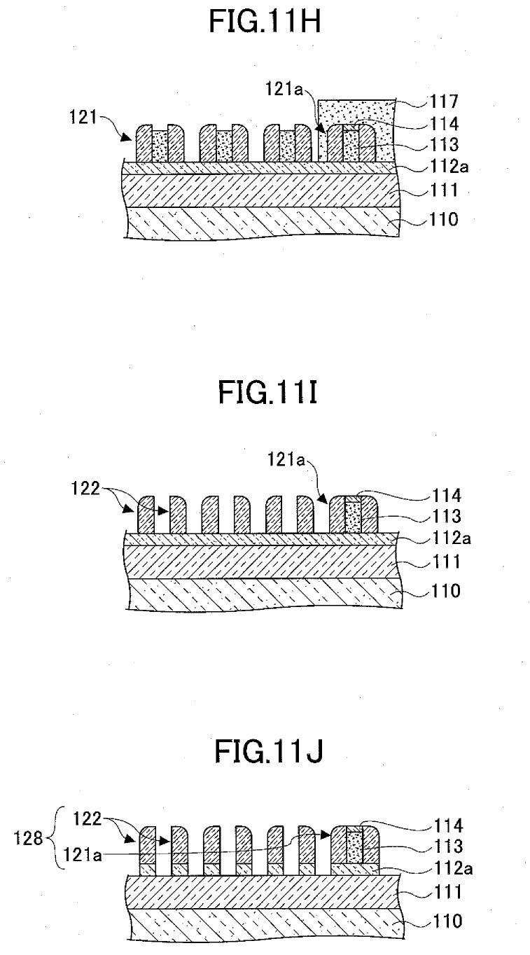

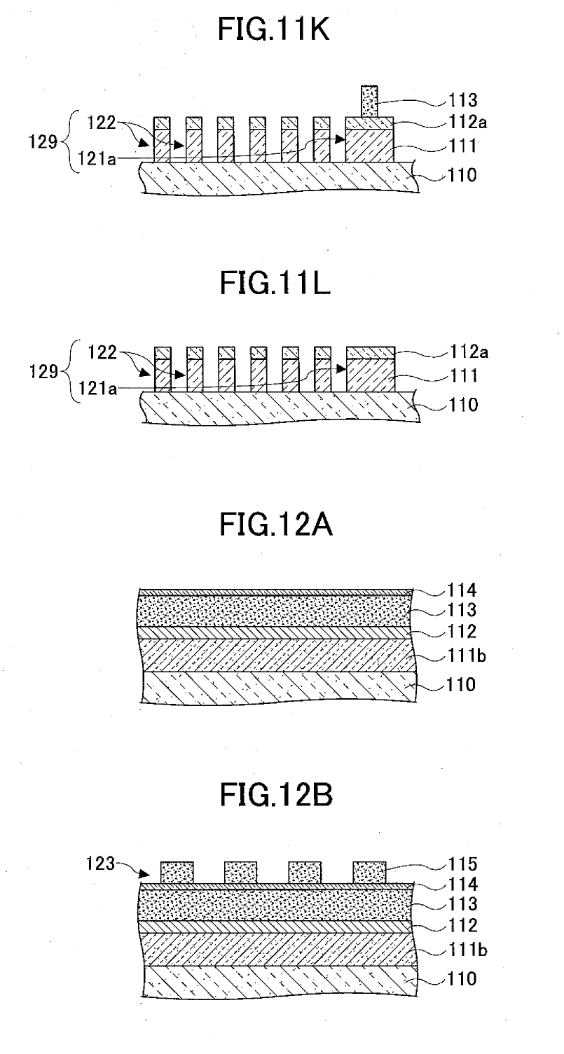

Next, with reference to FIGS. 11A through 11L, a semiconductor device manufacturing method in a first variant embodiment of the second embodiment according to the present invention will be described.

FIGS. 11A through 11L illustrate processes of the semiconductor device manufacturing method in the present variant embodiment, and are sectional views diagrammatically showing structures of the semiconductor device in the respective processes. It is noted that in the description below, the same reference numerals are given to the parts already described above, and description may be omitted (also the same in variant embodiments and embodiments below).

The semiconductor device manufacturing method according to the present variant embodiment is different from the semiconductor device manufacturing method according to the second embodiment in that the second to-be-etched layer is a silicon nitride layer.

With reference to FIGS. 11A through 11L, different from the second to-be-etched layer 112 made of amorphous silicon or polysilicon being used in the second embodiment, the second to-be-etched layer 112a made of a silicon nitride layer (referred to as SiN, hereinafter) is used in the present variant embodiment.

The semiconductor device manufacturing method according to the present variant embodiment includes processes of steps S111 through S122, as shown in FIG. 9, like the second embodiment.

First, a preparing process including step S111 is carried out. As shown in FIG. 11A, also in the present variant embodiment, like the second embodiment, a substrate in which a first to-be-etched layer 111, a second to-be-etched layer 112a, an organic film 113 and a protective film 114 are formed in the stated order from the bottom on the substrate 110 is used. However, the second to-be-etched layer 112a is SiN, different from amorphous silicon or polysilicon in the second embodiment. Like the second embodiment, a thickness of the second to-be-etched layer 112a may be, for example, 20 through 200 nm.

Like the second embodiment, the second to-be-etched layer 112a functions as a mask in subsequent various processing processes as a result of patterns being formed therein. SiN can improve a selection ratio of etching of SiN and the adjacent organic film 113 or first to-be-etched layer 111 in comparison to amorphous silicon or polysilicon used in the second embodiment.

A first pattern forming process including steps S112 through S116 is like the second embodiment, and partial structures of the semiconductor device when the respective processes are finished are shown in FIGS. 11B through 11F.

However, in a process of etching a SiO₂ film 116 in such a manner that the SiO₂ films remain as side wall parts 126 of core parts 125 as shown in step S116 and FIG. 11F, it is possible to improve a ratio (selection ratio) of an etching rate of the SiO₂ film 116 with respect to an etching rate of the second to-be-etched layer 112a by controlling conditions of the etching of the SiO₂ film 116, and cause the etching to be positively stopped when the etching has reached a surface of the second to-be-etched layer 112a at places other than the side wall parts 126. Specifically, the etching of the SiO₂ film 116 may use, for example, a mixed gas of a gas of a CF family, such as CF₄, C₄F₈, CHF₃, CH₃F or CH₂F₂, and an Ar gas or such, or, a gas obtained from adding oxygen to the mixed gas, as is necessary, or such, and it is possible to improve the selection ratio of etching between SiO₂ and SiN by controlling a type of the CF family gas, a type, a flow rate ratio and a gas pressure of the mixed gas, and a substrate temperature. As a result, it is possible to carry out the manufacturing method that is superior in repeatability.

A photoresist coating process including step S117 is like the second embodiment. A structure of the semiconductor device after the process of step S117 is finished is shown in FIG. 11G.

In a protective film removing process including step 118, it is possible to increase a selection ratio of etching between SiO₂ and SiN by changing process conditions, like the process of etching the SiO₂ film in step S116, and remove only the protective films 114 of the core parts 125 without etching the second to-be-etched layer 112a that is partially exposed. A structure of the semiconductor device after the process of step S118 is shown in FIG. 11H.

A second pattern forming process including step S119 is like the second embodiment. A structure of the semiconductor device after the process of step S119 is finished is shown in FIG. 11I.

Next, a to-be-etched layer etching process including steps S120 through S122 is carried out. Partial structures of the semiconductor device after the respective processes of steps S120 through S122 are finished are shown in FIGS. 11J through 11L.

Step S120 is a process of etching the second to-be-etched layer 112a by using second patterns 122 and a first pattern 121a as masks, like the second embodiment.

In the present variant embodiment, a ratio (selection ratio) between an etching rate for the second to-be-etched layer 112a made of SiN and an etching rate for the first to-be-etched layer 111 made of TEOS can be improved as a result of the conditions of the etching being controlled, and it is possible to positively stop the etching when the etching has reached the surface of the first to-be-etched layer 111. Specifically, the etching of the second to-be-etched layer 112a is carried out by using, for example, a mixed gas of a gas of a CF family, such as CF₄, C₄F₈, CHF₃, CH₃F or CH₂F₂, and an Ar gas or such, or, a gas obtained from adding oxygen to the mixed gas, as is necessary, or such, and it is possible to improve the selection ratio of etching between SiN and SiO₂ by controlling a type of the CF family gas, a type, a flow rate ratio and a gas pressure of the mixed gas, and a substrate temperature. As a result, it is possible to carry out the manufacturing method that is superior in repeatability.

Step S121 is a process of etching the first to-be-etched layer 111 by using the second patterns 122 and the first pattern 121a as masks, like the second embodiment.

In the present variant embodiment, a selection ratio in etching of the first to-be-etched layer 111 made of TEOS with respect to the second to-be-etched layer 112a made of SiN can be improved as a result of the conditions of the etching being controlled, and it is possible to precisely transfer shapes of the masks to the to-be-etched layer 111 without etching the patterns made of the second to-be-etched layers 112a while the first to-be-etched layer 111 is being etched. Specifically, the etching of the first to-be-etched layer 111 made of TEOS is carried out by using, for example, a mixed gas of a gas of a CF family, such as CF₄, C₄F₈, CHF₃, CH₃F or CH₂F₂, and an Ar gas or such, or, a gas obtained from adding oxygen to the mixed gas, as is necessary, or such, and it is possible to improve the selection ratio of etching between SiN and SiO₂ by controlling a type of the CF family gas, a type, a flow rate ratio and a gas pressure of the mixed gas, and a substrate temperature. As a result, it is possible to carry out the manufacturing method that is superior in repeatability.

A second pattern forming process including step S122 is like the second embodiment. Further, a structure of the semiconductor device after the process of step S122 is finished is shown in FIG. 11L.

Thus, according to the semiconductor device manufacturing method in the present variant embodiment, by changing the second to-be-etched layer 112a from amorphous silicon or polysilicon to SiN, it is possible to improve the selection ratio in etching with respect to the adjacent organic film 113 or to-be-etched layer 111, and manufacture the semiconductor device that is superior in repeatability at low costs.

It is noted that a composition ratio of Si and N of SiN is not particularly limited, and, for example, Si₃N₄ may be used. Further, instead of SiN, SiON (silicon oxynitride) may be used.

### Second Variant Embodiment of Second Embodiment

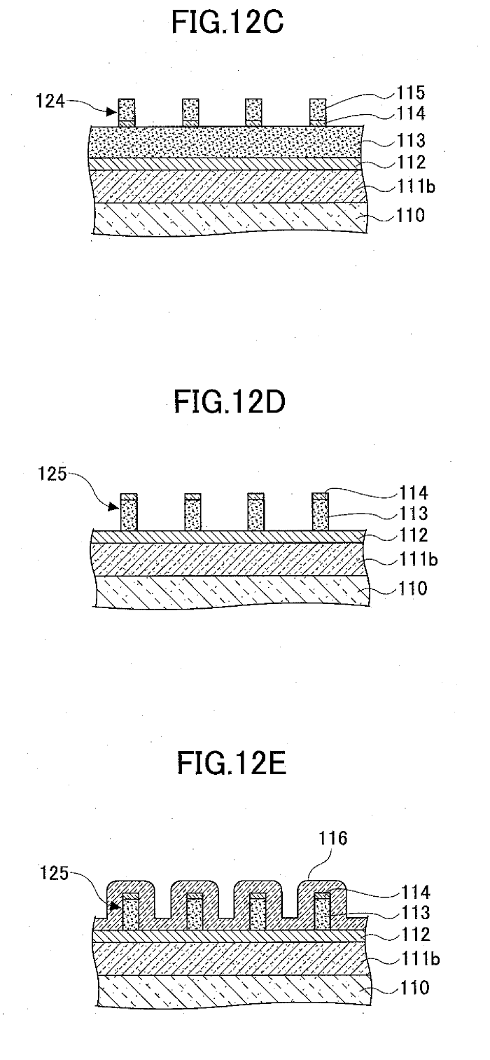

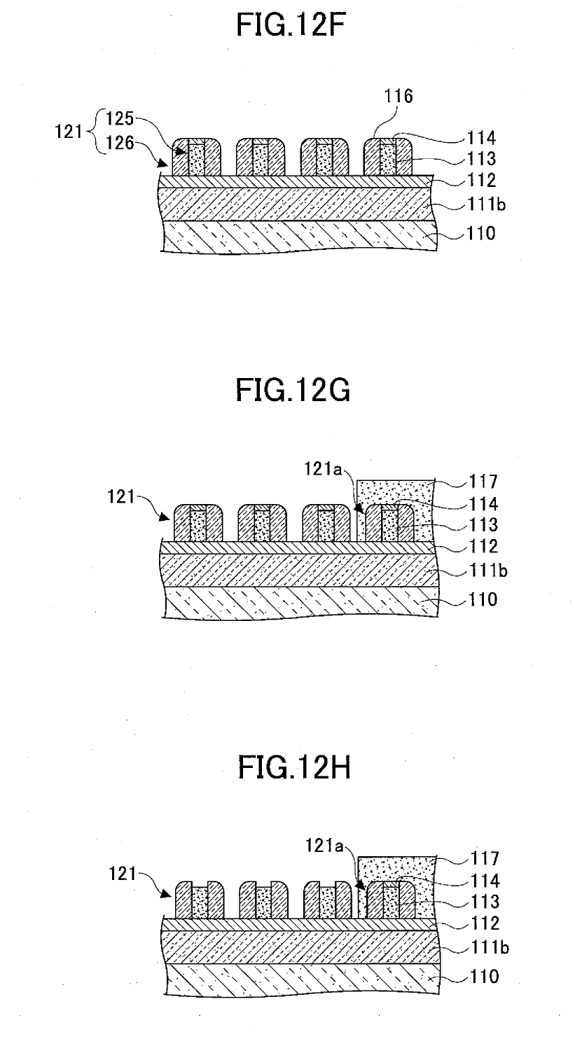

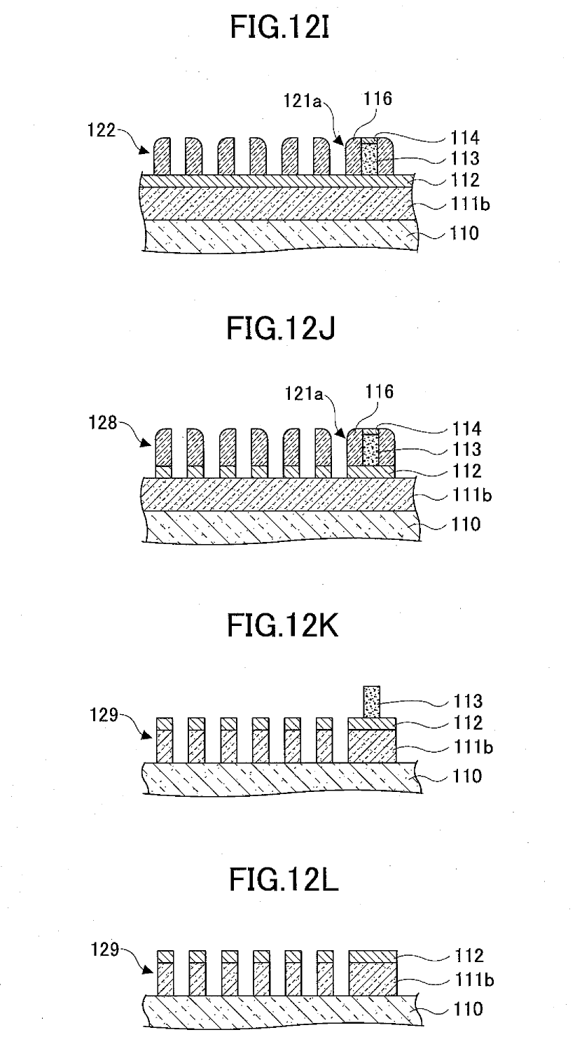

Next, with reference to FIGS. 12A through 12L, a semiconductor device manufacturing method in a second variant embodiment of the second embodiment according to the present invention will be described.

FIGS. 12A through 12L illustrate processes of the semiconductor device manufacturing method in the present variant embodiment, and are sectional views diagrammatically showing structures of the semiconductor device in the respective processes.

The semiconductor device manufacturing method according to the present variant embodiment is different from the semiconductor device manufacturing method according to the second embodiment in that the first to-be-etched layer is a silicon nitride layer.

With reference to FIGS. 12A through 12L, different from the first to-be-etched layer 111 made of TEOS being used in the second embodiment, the first to-be-etched layer 111b made of SiN is used in the present variant embodiment.

The semiconductor device manufacturing method according to the present variant embodiment includes processes of steps S111 through S122, as shown in FIG. 9, like the second embodiment.

First, a preparing process including step S111 is carried out. As shown in FIG. 12A, also in the present variant embodiment, like the second embodiment, a substrate in which a first to-be-etched layer 111b, a second to-be-etched layer 112, an organic film 113 and a protective film 114 are formed in the stated order from the bottom on the substrate 110 is used. However, the first to-be-etched layer 111b is SiN, different from TEOS in the second embodiment. Like the second embodiment, a thickness of the first to-be-etched layer 111b may be, for example, 20 through 200 nm.

Like the second embodiment, the first to-be-etched layer 111b functions as a mask in subsequent various processing processes as a result of patterns being formed therein. SiN can improve a selection ratio of etching of SiN and the adjacent second to-be-etched layer 112 in comparison to TEOS used in the second embodiment.

A first pattern forming process, a photoresist coating process and a protective film removing process including steps S112 through S119 are like the second embodiment, and partial structures of the semiconductor device when the respective processes are finished are shown in FIGS. 12B through 12I.

Next, a to-be-etched layer etching process including steps S120 through S122 is carried out. Partial structures of the semiconductor device after the respective processes of steps S120 through S122 are finished are shown in FIGS. 12J through 12L.

Step S120 is a process of etching the second to-be-etched layer 112 by using fifth pattern 128 including second patterns 122 and a first pattern 121a as masks, like the second embodiment.

In the present variant embodiment, a selection ratio between an etching rate for the second to-be-etched layer 112a made of amorphous silicon or polysilicon and an etching rate for the first to-be-etched layer 111b made of SiN can be improved as a result of the conditions of the etching being controlled, and it is possible to positively stop the etching when the etching has reached the surface of the first to-be-etched layer 111b. Specifically, the etching of the second to-be-etched layer 112 made of amorphous silicon or polysilicon is carried out by using, for example, a gas of Cl₂, Cl₂+HBr, Cl₂+O₂, CF₄+O₂, SF₆, Cl₂+N₂, Cl₂+HCl, HBr+Cl₂+SF₆ or such, and it is possible to improve the selection ratio of etching between amorphous silicon or polysilicon and SiN by controlling a type of the gas, a flow rate, a gas pressure, and a substrate temperature. As a result, it is possible to carry out the manufacturing method that is superior in repeatability.

Step S121 is a process of etching the first to-be-etched layer 111b by using sixth patterns 129 including the second patterns 122 and the first pattern 121a as masks, like the second embodiment.

In the present variant embodiment, a selection ratio in etching of the first to-be-etched layer 111b made of SiN with respect to the second to-be-etched layer 112 made of amorphous silicon or polysilicon can be improved as a result of the conditions of the etching being controlled, and it is possible to precisely transfer shapes of the masks to the to-be-etched layer 111b without etching the patterns made of the second to-be-etched layers 112 during the first to-be-etched layer 111b being etched. Specifically, the etching of the first to-be-etched layer 111b made of SiN is carried out by using, for example, a mixed gas of a gas of a CF family, such as CF₄, C₄F₈, CHF₃, CH₃F or CH₂F₂, and an Ar gas or such, or, a gas obtained from adding oxygen to the mixed gas, as is necessary, or such, and it is possible to improve the selection ratio of SiN with respect to amorphous silicon or polysilicon by controlling a type of the CF family gas, a type, a flow rate ratio and a gas pressure of the mixed gas, and a substrate temperature. As a result, it is possible to carry out the manufacturing method that is superior in repeatability.

Step S122 is like the second embodiment. Further, a structure of the semiconductor device after the process of step S122 is finished is shown in FIG. 12L.

Thus, according to the semiconductor device manufacturing method in the present variant embodiment, by changing the first to-be-etched layer 111b from TEOS to SiN, it is possible to improve the selection ratio in etching with respect to the adjacent second to-be-etched layer 112, and manufacture the semiconductor device that is superior in repeatability at low costs.

It is noted that a composition ratio of Si and N of SiN is not particularly limited, and, for example, Si₃N₄ may be used. Further, instead of SiN, SiON (silicon oxynitride) may be used.

### Third Variant Embodiment of Second Embodiment

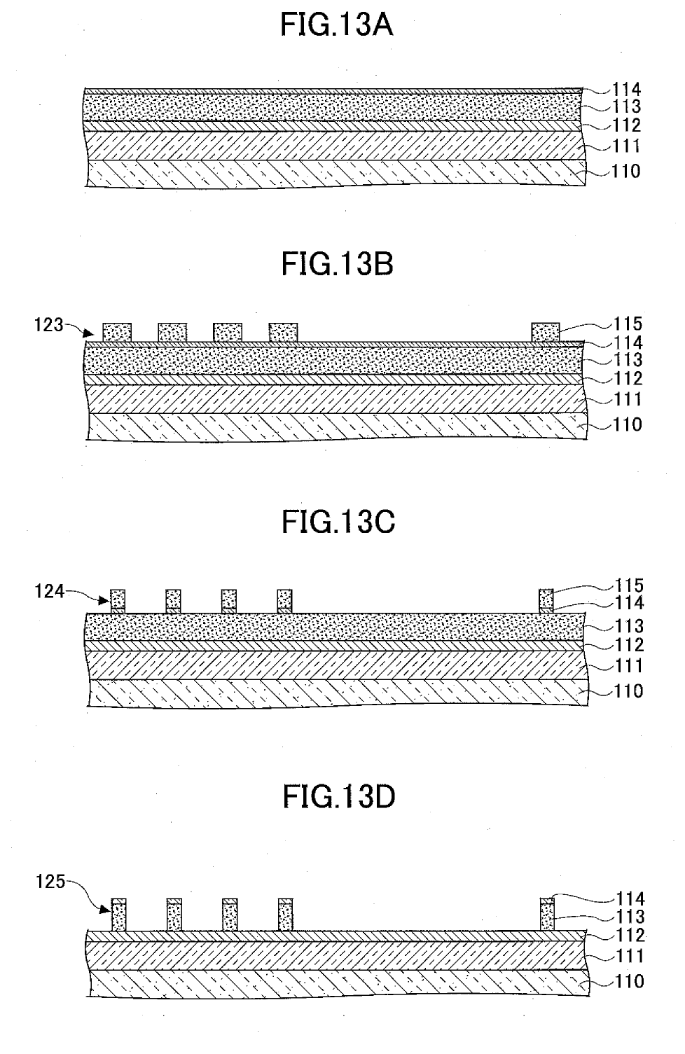

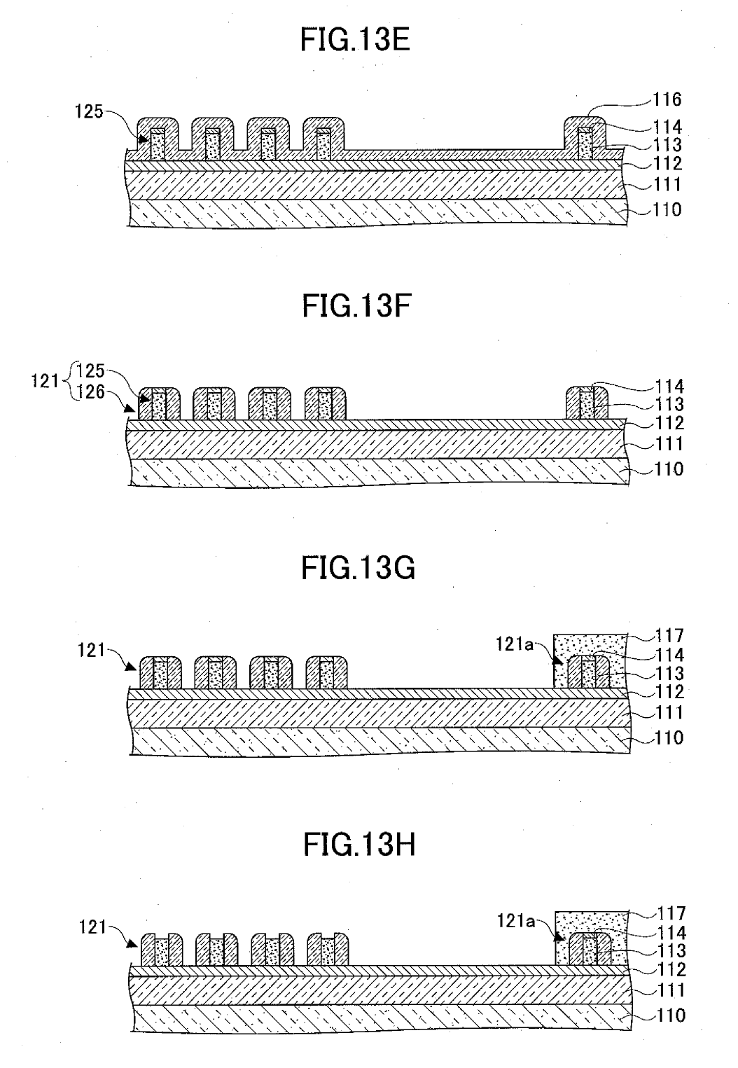

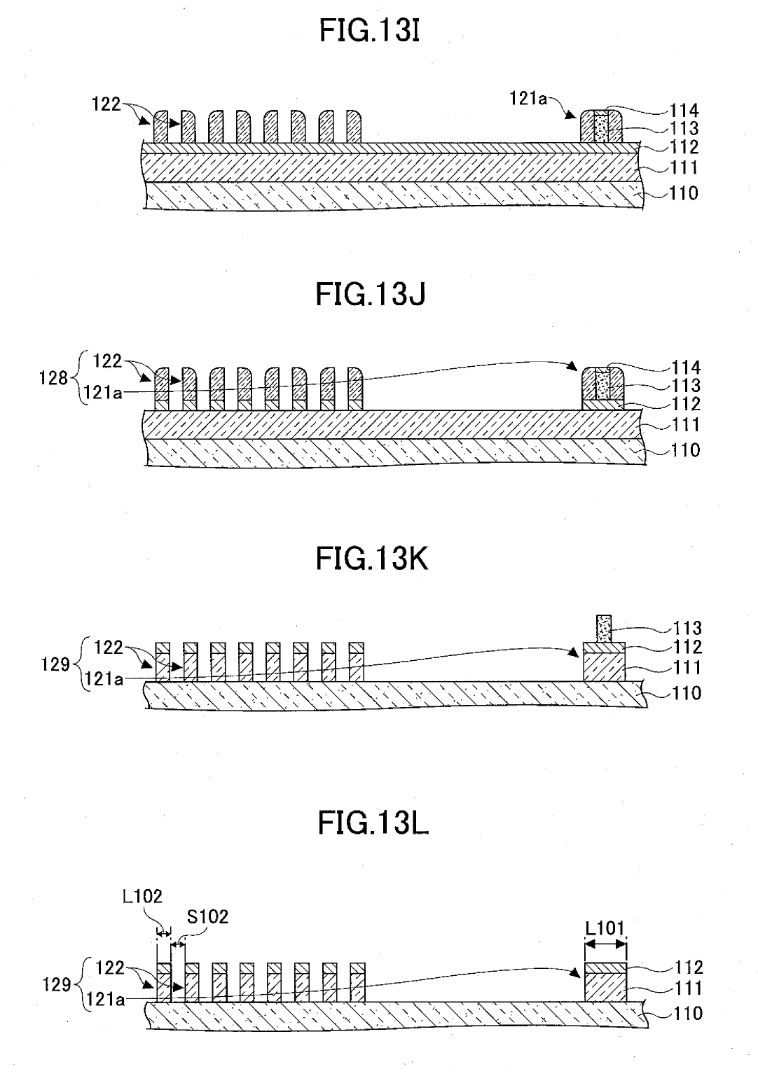

Next, with reference to FIGS. 13A through 13L, a semiconductor device manufacturing method according to a third variant embodiment of the second embodiment of the present invention will be described.

FIGS. 13A through 13L illustrate processes of the semiconductor device manufacturing method according to the present variant embodiment, and are sectional views diagrammatically showing structures of a semiconductor device in the respective processes.

The semiconductor device manufacturing method according to the present variant embodiment is different from the semiconductor device manufacturing method according to the second embodiment in that an isolated pattern is formed simultaneously at a position away from even number patterns.

With reference to FIGS. 13A through 13L, different from the second embodiment in which the odd number pattern is simultaneously formed adjacent to the even number patterns, the isolated pattern is formed at a position away from the even number patterns in the present variant embodiment.

The semiconductor device manufacturing method according to the present variant embodiment includes steps S111 through S122 as shown in FIG. 9, like the second embodiment.

First, a preparing process including step S111 is carried out. As shown in FIG. 13A, also in the present variant embodiment, like the second embodiment, a substrate in which, on a substrate 110, a first to-be-etched layer 111, a second to-be-etched layer 112, an organic film 113 and a protective film 114 are formed in the stated order from the bottom, is used.

Next, step S112 is carried out. That is, a third pattern forming process of exposing and developing a second photoresist film 115 and forming third patterns 123 of the second photoresist films 115 is carried out. In the present variant embodiment, the second photoresist film 115 is formed on the protective film 114, photolithography is carried out by using such a metal mask that the isolated pattern is disposed at a place away from the even patterns of the third patterns 123, exposing and developing are carried out, and the third patterns 123 having the isolated pattern are formed. A structure of the semiconductor device after the process of step S112 is carried out is shown in FIG. 13B.

A first pattern forming process including steps S113 through S116 is like the second embodiment, and partial structures of the semiconductor device after the respective processes are carried out are shown in FIG. 13C through 13F.

Next, a photoresist coating process of step S117 is carried out. That is, the isolated pattern is coated by a first photoresist film 117. Material and a thickness of the first photoresist film 117 may be like the same as the second embodiment. However, a metal mask used when the first photoresist film 117 is exposed in the present variant embodiment is different from the second embodiment, and, has such a pattern that the first photoresist film 117 coats a part including the isolated pattern. Further, because the metal mask does not require so high accuracy in comparison to the metal mask for forming the first patterns, it is possible to reduce the costs required for manufacturing the metal mask, like the second embodiment. A structure of the semiconductor device after the process of step S117 is carried out is shown in FIG. 13G.

After that, a protective film removing process, a second pattern forming process and a to-be-etched layer etching process including steps S118 through S122 are like the second embodiment, and partial structures of the semiconductor device after the respective processes are finished are shown in FIGS. 13H through 13L. As a result, it is possible to form, in a lump, the patterns having the isolated pattern made of the first to-be-etched layer 111 and the second to-be-etched layer 112 and having the line width L101 at the position away from the even number patterns having the line width L102 and the space width S102.

### Fourth Variant Embodiment of Second Embodiment

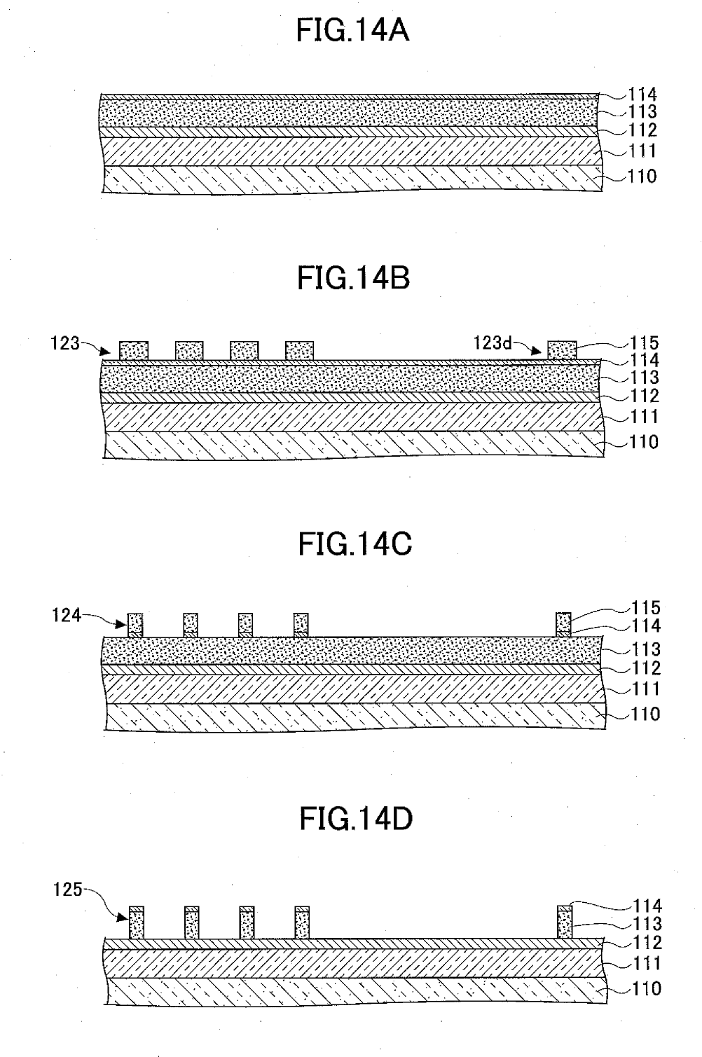

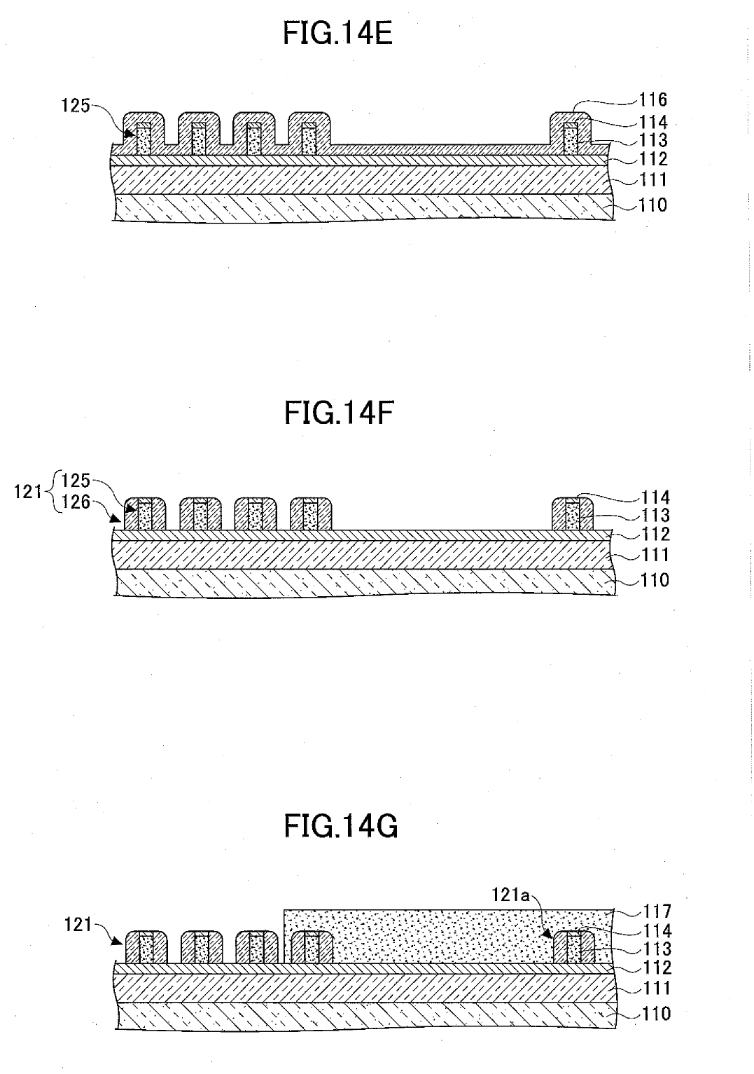

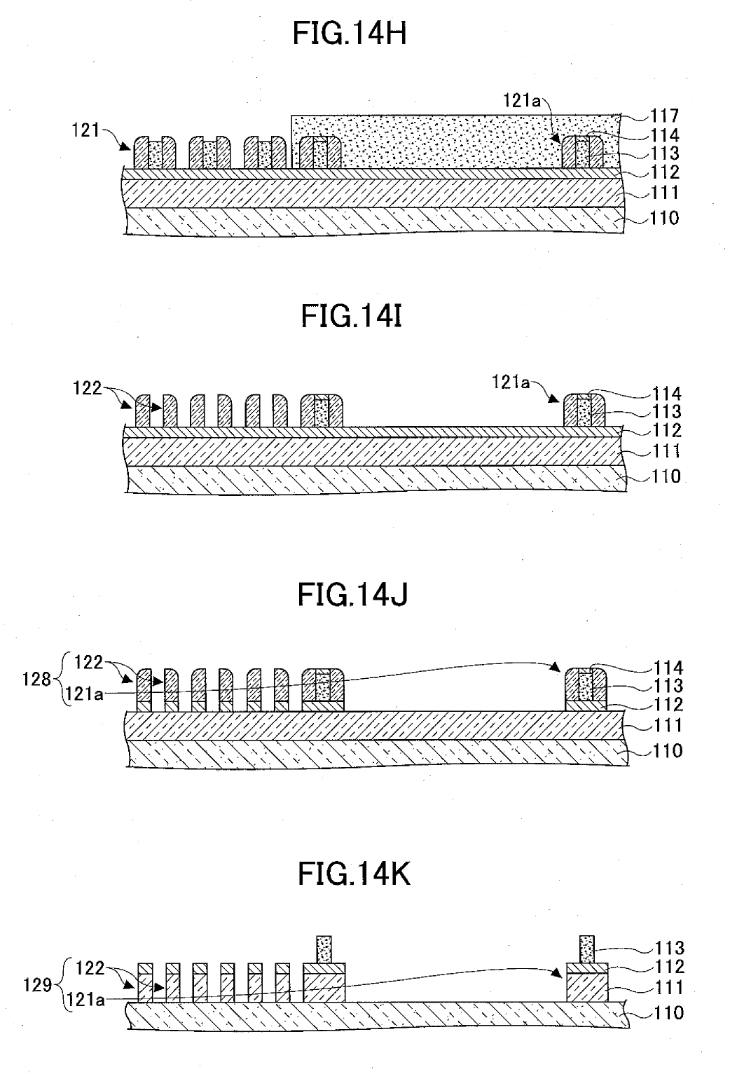

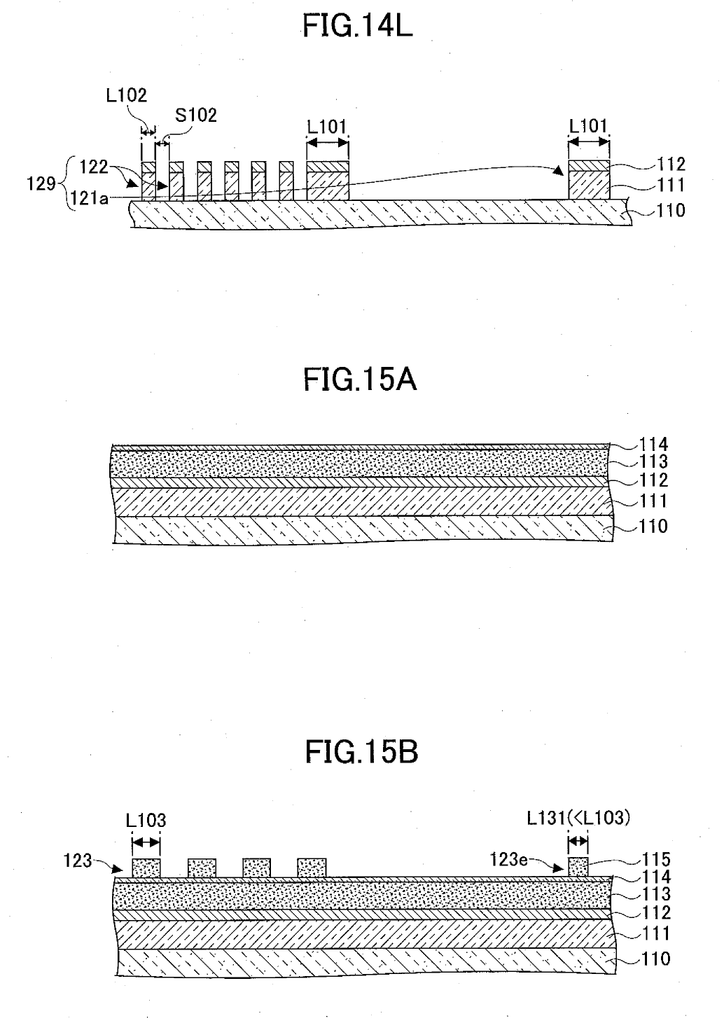

Next, with reference to FIGS. 14A through 14L, a semiconductor device manufacturing method according to a fourth variant embodiment of the second embodiment of the present invention will be described.

FIGS. 14A through 14L illustrate processes of the semiconductor device manufacturing method according to the present variant embodiment, and are sectional views diagrammatically showing structures of a semiconductor device in the respective processes.

The semiconductor device manufacturing method according to the present variant embodiment is different from the semiconductor device manufacturing method according to the second embodiment in that an odd number pattern is formed simultaneously at a position adjacent to even number patterns, and also, an isolated pattern is formed simultaneously at a position away from the even number patterns.

With reference to FIGS. 14A through 14L, different from the second embodiment in which the odd number pattern is simultaneously formed adjacent to the even number patterns, the odd number pattern is formed at the position adjacent to the even number patterns simultaneously, and also, the isolated pattern is formed at the position away from the even number patterns in the present variant embodiment.

The semiconductor device manufacturing method according to the present variant embodiment includes steps S111 through S122 as shown in FIG. 9, like the second embodiment.

First, a preparing process including step S111 is carried out. As shown in FIG. 14A, also in the present variant embodiment, like the second embodiment, a substrate in which, on a substrate 110, a first to-be-etched layer 111, a second to-be-etched layer 112, an organic film 113 and a protective film 114 are formed in the stated order from the bottom, is used.

Next, step S112 is carried out. That is, a third pattern forming process of exposing and developing a second photoresist film 115 and forming third patterns 123 of the second photoresist films 115 is carried out. In the present variant embodiment, like the third variant embodiment of the second embodiment, the second photoresist film 115 is formed on the protective film 114, photolithography is carried out by using such a metal mask having a part for forming the isolated pattern 123b at the place away from the even patterns of the third patterns 123, exposing and developing are carried out, and the third patterns 123 having the isolated pattern 123b are formed. A structure of the semiconductor device after the process of step S112 is carried out is shown in FIG. 14B.

A first pattern forming process including steps S113 through S116 is like the second embodiment, and partial structures of the semiconductor device after the respective processes are carried out are shown in FIG. 14C through 14F.

Next, a photoresist coating process of step S117 is carried out. That is, the isolated pattern 121a is coated by a first photoresist film 117. Material and a thickness of the first photoresist film 117 may be the same as the second embodiment. However, a metal mask used when the first photoresist film 117 is exposed in the present variant embodiment is different from the second embodiment and also from the third variant embodiment of the second embodiment, and, has such a pattern that the first photoresist film 117 coats a part including the isolated pattern 121a and one pattern at one end of the even number patterns. Further, because the metal mask does not require so high accuracy in comparison to the metal mask for forming the first patterns 121, it is possible to reduce the costs required for manufacturing the metal mask, like the second embodiment. A structure of the semiconductor device after the process of step S117 is carried out is shown in FIG. 14G.

After that, a protective film removing process, a second pattern forming process and a to-be-etched layer etching process including steps S118 through S122 are like the second embodiment, and partial structures of the semiconductor device after the respective processes are finished are shown in FIGS. 14H through 14L. As a result, it is possible to form, in a lump, the patterns having made of the first to-be-etched layers 111 and the second to-be-etched layers 112, having the odd number pattern having the line width L101 at the position adjacent to the even number patterns having the line width L102 and the space width S102, and having the isolated pattern having the line width L101 also at the position away from the even number patterns.

### Fifth Variant Embodiment of Second Embodiment

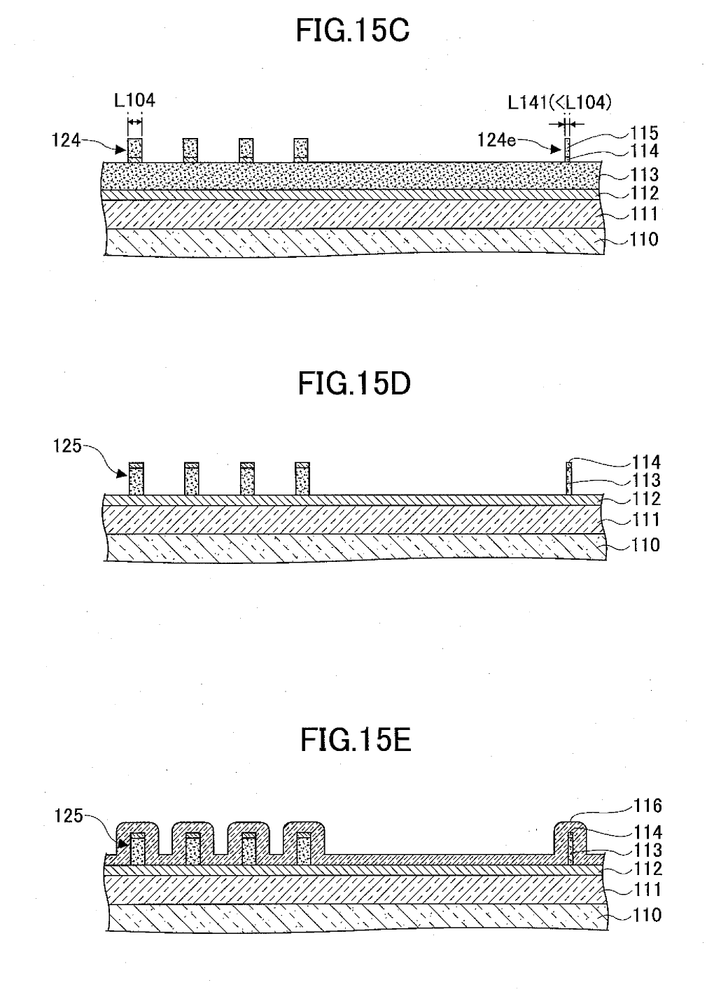

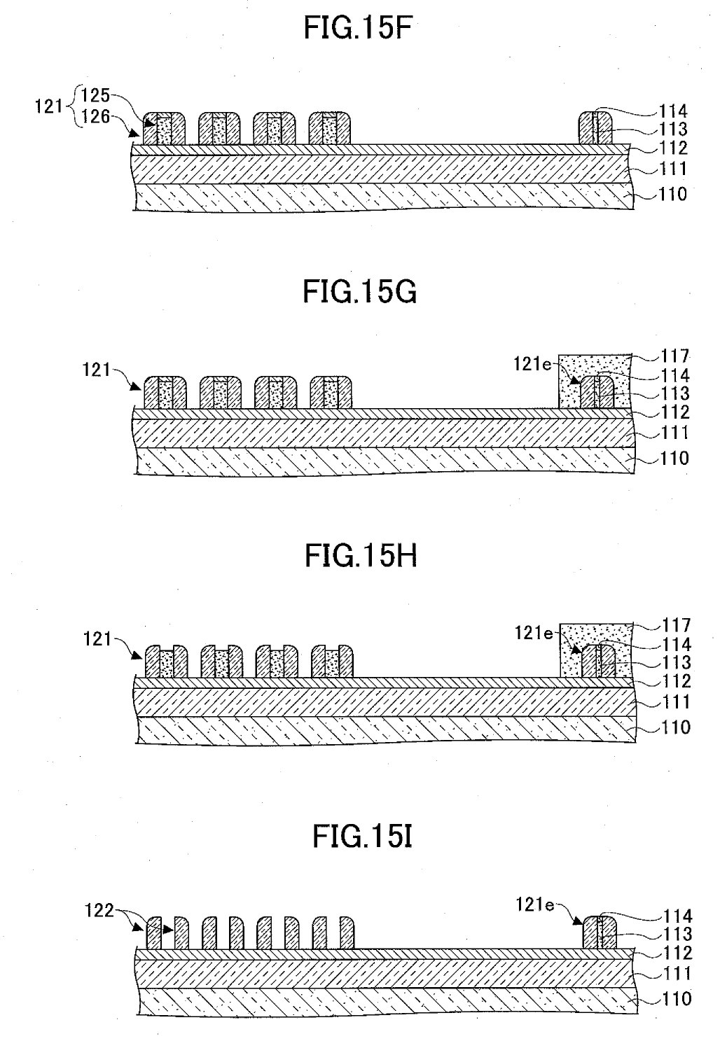

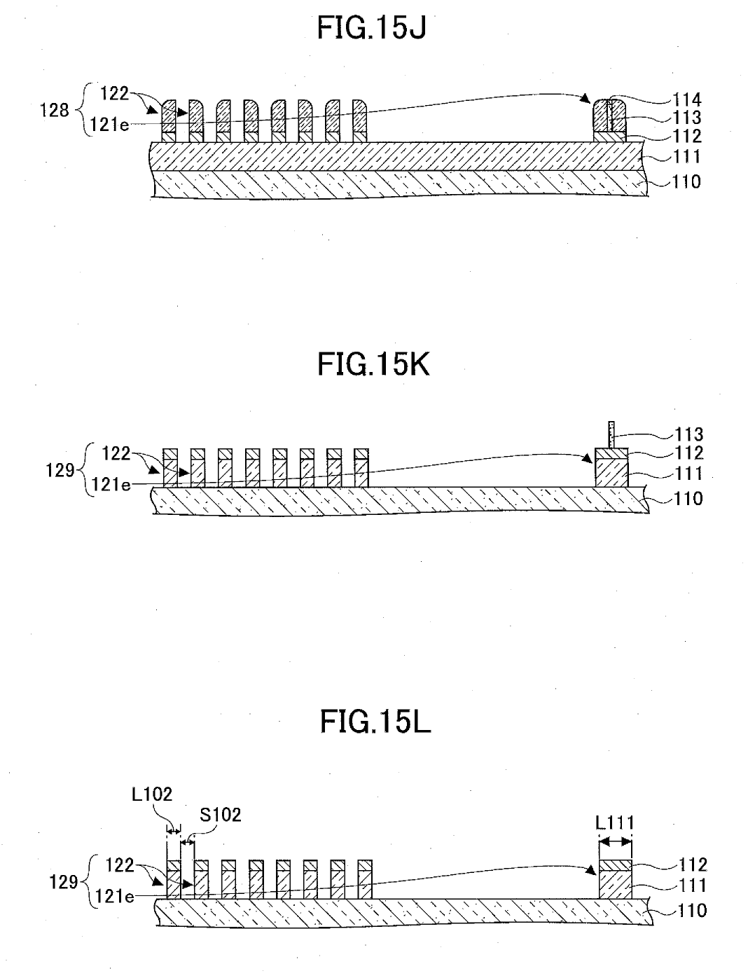

Next, with reference to FIGS. 15A through 15L, a semiconductor device manufacturing method according to a fifth variant embodiment of the second embodiment of the present invention will be described.

FIGS. 15A through 15L illustrate the semiconductor device manufacturing method according to the present variant embodiment, and are sectional views diagrammatically showing structures of a semiconductor device in the respective processes.

The semiconductor device manufacturing method according to the present variant embodiment is different from the semiconductor device manufacturing method according to the third variant embodiment of the second embodiment in that, when first patterns including core parts and side wall parts are formed, a line width of a core part in a first pattern coated with a first photoresist film after that is thinner than a line width of core parts in first patterns not coated by the first photoresist film.

With reference to FIGS. 15A through 15L, different from the line width of the core part in the first pattern coated by the first photoresist film being the same as the line width of the core parts in the first patterns not coated by the first photoresist film in the third variant embodiment of the second embodiment, the line width L141 of the core part 125 in the first pattern 121a coated by the first photoresist film 117 is thinner than the line width L104 of the core parts 125 in the first patterns 121 not coated by the first photoresist film 117 in the present variant embodiment.

The semiconductor device manufacturing method according to the present variant embodiment includes steps S111 through S122 as shown in FIG. 9, like the third variant embodiment of the second embodiment.

First, a preparing process including step S111 is carried out. As shown in FIG. 15A, a substrate is used in which, on the substrate 110, a first to-be-etched layer 111, a second to-be-etched layer 112, an organic layer 113 and a protective layer 114 are formed in the stated order from the bottom, like the second embodiment, also in the present variant embodiment.

Next, step S112 is carried out. That is, a third pattern forming process of exposing and developing a second photoresist film 115, and forming third patterns 123 of the second photoresist films 115. In the present variant embodiment, like the third variant embodiment of the second embodiment, the second photoresist film 115 is formed on the protective film 114, photolithography is carried out by using a metal mask having an isolated pattern 123e having a line width thinner than even number patterns of the third patterns 123 at a place away from the even number patterns of the third patterns 123, exposing and developing are carried out, and the third patterns 123 having the isolated pattern 123e are formed. A structure of the semiconductor device after the process of step S112 is carried out is shown in FIG. 15B. In the present variant embodiment, the width L103 of the third patterns 123 corresponding to the even number patterns may be, for example, 60 nm, and the width L131 of the isolated pattern 123e may be, for example, 40 nm that is thinner than L103 by 20 nm.

Next, step S113 is carried out. That is, a process of trimming the third patterns 123 of the second photoresist films 115, and etching the protective film 114 by using the trimmed second photoresist films 115 as masks is carried out. In the present variant embodiment, the trimming may be carried out in such a manner that the third patterns 123 of the second photoresist films 115 are etched from both left and right sides by 15 nm each. As a result, it is possible to trim L104 that is the line width corresponding to the even number of line patterns 124 to 30 nm, and trim L141 that is the line width corresponding to the isolated pattern 124e to 10 nm. A partial structure of the semiconductor device after the process of step S112 is shown in FIG. 150.

A first pattern forming process including steps S114 through S116 to be carried out next is like the second embodiment, and partial structures of the semiconductor device after the respective processes are finished are shown in FIGS. 15D through 15F.

Further, a photoresist coating process, a protective film removing process, a second pattern forming process and a to-be-etched layer etching process including steps S117 through S122 are like the third variant embodiment of the second embodiment, and partial structures of the semiconductor device after the respective processes are finished are shown in FIGS. 15G through 15L. As a result, the patterns made of the first to-be-etched layers 111 and the second to-be-etched layers 112 and having the isolated pattern 121e at the position away from the even number patterns 122 are formed in a lump. The line width L102 and the space width S102 of the even number patterns 122 may be the same as the third variant embodiment of the second embodiment, i.e., for example, both may be 30 nm. On the other hand, since, in comparison to the third variant embodiment of the second embodiment, the first one of the line width L131 of the isolated pattern 123e of the third patterns 123 of the second photoresist films 115 is 40 nm that is thinner by 20 nm than the line width L103, 60 nm, of the even number patterns of the third patterns 123, the line width L111 of the isolated pattern 121e may be 70 nm that is thinner by 20 nm than 90 nm in the third variant embodiment of the second embodiment.

It is noted that, as a result of the line width of the isolated pattern 123e being made to be any width that is different from the line width of the even number patterns of the third patterns 123 when the third patterns 123 made of the second photoresist films 115 are formed, a width of a mask for the isolated pattern made of the first to-be-etched layer 111 and the second to-be-etched layer 112 may be made to be any width.

### Sixth Variant Embodiment of Second Embodiment

Next, a semiconductor device manufacturing method according to a sixth variant embodiment of the second embodiment of the present invention will be described.

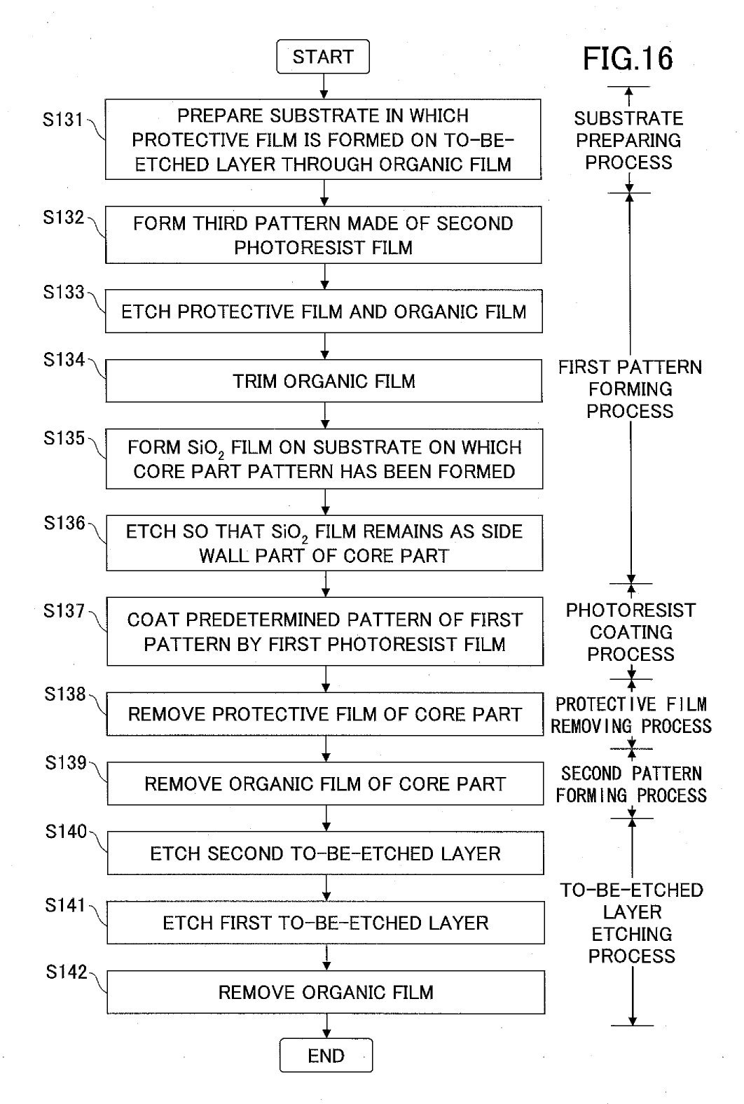

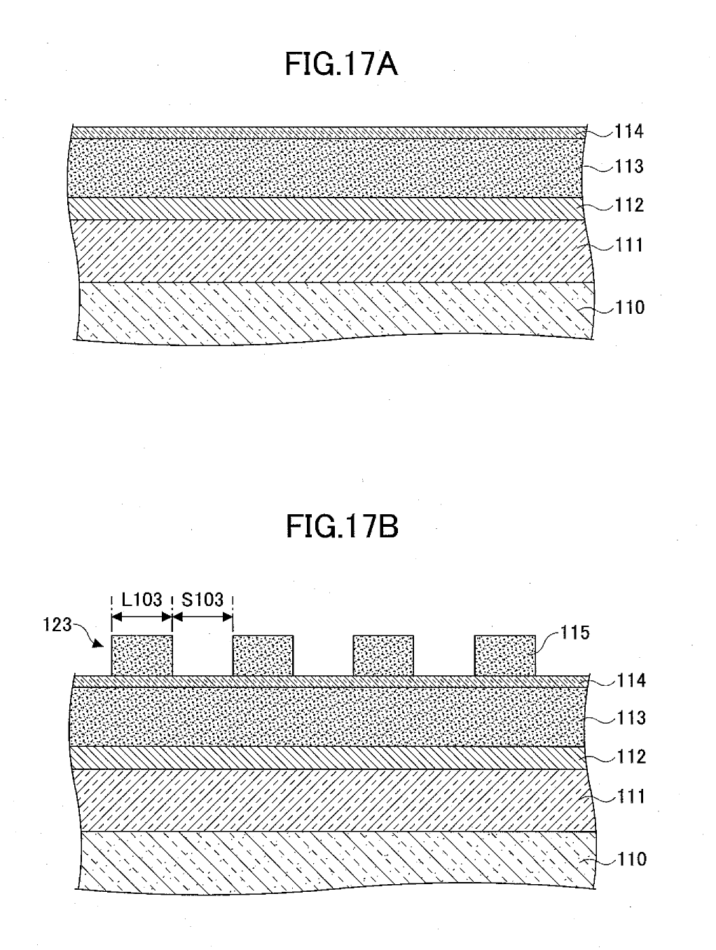

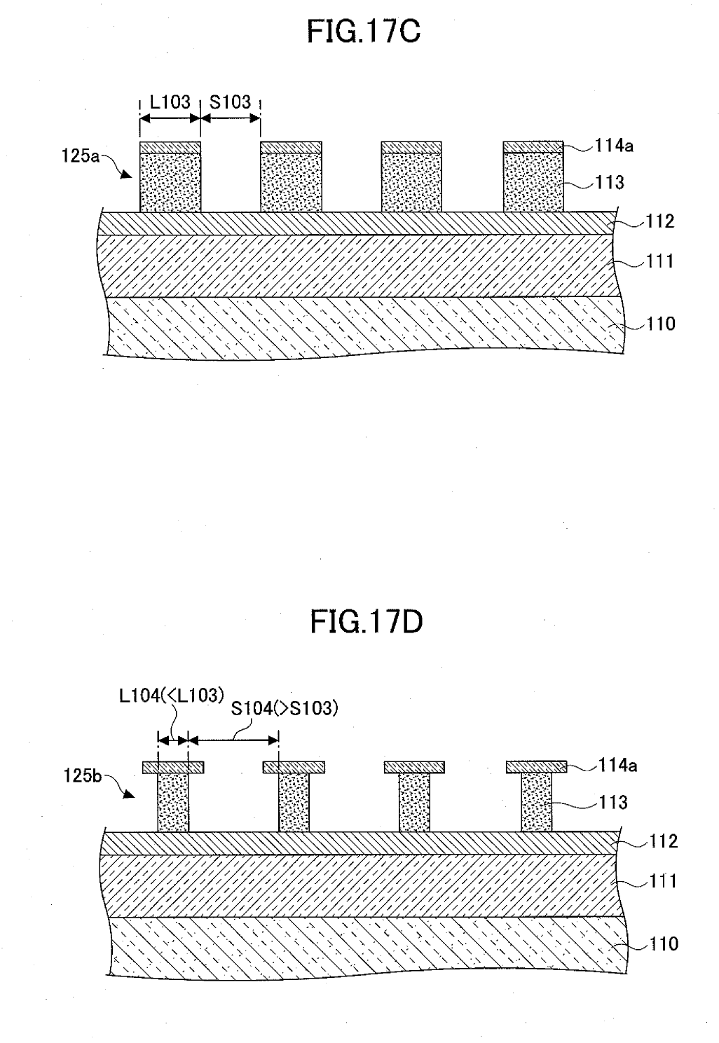

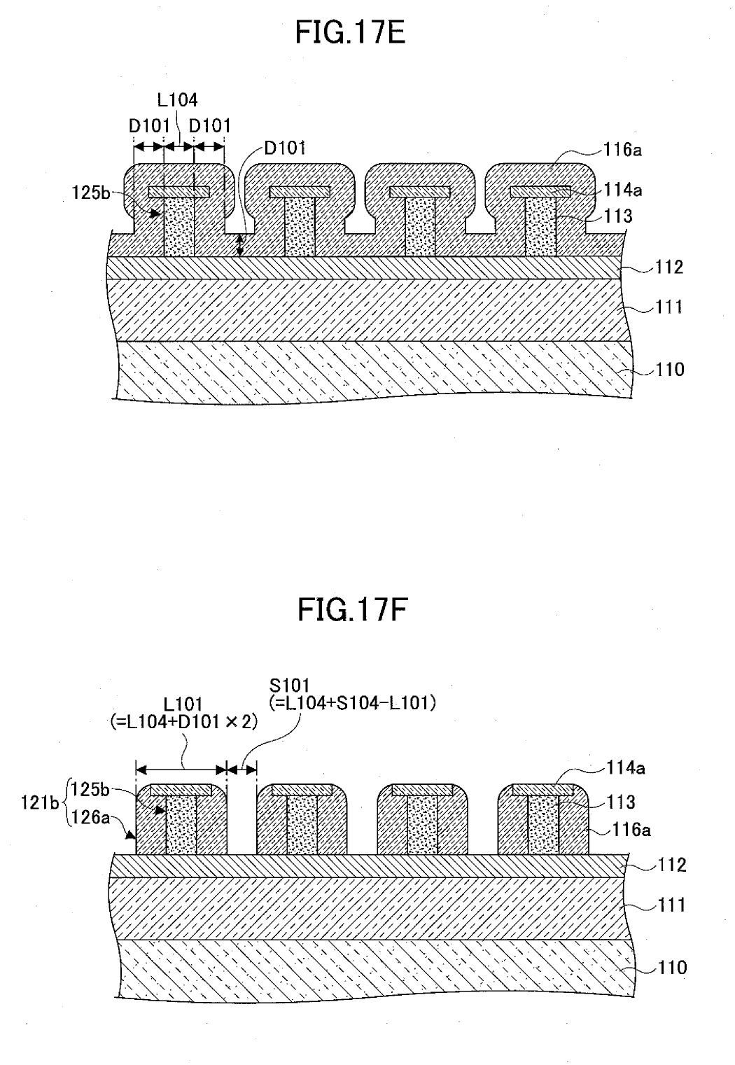

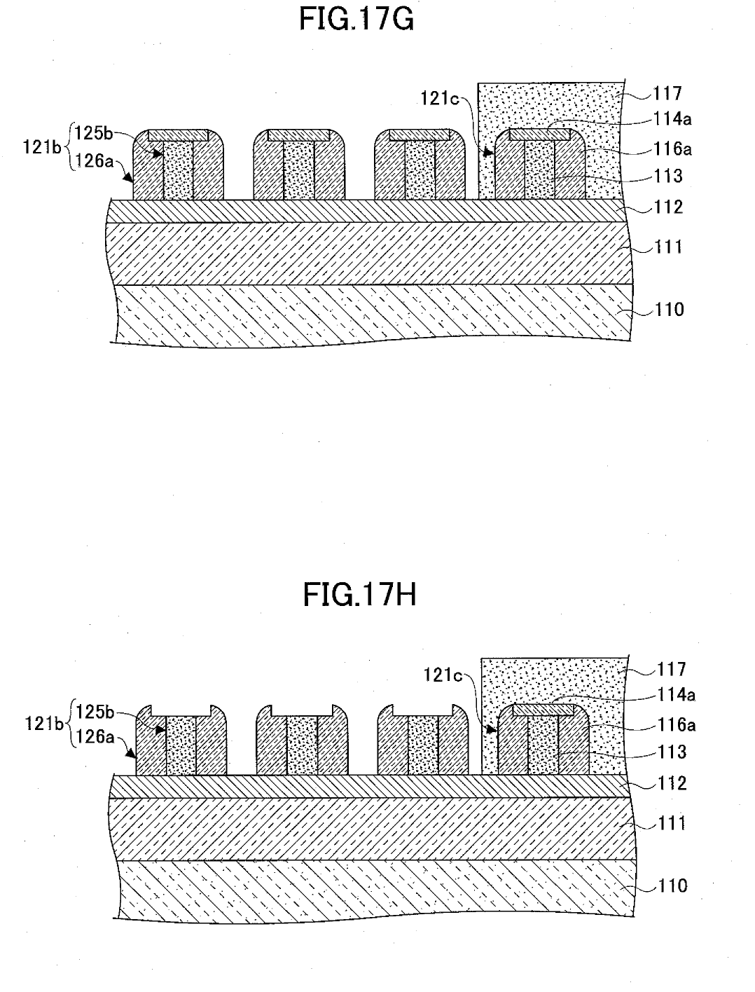

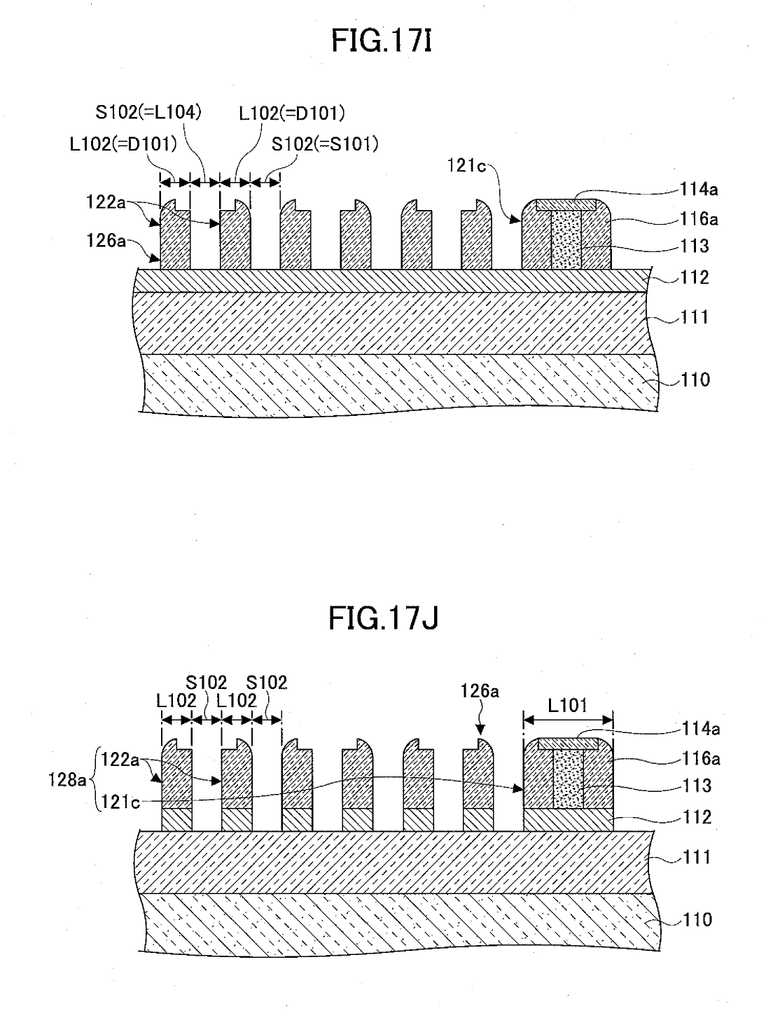

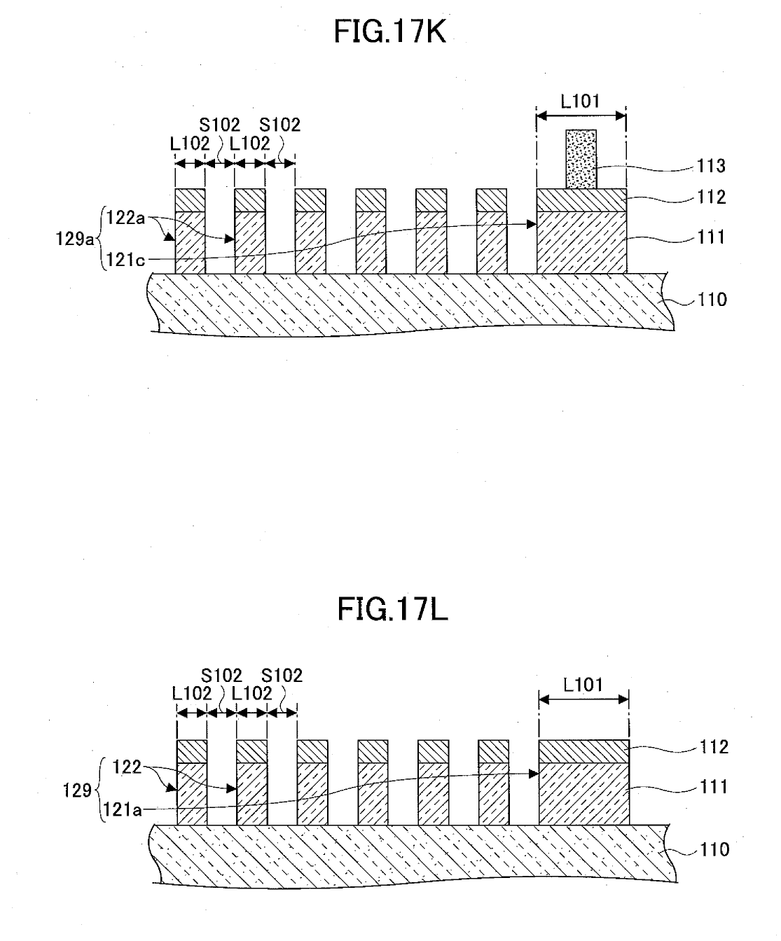

FIG. 16 shows a process diagram illustrating procedures of respective processes of the semiconductor device manufacturing method according to the present variant embodiment. FIGS. 17A through 17L illustrate the processes of the semiconductor device manufacturing method in the present variant embodiment, and are sectional views diagrammatically showing structures of the semiconductor device in the respective processes. Further, the structures of the semiconductor device after the respective processes are carried out correspond to the respective sectional views of FIGS. 17A through 17L.

The semiconductor device manufacturing method according to the present variant embodiment is such that part of the order of the processes of the semiconductor device manufacturing method according to the second embodiment is changed, and is different from the semiconductor device manufacturing method according to the second embodiment in that second photoresist films 115 that form third patterns 123 are not trimmed, and, after patterns of core pattern parts 125a are formed, the patterns of the core part patterns 125a are trimmed.

With reference to FIG. 16, different from the second photoresist films that form the third patterns being trimmed in step S113 and the protective films and the organic films being trimmed in step S114 in the second embodiment, a protective film and an organic film being etched in step S133, and the organic films are trimmed in step S134 in the present variant embodiment.

As shown in FIG. 16, the semiconductor device manufacturing method according to the present variant embodiment includes a substrate preparing process, a first pattern forming process, a photoresist coating process, a protective film removing process, a second pattern forming process and a to-be-etched layer etching process. The substrate preparing process includes a process of step S131, the first pattern forming process includes processes of steps S132 through S136, the photoresist coating process includes a process of step S137, the protective film removing process includes a process of step 138, the second pattern forming process includes a process of step S139, and the to-be-etched layer etching process includes processes of steps S140 through S142.

First, the preparing process including step S131 is carried out. Step S131 is a process of preparing a substrate on which the protective film is formed on the to-be-etched layer through the organic film, and is like the process of step S111 in the second embodiment. FIG. 17A is a sectional view showing a structure of the semiconductor device after the process of step S131 is carried out.

In step S131, as shown in FIG. 17A, the substrate is prepared in which, in the stated order from the bottom, a first to-be-etched layer 111, a second to-be-etched layer 112, the organic film 113 and the protective film are formed. As the second to-be-etched layer 112, for example, amorphous silicon or polysilicon may be used. As the organic film 113, a broad range of organic materials may be used, which include amorphous carbon formed by a chemical vapor deposition (CVD) method, polyphenol, a film of which is formed by spin on, and photoresist such as i-ray resist. As the protective film 114, for example, a SOG film that is a reflection-preventing film made of inorganic material (or a SiON film, or a composite film of a LTO film and BARC) may be used.

Next, the first pattern forming process including steps S132 through S136 is carried out.

Step S132 is a third pattern forming process of forming a second photoresist film 115, exposing and developing the formed second photoresist film 115, and forming third patterns 123 that are made of the second photoresist films 115 and have a line width L103 and a space width S103, as shown in FIG. 17B, and is a process like step S112 of the second embodiment.

Step S133 is to etch the protective film 114 made of a SOG film (or a SiON film, or a composite film of a LTO film and a BARC film) and the organic film 113 by using the third patterns 123 made of the second photoresist films 115 as masks. FIG. 17C is a sectional view showing a structure of the semiconductor device after the process of step S133 is carried out.

In step S133, first, the protective film 114 is etched by using the third patterns 123 as masks. The etching of the protective film 114 may be carried out by using, for example, a mixed gas of a gas of a CF family, such as CF₄, C₄F₈, CHF₃, CH₃F or CH₂F₂, and an Ar gas or such, or, a gas obtained from adding oxygen to the mixed gas, as is necessary, or such.

In step S133, next, as shown in FIG. 17C, plasma etching is carried out on the organic film 113 by using, for example, plasma of an oxygen gas, a nitrogen gas or such, by using the protective films 114a to which the shapes of the third patterns 123 have been transferred, and patterns 125a of the organic films 113 having a line width L103 and a space width S103, and an upper layer of which are protected by the protective films 114a, are formed.

Step S134 is a process of trimming the organic films 113 that form the patterns 125a. FIG. 17D is a sectional view showing a structure of the semiconductor device after the process of step S134 is carried out.

In step S134, the line width of the organic films 113 is reduced through the trimming by using the plasma of an oxygen gas, a nitrogen gas or such, and core part patterns 125b are formed. Further, as shown in FIG. 17D, the line width L104 in the organic films 113 of the core part patterns 125b obtained from the trimming is thinner than the line width L103 of the third patterns 123 before the trimming. Therefore, a size relationship between the line width L104 and the space width S104 of the core part patterns 125b and the line width S103 and the space width S103 of the third patterns 123 is such as L104<L103, and S104>S103.

The trimming in step S134 is carried out in a state in which upper layer parts of the organic films 113 are covered by the protective films 114a made of the SOG film (or a SiON film, or a composite film of a LTO film and a BARC film) as the masks. Therefore, etching of the organic films 113 in a vertical direction is not carried out, the film thickness is not reduced, only the line width is reduced, and also, the trimming is carried out vertically. Therefore, a SiO₂ film 116a can be formed to be vertically thicker in step S135 described later.

It is noted that the process of etching the organic film 113 in step S133 and the process of trimming the organic films 113 in step S134 may be carried out continuously.

Step S135 is a process of forming the SiO₂ film 116a on the substrate on which the patterns of the core parts 125b have been formed, and is like the process of step S115 in the second embodiment. Further, FIG. 17E is a sectional view showing a structure of the semiconductor device after the process of step S135 is carried out.

As shown in FIG. 17E, the SiO₂ film 116a is formed throughout the surface of the substrate including places at which the core parts 125b are formed and places at which no core parts are formed, and the SiO₂ film 116a is formed also on side faces of the core parts 125b to coat the side faces of the core parts 125b. At this time, assuming that a thickness of the SiO₂ film 116a is D101, a width of the SiO₂ film 116a coating the side faces of the patterns of the core parts 125b is also D101. The thickness D101 of the SiO₂ film 116a is not particularly limited, and, for example, may be 30 nm.

Next, step S136 is carried out. Step S136 is an etching process of etching such that the SiO₂ film 116a remains only as side wall parts 126a of the core parts 125b. Further, FIG. 17F is a sectional view showing a structure of the semiconductor device after the process of step S136 is carried out.

In step S136, the SiO₂ film 116a and the protective film 114a made of the SOG film (or a SiON film, or a composite film of a LTO film and BARC) are etched, the SiO₂ films 116a remain only in the side wall parts 126a of the core parts 125b made of the organic films 113, and first patterns 121b including the core parts 125b and the side wall parts 126a are formed. As shown in FIG. 17F, the protective films 114a that protect upper layer parts of the core parts 125b may be made to remain. The etching in step S136 may be carried out by using, for example, a mixed gas of a gas of a CF family, such as CF₄, C₄F₈, CHF₃, CH₃F or CH₂F₂, and an Ar gas or such, or, a gas obtained from adding oxygen to the mixed gas, as is necessary, or such. Assuming that a line width of the first patterns 121b is L101 and a space width thereof is S101, L101=L104+D101×2 and S101=L104+S104−L101, and thus, L101 may be made to be 90 nm and S101 may be made to be 30 nm in a case where the line width of the core parts 125b is 30 nm and the thickness D101 of the side wall parts 126a is 30 nm.

In the present variant embodiment, the forming of the SiO₂ film 116a and the etching of the SiO₂ film and the protective film 114a made of the SOG film (or a SiON film, or a composite film of a LTO film and a BARC film) are carried out in the state in which, on the organic film 113, the protective film 114a made of the SOG film (or a SiON film, or a composite film of a LTO film and BARC) is formed on the organic film 114a. Therefore, it is possible to vertically form the side wall parts 126a made of the remaining SiO₂ films 116a.

After that, processes of step S137 through S142 are like the processes of steps S117 through S122 in the second embodiment.

As shown in FIG. 17G, the photoresist coating process including step S137 is carried out, and a predetermined pattern 121c of the first patterns 121b is coated with a first photoresist film 117.

Next, as shown in FIG. 17H, the protective film removing process including step S138 is carried out, and the protective films 114a protecting the upper layer parts of the core parts 125b are etched.

Next, as shown in FIG. 17I, the second pattern forming process including step S139 is carried out, and thus, second patterns 122a are formed, made of the side wall parts 126a remaining as a result of the organic films 113 of the core parts 125b being removed. The organic films 113 of the core parts 125b are removed and only the side wall parts 126a remain in the first patterns 121b not coated by the first photoresist film 117, and the second patterns 122a are formed which are such patterns that the line width is D101 and the space widths of L104 and S101 alternately occur. In the present variant embodiment, as a result of the line width L104 of the core parts 125b being made to be equal to the space width S101 of the first patterns 121b, the space width becomes S102 that is equal to L104 and S101. Further, a line width equal to D101 is newly referred to as L102.

Next, as shown in FIG. 17J, a process of step S140 is carried out, the second to-be-etched layer 112 that is a lower layer of the organic films 113 is etched by using the second patterns 122a and the first pattern 121c as masks, and fifth patterns 128a made of the second to-be-etched layers 112 having the side wall parts 126a as upper layer parts and having the same shapes as those of the second patterns 112a and the first pattern 121c are formed.

Next, as shown in FIG. 17K, a process of step S141 is carried out, the first to-be-etched layer 111 is etched by using the fifth patterns 128a as masks, and sixth patterns 129a made of the first to-be-etched layers 111 and the second to-be-etched layers 112 are formed. As a result, it is possible to form simultaneously the second patterns 122a that are even number patterns having the line width L102 and the space width S102, and the first pattern 121c that is an odd number pattern having the line width L101.

Finally, as shown in FIG. 17L, a process of step S142 is carried out, and the organic film 113 that has not been removed in step S141 is removed.

### Third Embodiment

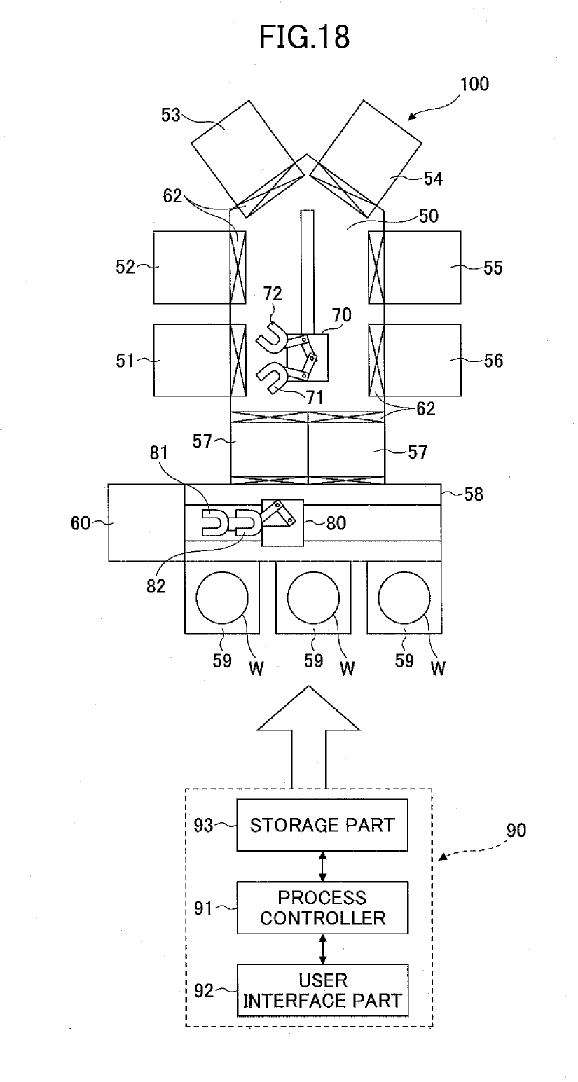

Next, with reference to FIG. 18, a semiconductor device manufacturing apparatus for carrying out a semiconductor device manufacturing method according to a third embodiment of the present invention will be described.

FIG. 18 is a plan view diagrammatically showing one example of a configuration of the semiconductor device manufacturing apparatus for carrying out the semiconductor device manufacturing method according to the present embodiment.

At a central part of the semiconductor device manufacturing apparatus 100, a vacuum conveyance chamber 50 is provided, and plural (six, in the present embodiment) processing chambers 51 through 56 are provided in the periphery of and along with the vacuum conveyance chamber 50. The processing chambers 51, 52, 53, 54, 55 and 56 are those for carrying out, in the inside, plasma etching and low-temperature MLD.

In front (on the lower side in the figure) of the vacuum conveyance chamber 50, two load lock chambers 57 are provided, and further a conveyance chamber 58 for conveying substrates (semiconductor wafers W in the present embodiment) in the atmosphere is provided in front (on the lower side in the figure) of the load lock chambers 57. Further in front (on the lower side in the figure) of the conveyance chamber 58, plural placement parts 59 are provided in which substrate holding cases (cassettes or hoops) that are capable of holding plural semiconductor wafers W are disposed. In a lateral direction (on the left side in the figure) of the conveyance chamber 58, an orientor 60 that detects a position of the semiconductor wafer W by using an orientation flat or a notch is provided.

Gate valves are provided, respectively, between the load lock chambers 57 and the conveyance chamber 58, between the load lock chambers 57 and the vacuum senescence chamber 50, and between the vacuum conveyance chamber 50 and the processing chambers 51 through 56, and are capable of closing and opening therebetween in an airtight manner. Further, a vacuum conveyance mechanism 70 is provided in the vacuum conveyance chamber 50. The vacuum conveyance mechanism 70 is provided with a first pick 71 and a second pick 72, is capable of supporting the two semiconductor wafers W therewith, and is capable of conveying the semiconductor wafers W in and out from the respective processing chambers 51 through 56 and the load lock chambers 57.

Further, in the conveyance chamber 58, an atmosphere conveyance mechanism 80 is provided. The atmosphere conveyance mechanism 80 is provided with a first pick 81 and a second pick 82, and is capable of supporting the two semiconductor wafers W by means of the first pick 81 and the second pick 82. The atmosphere conveyance mechanism 80 is capable to conveying the semiconductor wafers W in and out from the respective cassettes or hoops placed on the placement parts 59, the load lock chamber 57 and the orientor 60.

Operations of the semiconductor device manufacturing apparatus 100 configured as mentioned above are control by a control part 90 in an overall control manner. In the control part 90, a process controller 91 that is provided with a CPU and controls the respective parts of the semiconductor device manufacturing apparatus 100, a user interface part 92 and a storage part 93 are provided.

The user interface part 92 includes a keyboard which a process manager operates to input commands for managing the semiconductor device manufacturing apparatus 100, a display which visualizes and displays operating situations of the semiconductor device manufacturing apparatus 100, and so forth.

In the storage part 93, recipes are stored, in which control programs (software) for realizing various processes to be carried out in the semiconductor device manufacturing apparatus 100 through the control of the process controller 91, processing condition data, and so forth are stored. As a result of any recipe being called from the storage part 93 by instructions given through the user interface part 92 as is necessary, and being executed by the process controller 91, a desired process is carried out in the semiconductor device manufacturing apparatus 100 under the control of the process controller 91. Further, as the recipes of the control programs, the processing condition data and so forth, those in a state of being stored in a computer readable information recording medium (such as a hard disk, a CD, a flexible disk, a semiconductor memory or such) or such may be used, or, those may be transmitted from another apparatus through, for example, a dedicated line as needed and used in an online state.

By using the above-mentioned semiconductor device manufacturing apparatus 100, the sequence of processes according to the first embodiment, the first through fifth variant embodiments of the first embodiment, the second embodiment and the first through sixth variant embodiments of the second embodiment may be carried out. It is noted that as to the photoresist coating process and the film forming process, these processes may be carried out by another apparatus after the semiconductor wafer W is conveyed out from the semiconductor device manufacturing apparatus 100.

Thus, the preferable embodiments of the present invention have been described. However, the present invention is not limited to the specific embodiments, and various modifications and changes may be made within the scope of the present invention described in the claims.

The present application includes the subject matter relating to the Japanese Patent Application No. 2008-155844 filed in Japan Patent Office on Jun. 13, 2008 and the subject matter relating to the Japanese Patent Application No. 2008-155845 filed in Japan Patent Office on Jun. 13, 2008, and the contents of all thereof are hereby incorporated herein by reference.

1. A semiconductor device manufacturing method, comprising:
a first organic film pattern forming process of forming a to-be-etched layer, a first organic film, and a protective film on a substrate in this order, and patterning the protective film and the first organic film to form a first organic film pattern having line parts that have a fixed width;
a silicon oxide film forming process of forming a silicon oxide film so as to coat the first organic film pattern in an isotropic manner;
a first mask pattern forming process of etching the silicon oxide film to form a first mask pattern so as to cause the width of the first organic film pattern to have a fixed proportion with respect to a thickness of the silicon oxide film that coats side walls of the line parts of the first organic film pattern in the isotropic manner;
a second organic film pattern forming process of forming a second organic film to coat a part of the first mask pattern, and patterning the second organic film to form a second organic film pattern;
a second mask pattern forming process of, in an area other than the area that is coated by the second organic film pattern, removing the protective film of the first mask pattern;
a third mask pattern forming process of, in an area other than an area that is coated by the second organic film pattern, removing the first organic film of the first mask pattern to form a second mask pattern in which an even number of parts of the silicon oxide film are arranged, and removing, in the area that is coated by the second organic film pattern, the second organic film without removing the protective film and the first organic film to form a third mask pattern; and
an etching process of etching the to-be-etched layer by using the second mask pattern and the third mask pattern of which width is greater than widths of the parts of the second mask pattern.

2. The semiconductor device manufacturing method as claimed in claim 1,
wherein the first organic pattern forming process includes:
a fourth organic film pattern forming process of forming a fourth organic film on the protective film formed on the to-be-etched layer, and forming a fourth organic film pattern by patterning the fourth organic film; and
a core part pattern forming process of forming a pattern of core parts protected by the protective film as the line parts, by etching the protective film and the first organic film protected by the protective film by using the fourth organic film pattern.

3. The semiconductor device manufacturing method as claimed in claim 2,
wherein, in the core part pattern forming process,
after the fourth organic film pattern is trimmed, the protective film and the first organic film protected by the protective film are etched.

4. The semiconductor device manufacturing method as claimed in claim 1,
wherein in the silicon oxide film forming process, a source gas containing silicon and a gas containing oxygen are supplied alternately, and the silicon oxide film is formed over the substrate.

5. The semiconductor device manufacturing method as claimed in claim 1,
wherein the to-be-etched layer is a silicon layer, a silicon oxide layer, a silicon nitride layer or a silicon oxynitride layer.

6. The semiconductor device manufacturing method as claimed in claim 1,
wherein for the to-be-etched layer, a layer obtained from laminating a first to-be-etched layer and a second to-be-etched layer in sequence from a side of the substrate is used.

7. The semiconductor device manufacturing method as claimed in claim 1,
wherein the protective film is a SOG film, a SiON film, or a composite film of a LTO film and a BARC film.
